(19) United States
(12) Patent Application Publication
(10) Pub. No.: US 2016/0027937 A1
(43) Pub. Date: Jan. 28, 2016

(54) SEMICONDUCTOR MATERIALS AND METHOD FOR MAKING AND USING SUCH MATERIALS

(71) Applicant: Oregon State University, Corvallis, OR (US)

(72) Inventors: Douglas A. Keszler, Corvallis, OR (US); Jeoseok Heo, Corvallis, OR (US); Robert S. Kokenyesi, Corvallis, OR (US); Ram Ravichandran, Corvallis, OR (US)

(73) Assignee: Oregon State University, Corvallis, OR (US)

(21) Appl. No.: 14/877,283

(22) Filed: Oct. 7, 2015

Related U.S. Application Data
(63) Continuation-in-part of application No. PCT/US2014/033363, filed on Apr. 8, 2014.
(60) Provisional application No. 61/809,808, filed on Apr. 8, 2013.
(60) Provisional application No. 61/900,847, filed on Nov. 6, 2013.

(51) Int. Cl. H01L 31/032; H01L 31/18

(52) U.S. Cl. CPC H01L 31/032; H01L 31/18

(57) ABSTRACT

Novel compounds having a formula M¹_{d}M²ₑM³_{f}Ch_{g} where M¹ is a transition metal, a group III, group IV, or group V element, M² is a group 13, group 14, or group 15 element, and M³ and Ch independently are group 15 or group 16 elements, and a method for making the same are disclosed. The compounds may have a tetrahedrite crystal structure. Also disclosed are novel compounds having a formula A¹₃MCh^{a}₄ where A¹, is a transition metal, M is a transition metal, a group 14 element, a group 15 element or a combination thereof, and Ch^{a} is a group 16 element. Also disclosed are methods of making and using the compounds. The compounds may form part of a device. Some devices may comprise both a tetrahedrite and a A¹₃MCh^{a}₄ compound. Some devices may have an electrical output, for example a photovoltaic device, such as a thin film solar cell.

### CROSS REFERENCE TO RELATED APPLICATION

This application is a continuation-in-part of International Application No. PCT/US2014/033363, filed on Apr. 8, 2014, which claims the benefit of the earlier filing dates of U.S. Provisional Application No. 61/809,808, filed on Apr. 8, 2013, and U.S. Provisional Application No. 61/900,847, filed on Nov. 6, 2013. The contents of these prior applications are incorporated herein by reference in their entirety.

### ACKNOWLEDGMENT OF GOVERNMENT SUPPORT

This invention was made with government support under Contract No. DE-AC36-08GO28308 awarded by the U.S. Department of Energy, Office of Science, Office of Basic Energy Sciences. The United States government has certain rights in the invention.

### FIELD

This invention concerns semiconductor compounds, such as solar absorber compounds, and methods for making and using the same, including embodiments of devices incorporating the disclosed compounds, with certain particular embodiments concerning photovoltaic devices.

### BACKGROUND

Photovoltaic cells or solar cells, and modules are photovoltaic (PV) devices that convert sunlight energy into electrical energy. Common materials used in PV cells are crystalline silicon (c-Si), Cu(In,Ga)Se₂ (CIGS) and CdTe. The use of c-Si is constrained by high production costs of bulk wafers. Cu(In,Ga)Se₂ (GIGS) and CdTe may be fabricated using low-cost thin-film growth techniques to deposit the polycrystalline absorber material onto large-area substrates. All of the known PV technologies, however, are not sufficiently efficient to overcome balance of systems costs, which drive the total cost of a PV system. Improved device efficiency at low-cost and associated balance of system cost reduction can be achieved by incorporating highly absorbing semiconductors into thin film photovoltaic cells.

The semiconductors silicon, CIGS, and CdTe, exhibit relatively low absorption in critical portions of the solar spectrum. Accordingly, to maximize solar cell efficiency, the absorber layers are thick, varying from 2-8 μm to over 100 μm for CIGS, CdTe and c-Si, respectively. Thin-film solar cells (TFSCs) reduce the amount of material required compared to c-Si. TFSCs also provide flexible substrate integration. Laboratory-scale PV device efficiencies of 20% for CIGS and CdTe solar cells have been achieved. Toxicity and/or relative abundance considerations with respect to constituent elements, as well as limited efficiency at scale, hinder the large-scale deployment of CdTe- and CIGS-based TFSCs.

Most current solar cell technologies, e.g., c-Si, GaAs, CdTe and CIGS, rely primarily on diffusion rather than drift for photo-generated carrier extraction. Carrier mobility and lifetimes must be comparatively large for efficient photovoltaic conversion in a diffusion-based solar cell. In this case charge-carrier separation relies on random thermal motion of the electrons until they are captured by the electric fields existing at the edges of the active region. Reducing absorber layer thickness can overcome efficiency limitations by shortening carrier collection lengths and lowering bulk recombination effects. The carrier mobility and lifetimes in a drift-based solar cell, such as amorphous silicon, can be smaller and shorter, respectively, compared with a diffusion-based cell, since the presence of an internal electric field established across the device aids carrier extraction. For an efficient drift-based TFSC, the absorber layer requires very strong absorption with an abrupt onset near the band gap, such that the thickness of the layer can be less than 1 nm.

Thermodynamic considerations, as outlined by Shockley and Queisser, J. Appl. Phys. 1961, 32, 510, are commonly used to assess the efficiency limits of a solar absorber material. Recently a new and improved analysis methodology, Spectroscopic Limited Maximum Efficiency (SLME), was proposed by Yu and Zunger, Phys. Rev. Lett. 2012, 108, 068701. Building on the original Shockley-Queisser approach in which photovoltaic absorber candidates are selected solely on the basis of band gap, SLME incorporates absorption, emission, and recombination considerations to account for a spread of different efficiencies for materials with the same band gap. Chemical insight along with SLME can be used effectively to identify absorber candidates for high-efficiency, drift-based cells.

### SUMMARY

In view of the above, there is a need for new materials for use in semiconductor devices. In addition, TFSCs need to be a larger contributor to the overall net electricity generation, utilizing new, earth-abundant and environmentally benign solar cell materials. Disclosed embodiments of the present application address these needs and provide a method for forming novel compounds, both as bulk materials and as thin films that can be used in TFSCs. Devices comprising those compounds also are disclosed.

Certain disclosed devices comprise a contact electrode, and a material comprising a first compound, having a formula VII

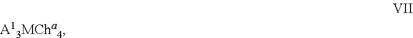

and a second compound, having a formula V

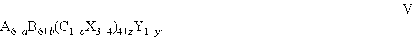

With reference to formula VII, A¹ is a transition metal, or any combination thereof, M is selected from a transition metal, a group 14 element, a group 15 element, or any combination thereof, and Ch^{a} is a group 16 element, or any combination thereof. With reference to formula VII, A¹ is a transition metal, or any combination thereof; M is selected from a transition metal, a group 14 element, a group 15 element, group 16 element or any combination thereof; Ch^{a} is a group 16 element, or any combination thereof. With reference to formula V, A and B independently are selected from a transition metal, a group 13 element, a group 14 element, a group 15 element, or any combination thereof; C is a cation with ns² electronic configuration, which is selected from a group 13 element, a group 14 element, a group 15 element, or any combination thereof; and X and Y independently are a group 15 anion, a group 16 anion, a group 17 anion, or any combination thereof; a is from −2.5 to 2; b is from −2 to 2; c is from −1 to 1; x is from −2 to 2; z is from −1 to 1; and y is from −1 to 2.

In some embodiments, A and B independently are selected from Cu, Ag, Au, Mn, Zn, Mo, W, Ti, Zr, Hf, Cd, Al, Ga, In, Si, Ge, Sn, Fe, Co, Ni, V, Nb, Ta, or any combination thereof. In some examples, C is selected from Ga, In, Si, Ge, Sn, Pb, P, As, Sb, Bi, Se, Te, or any combination thereof. In other examples, X and Y independently are selected from P, As, Sb, Bi, O, S, Se, Te, F, Cl, or any combination thereof. In certain examples, X and Y each is independently selected from S, Se, or a combination thereof.

In some embodiments, A₆₊ₐB_{6+b} comprises Cu_{12+a+b-h}M⁵ₕ, M⁵ is selected from Mg, Zn, Mn, Sn, or any combination thereof, and h is from 0 to 2.

Alternatively, M⁵ may be selected from Al, Ga, In, or any combination thereof, and h is from 0 to 1.

In certain disclosed embodiments, A¹ of formula VII is selected from Cu, Ag, Mg, Zn, Mn, or any combination thereof. In other embodiments, M is selected from P, As, Sb, V, Nb, Te, Ta, Si, Ge, Sn, Ti, Zr, Hf, Cr, Mo, W, Al, Ga, In, or any combination thereof, and/or Ch^{a} is selected from S, Se, or any combination thereof.

Devices may be made using any disclosed compound. The device may be an electrical device, such as a photovoltaic device. In some embodiments, the device comprises a plurality of semiconductor layers, with the first compound in a first discrete semiconductor layer and the second compound in a second discrete semiconductor layer. In other embodiments, the device comprises a semiconductor layer comprising the material or materials. For example, the semiconductor layer may be a graded semiconductor layer wherein the relative amounts of the first and second materials change inversely throughout the cross section of a layer comprising these semiconductors.

In some embodiments, the device comprises a p-layer and a p⁺-layer, wherein at least one of the p-layer and the p⁺-layer comprises the first compound and at least one of the p-layer and the p⁺-layer comprises the second compound. In certain examples, the p-layer comprises the first compound and the p⁺-layer comprises the second compound.

In certain disclosed embodiments, the device comprises a substrate, a contact layer, an absorber layer comprising the first compound, a p⁺-layer comprising the second compound, and a top contact electrode. In some embodiments, the device comprises a substrate, a bottom contact layer, a p⁺-type layer comprising the second compound, a p-type layer comprising the first compound, a buffer layer, a window layer, and a top contact electrode. In other embodiments, the device comprises a transparent substrate, a window layer, a buffer layer, a p-type layer comprising the first compound, a p⁺-type layer comprising the second compound, and a bottom contact electrode.

Also disclosed are embodiments of a compound having a formula I

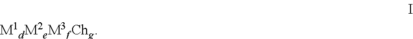

With reference to formula I, M¹ is selected from a transition metal, a group 13 element, a group 14 element, a group 15 element, or any combination thereof; M² is selected from a group 13 element, a group 14 element, a group 15 element, or any combination thereof; M³ is selected from a group 15 element, a group 16 element, a group 17 element, or any combination thereof; and Ch is selected from a group 15 element, a group 16 element, a group 17 element, or any combination thereof. Also with reference to formula I, d is from 10 to 14, e is from 0 to 14-d, f is from 2 to 6, and g is from 10 to 16. However, when M¹ is a transition metal and d+e is 12, then e is greater than 0; and when d+e is not 12, and M¹ is Cu, then e is greater than 0.

In some examples, M¹ is selected from Cu, Ag, Au, Mn, Zn, Mo, W, Ti, Zr, Hf, Cd, Al, Ga, In, Si, Ge, Sn, Fe, Co, Ni, V, Nb, Ta, or any combination thereof. In some embodiments, M² may be selected from Ga, In, Si, Ge, Sn, Pb, P, As, Sb, Bi, or any combination thereof; M³ may be selected from P, As, Sb, Bi, O, S, Se, Te, F, Cl, or any combination thereof; and/or Ch may be selected from P, As, Sb, Bi, O, S, Se, Te, F, Cl, or any combination thereof.

In certain particular embodiments, d is 10, e is 2, f is 4 and g is 13. In other particular embodiments, M¹ is Cu, M² is In, M³ is Sb and Ch is S, Se, or combination thereof.

In some embodiments M¹ is Cu. These compounds also satisfy formula II

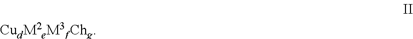

In some other embodiments M³ is Sb. These compounds have a formula III

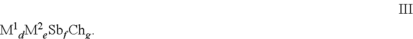

In certain other disclosed embodiments M¹ is Cu and M³ is Sb and the compounds have a formula IV

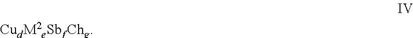

In some examples, Ch comprises Ch¹₁₋ₕCh²ₕ, where h is from 0 to 1, and Ch¹ and Ch² independently are selected from P, As, Sb, Bi, O, S, Se, Te, F, or Cl. In particular embodiments, compounds satisfying formula I also have a tetrahedrite crystal structure, such as a crystal structure with an I-43m space group.

Additionally, a method for using compounds with formula I is disclosed herein. The method comprises providing a compound having formula I, and using that compound in an electronic device, particularly a photovoltaic device.

Also disclosed is a composition comprising a tetrahedrite compound having formula V. In some embodiments the composition is formulated particularly for use in an electronic device, such as to form a component of a photovoltaic device. In some other embodiments the composition further comprises a binder, a second photovoltaic compound, a conductor material, a semiconductor material, or any combination thereof.

A method for making a thin layer comprising disclosed compounds also is disclosed. The method comprises providing a mixture of reactants, depositing a layer onto a substrate, and annealing. In certain embodiments the layer is annealed at a temperature of less than 300° C.

Additionally, disclosed herein is a device comprising at least one contact electrode, and at least one semiconductor layer comprising a tetrahedrite compound having formula V that contacts at least one contact electrode. In some embodiments, the device is a Schottky barrier diode, field effect transistor, thin film transistor, bipolar junction transistor, solar cell, light emitting diode, fuel cell, metal-semiconductor-metal diode, or metal-insulator-metal diode. In some examples, the device comprises a substrate, a bottom contact layer, a p⁺-type layer, a p-type layer, a buffer layer, a window layer, and a top contact electrode, where at least one of the p⁺-type layer and the p-type layer comprises the compound having formula V. In other examples, the device comprises a transparent substrate, a window layer, a buffer layer, a p-type layer, a p⁺-type layer, and a bottom contact electrode, where at least one of the p⁺-type layer and the p-type layer comprises the compound having the formula V.

Also a device comprising a contact electrode and a compound having a formula VII is disclosed herein.

The foregoing and other objects, features, and advantages of the invention will become more apparent from the following detailed description, which proceeds with reference to the accompanying figures.

### BRIEF DESCRIPTION OF THE DRAWINGS

FIG. 1 provides the crystal structure of the tetrahedrite compound Cu₁₂Sb₄S₁₃, having the formula A₆B₆(CX₃)₄Y₁₃, where A and B are Cu, C is Sb, and X and Y are S.

FIG. 2 provides a portion of the tetrahedrite crystal structure composed of AX₄ corner-connected tetrahedral frameworks.

FIG. 3 provides a portion of the tetrahedrite crystal structure comprising a cavity polyhedron composed of BX₂Y and CX₃.

FIG. 4 provides the X-ray diffraction pattern of synthetic powder samples Cu₁₀Mn₂Sb₄S₁₃, Cu₁₀Fe₂Sb₄S₁₃, Cu₁₀CO₂Sb₄S₁₃, Cu₁₀Ni₂Sb₄S₁₃, Cu₁₀Cu₂Sb₄S₁₃, Cu₁₀Zn₂Sb₄S₁₃, all with substitution at the A sites, and the simulated X-ray pattern of Powder Diffraction File (PDF) card No. 00-024-1318 for Cu₁₂Sb₄S₁₃ as a reference.

FIG. 5 provides the X-ray diffraction pattern of synthetic powder sample Cu₁₂Te₄S₁₃, an exemplary tetrahedrite compound with substitution at the C sites, and the simulated X-ray pattern of PDF card No. 00-024-1318 for Cu₁₂Sb₄S₁₃ as a reference.

FIG. 6 provides the X-ray diffraction spectra of synthetic powder samples having a formula Cu₁₀Zn₂Sb₄(S₁₋ₓSeₓ)₁₃, where x is 0, 0.25, 0.50, 0.75 and 1, as exemplary tetrahedrite compounds with substitutions at the A, X and Y sites; along with the simulated X-ray pattern of PDF card No. 00-024-1318 for Cu₁₂Sb₄S₁₃ as a reference.

FIG. 7 provides plots of calculated total density of states versus energy (eV), for the density of states (DOS) near the conduction band minimum (CBM), from density-functional theory (DFT) calculations of CuInSe₂, Cu₃SbS₄, CuSbS₂, and Cu₁₂Sb₄S₁₃.

FIG. 8 provides plots of the absorption coefficient (cm⁻¹) versus band gap normalized energy (eV-E_{G}), for CuInSe₂, Cu₃SbS₄, CuSbS₂, CdTe and Cu₁₂Sb₄S₁₃ thin films, clearly showing the abrupt onset of absorption near the band gap of examples of the disclosed materials.

FIG. 9 provides plots of energy versus wavevector, indicating the energy band structure of Cu₁₂Sb₄S₁₃ from DFT calculations.

FIG. 10 provides plots of the absorption coefficient (cm′) versus energy (eV), for Cu₁₀Mn₂Sb₄S₁₃, Cu₁₀Zn₂Sb₄S₁₃, Cu₁₂Sb₄S₁₃, Cu₁₁InSb₄S₁₃, Cu₁₀Zn₂Sb₄Se₁₃ thin films.

FIG. 11 provides plots of resistivity (Ohm m) versus temperature (K), indicating the temperature-dependent resistance of Cu₁₂Sb₄S₁₃ and Cu₁₀Mn₂Sb₄S₁₃.

FIG. 12 provides the X-ray diffraction pattern of tetrahedrite thin films Cu₁₀Zn₂Sb₄S₁₃ and Cu₁₀Zn₂Sb₄Se₁₃ and the simulated X-ray pattern of PDF card No. 00-024-1318 for Cu₁₂Sb₄S₁₃ as a reference.

FIG. 13 provides normalized plots of measured diffuse reflectance [K/S (a.u.)] versus energy (eV) of bulk powder samples of Cu₁₀Zn₂Sb₄Se₁₃ and Cu₁₀Zn₂Sb₄S₁₃, indicating a band gap of 1.36 and 1.8 eV, respectively.

FIG. 14 provides plots of α_{1/2} and α² versus energy for E (indirect) and E (direct), respectively, of a Cu₁₀Zn₂Sb₄Se₁₃ thin film, indicating that the energy difference between direct and indirect gap is <0.02 eV.

FIG. 15 provides the orthorhombic crystal structure, enargite-type, adopted by Cu₃PS₄, Cu₃PSe₄, and Cu₃AsS₄

FIG. 16 provides a tetragonal crystal structure adopted by other Cu—V—VI compounds such as Cu₃SbS₄ and Cu₃AsSe₄, with space group I42m.

FIG. 17 provides the cubic crystal structure of Cu—V—VI semiconductors adopted by Cu₃VS₄, Cu₃NbS₄ and Cu₃TaS₄.

FIG. 18 provides X-ray diffraction patterns for Cu₃PS₄₋ₓSeₓ (x is from 0 to 4) solid solutions and the calculated patterns from ICSD for Cu₃PSe₄ (#95412) and Cu₃PS₄ (#412240).

FIG. 19 provides X-ray diffraction patterns for Cu₃PₓAs₁₋ₓS₄ (x is from 0 to 1) solid solutions of the orthorhombic enargite structure and the calculated patterns from the Inorganic Crystal Structure Database (ICSD) for Cu₃PS₄ (#412240), and Cu₃AsS₄ (#413350).

FIG. 20 provides X-ray diffraction patterns for Cu₃AsSₓSe₄₋ₓ (x is from 0 to 3) solid solutions and the calculated patterns from ICSD for Cu₃AsS₄ (#413350) and Cu₃AsSe₄ (#610359).

FIG. 21 provides X-ray diffraction patterns for Cu₃P₁₋ₓAsₓSe₄ (x is from 0 to 1) solid solutions and the calculated patterns from ICSD for Cu₃PSe₄ (#41906) and Cu₃AsSe₄ (#610359).

FIG. 22 provides X-ray diffraction patterns for Cu₃As₁₋ₓSbₓS₄ (x is from 0 to 1) solid solutions.

FIG. 23 provides XRD patterns of Cu₃SbS₄₋ₓSeₓ (x=0.5 and 1), referenced to Cu₃SbS₄ (ICSD#412239)

FIG. 24 provides XRD patterns of example Mn, Zn and Ag doped Cu₃SbS₄, referenced to ICSD#412239.

FIG. 25 is a graph of unit cell volume versus band gap for certain exemplary compounds.

FIG. 26 provides graphs illustrating the optical band gaps of exemplary compounds of formula VII disclosed herein for PV device application.

FIG. 27 provides diffuse reflectance spectra of Cu₃SbS_{4-f}Se_{f} for f=0.5 and 1, exhibiting band gaps of 0.8 eV and 0.7 eV, respectively.

FIG. 28 provides graphs illustrating the resistivity of exemplary compounds disclosed herein.

FIG. 29 provides graphs illustrating the hole carrier concentrations of exemplary compounds disclosed herein for PV device application.

FIG. 30 provides graphs illustrating the hole mobilities of exemplary compounds disclosed herein for PV device application.

FIG. 31 provides XRD patterns of Cu₃SbS₄ materials substituted with Te for Sb (referenced to ICSD#412239).

FIG. 32 is a schematic, cross-sectional view of an exemplary photovoltaic cell.

FIG. 33 is a graph of simulated efficiency versus thickness, illustrating the change in efficiency of the absorber layer with changes in thickness.

FIG. 34 is a schematic, cross-sectional view of one exemplary configuration of a photovoltaic device with a superstrate configuration comprising a tetrahedrite compound.

FIG. 35 is a schematic, cross-sectional view of one exemplary configuration of a photovoltaic device comprising a tetrahedrite compound.

FIG. 36 is a schematic, cross-sectional view of an exemplary single-junction cell.

FIG. 37 is a schematic, cross-sectional view of one exemplary configuration of a photovoltaic device comprising a C—V—VI compound.

FIG. 38 is a schematic, cross-sectional view of one exemplary configuration of a photovoltaic device with a superstrate configuration comprising a C—V—VI compound.

FIG. 39 is a schematic, cross-sectional view of an exemplary single-junction cell comprising a p⁺-layer.

FIG. 40 is a schematic, cross-sectional view of one exemplary configuration of a photovoltaic device comprising both a C—V—VI compound and a tetrahedrite compound.

FIG. 41 is a schematic, cross-sectional view of one exemplary configuration of a photovoltaic device with a superstrate configuration comprising both a C—V—VI compound and a tetrahedrite compound.

FIG. 42 is a schematic, cross-sectional view of an exemplary multi-junction cell.

FIG. 43 is a schematic, cross-sectional view of one exemplary configuration of a bipolar junction transistor.

FIG. 44 is a schematic, cross-sectional view of one exemplary configuration of a field effect transistor.

FIG. 45 is a schematic, cross-sectional view of one configuration of an exemplary thin-film transistor.

FIG. 46 is a schematic, cross-sectional view of one exemplary configuration of a Schottky barrier diode.

FIG. 47 is a schematic, cross-sectional view of one exemplary configuration of a light emitting diode.

FIG. 48 is a schematic, cross-sectional view of one exemplary configuration of a fuel cell.

FIG. 49 provides a plot of simulated efficiency (%) versus absorber layer thickness (μm) for a Cu₁₀Zn₂Sb₄Se₁₃-based TFSC, indicating that efficiencies greater than 20% can be achieved with an absorber layer thickness greater than 200 nm.

FIG. 50 provides a plot of simulated efficiency (%) versus midgap defect density cm⁻³) for a Cu₁₀Zn₂Sb₄Se₁₃-based TFSC, indicating that efficiencies of 13% can be obtained even when the defect density in the absorber material is as high as 10¹⁶ cm⁻³.

FIG. 51 provides a plot of simulated current density (mA cm⁻²) versus voltage (V) for a TFSC with a 300 nm thick Cu₁₀Zn₂Sb₄Se₁₃ absorber layer and a minority carrier lifetime of 1 ns, indicating that the open circuit voltage (V_{oc}) is 0.92 V and the short circuit current (J_{sc}) is 27.2 mA/cm², thereby providing a 20.8% efficient TFSC.

FIG. 52 provides a plot of simulated quantum efficiency (QE; %) versus wavelength (nm), indicating the QE characteristics of a TFSC with a 300 nm thick Cu₁₀Zn₂Sb₄Se₁₃ absorber layer, and demonstrating that the QE approaches 90% for wavelengths between 530-780 nm.

FIG. 53 provides the X-ray diffraction spectra of Cu₁₂Sb₄S₁₃, Cu₁₀Mn₂Sb₄S₁₃, Cu₁₀Zn₁₂Sb₄S₁₃, and Cu₁₁InSb₄S₁₃ thin films, and the simulated X-ray pattern of PDF card No. 00-024-1318 for Cu₁₂Sb₄S₁₃ as a reference.

FIG. 54 provides an SEM image of a simple photovoltaic device of FIG. 52 using a u₃SbS₄ semiconductor absorber layer prepared by one embodiment of the disclosed method.

FIG. 55 is a graph of current density versus voltage providing a current-voltage measurement for a working example of a C—V—CI solar cell according to one embodiment of the present invention.

### DETAILED DESCRIPTION

### I. Definitions

Absorber layer—refers to a material layer comprising a semiconductor that is used to generate and separate photoinduced carriers, and more typically refers to a p-type semiconductor with a hole carrier concentration less than 5×10¹⁷ cm⁻³.

Band gap—the energy gap in which no electron states can exist. In insulators and semiconductors this refers to the energy difference between the top of the valence band (valence band maxima) and the bottom of the conduction band (conduction band minima). Conductors have no band gap, as the conduction band overlaps with the valence band.

Conduction band—the range of electron energies sufficient to free an electron from binding with its atom, enabling it to move freely within an atomic lattice as a delocalized electron.

Conduction band minima (CBM)—is the lowest energy level in the conduction band.

Density of states (DOS)—describes the number of states per interval of energy at each energy level that are available to be occupied by electrons. The density distributions are continuous, not discrete, and are an average over time and space domains occupied by a system.

p+ layer—refers to a material layer comprising a semiconductor with a hole majority carrier concentration greater than 5×10¹⁷ cm³, which often is used, for example, as a hole carrier extraction layer in a PV device.

PV—photovoltaic.

“Providing a compound or composition comprising the compound” refers to a person, entity or other manufacturer who makes the compound or composition comprising the compound and provides instructions for its use, such as by establishing the manner and/or timing of using the compound or composition; a supplier who supplies the compound or composition and provides instructions for its use, establishing the manner and/or timing of using the compound or composition; a facility that uses the compound or composition; and/or a subject who uses the compound or composition themselves. The manufacturer, supplier, facility and/or subject may act jointly or as a joint enterprise by agreement, by a common purpose, a community of pecuniary interest, and/or substantially equal say in direction of using the compound or composition. Alternatively, or additionally, the manufacturer, supplier, facility and/or subject may condition participation in an activity or receipt of a benefit upon performance of a step or steps of the method of using the compound or composition disclosed herein, and establish the manner and/or timing of that performance.

Quantum efficiency (QE)—the percentage of photons hitting a device's photoreactive surface that produce charge carriers, and as such can be a measurement of a photosensitive device's electrical sensitivity to light. It is often measured over a range of different wavelengths to characterize a device's efficiency at each photon energy level.

Tetrahedrite compound—a compound with a tetrahedrite crystal structure. For example, tennanite (Cu₁₂As₄S₁₃) and tetrahedrite (Cu₁₂Sb₄S₁₃) have the same tetrahedrite crystal structure; accordingly, both are referred to as tetrahedrite compounds herein. Additionally, compounds that have the tetrahedrite crystal structure but have some vacant sites or some interstitial substitutions may also have a tetrahedrite crystal structure, and therefore are also included as tetrahedrite compounds, for example goldfieldite (Cu₁₀Te₄S₁₃).

Transition metal—refers to any element from groups 3-12 of the periodic table, including the lanthanide and actinide series.

Trap density—the density of traps created as a result of impurities or defects in a material. The charged trap states capture electrons excited from the valence band to the conduction band. The concentration of trap states can affect transport properties of a material.

Valence band—the highest range of electron energies in which electrons are still bound to individual atoms.

Valence band maxima (VBM)—the highest energy level in which the electron is still bound to an individual atom.

### II. Tetrahedrite Compounds

A. Overview

Certain disclosed compounds have a formula I

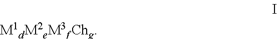

With reference to formula I, M¹ is selected from a transition metal, a group 13 element, a group 14 element, a group 15 element or a combination thereof; M² is a cation with ns² electronic configuration, which is selected from a group 13 element, a group 14 element, a group 15 element or a combination thereof; M³ and Ch independently are selected from a group 15 element, a group 16 element or a combination thereof. Also with reference to formula I, d is from about 10 to about 14, e is from about 0 to about 14-d, f is from about 2 to about 6, and g is from about 10 to about 16. However, when M¹ is a transition metal and d+e is 12, then e is greater than 0, and when d+e is not 12, and M¹ is Cu, then e is greater than 0.

In some embodiments M¹ is selected from Cu, Ag, Au, Mn, Zn, Mo, W, Ti, Zr, Hf, Cd, Al, Ga, In, Si, Ge, Sn, Fe, Co, Ni, V, Nb, Ta, or any combination thereof. In other embodiments, M² is selected from Ga, In, Si, Ge, Sn, Pb, P, As, Sb, Bi or a combination thereof. In some other embodiments M³ and Ch independently are selected from P, As, Sb, Bi, O, S, Se, Te, F, Cl or a combination thereof.

In some embodiments, M¹ is selected from Cu, Ag, or combinations thereof, M² is selected from Cu, Ag, Au, Mn, Zn, Mo, W, Ti, Zr, Hf, Cd, Al, Ga, In, Si, Ge, Sn, Fe, Co, Ni, V, Nb, Ta, or combinations thereof, M³ is selected from P, As, Sb, Te, F, Cl, or combinations thereof, Ch is selected from S, Se or a combination thereof, and d is from 10 to 12, e is from 1 to 2, f=4 and g=13.

In some working embodiments M¹ was Cu, leading to compounds having a formula II

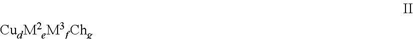

where M², M³, Ch, d, e, f and g are as defined with respect to formula I.

In another working embodiment M³ was Sb, leading to compounds having a formula III

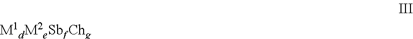

where M¹, M², Ch, d, e, f and g are as defined with respect to formula I.

In particular working embodiments M¹ was Cu and M³ was Sb, leading to compounds having a formula IV

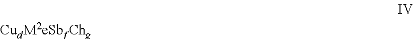

where M², Ch, d, e, f and g are as defined with respect to formula I.

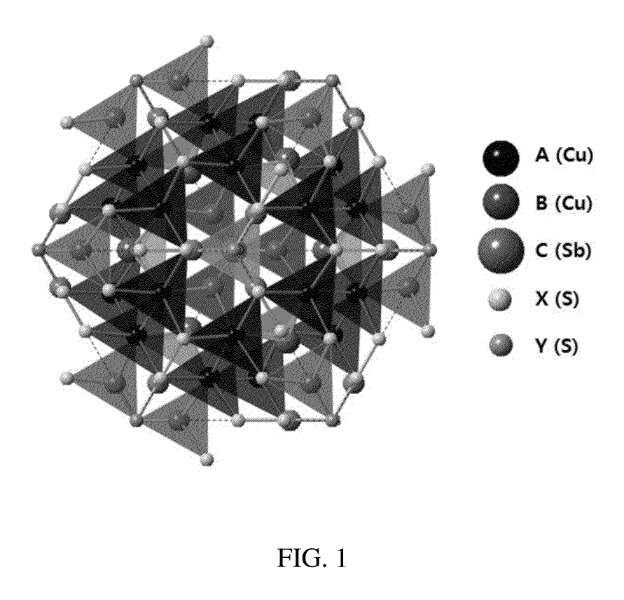

Typically, compounds having formula I have a tetrahedrite crystal structure with a space group I-43m (FIG. 1). The chemical formula of a tetrahedrite compound can be rationalized from a crystal structural point of view as A₆B₆[CX₃]₄Y. For example, in Cu₁₂Sb₄S₁₃ six of the Cu atoms occupy tetrahedral A sites and the remaining Cu atoms occupy the B sites forming triangular planes, the four Sb atoms occupy the C sites occupying triangular pyramids, and the sulfur atoms are at positions X and Y.

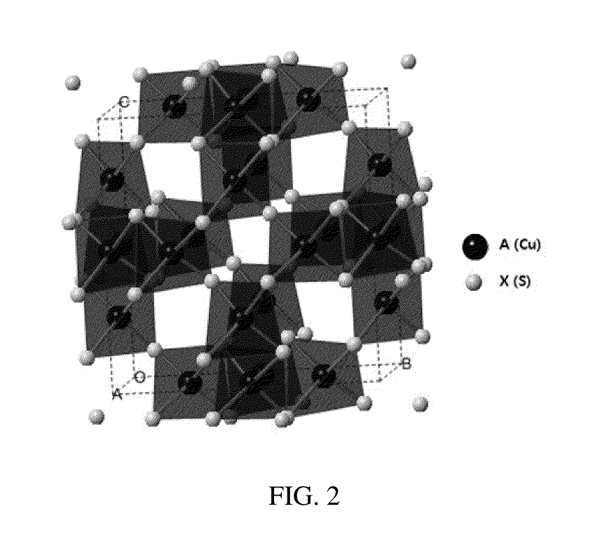

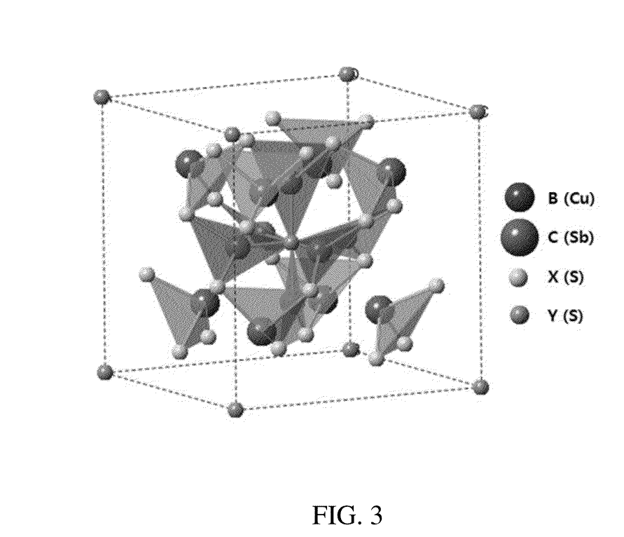

In various embodiments, the crystal structure of the tetrahedrite can be divided into two sub-units: outer frameworks formed by tetrahedral AX₄ units as shown in FIG. 2; and an inner cavity polyhedron formed from the combination of BX₂Y and CX₃ shown in FIG. 3. The framework structure is the form of corner-sharing tetrahedral, and a cavity polyhedron that is isolated within the framework. Since absorption of light by the material is enhanced by an isolated atom and/or an atom with lone pair electrons, a tetrahedrite compound with a cavity polyhedron isolated within the framework can induce high absorption. Thus, disclosed tetrahedrite compounds can improve the efficiency of, for example, a photovoltaic device. Furthermore, since the frameworks are interconnected, carriers generated within a cavity polyhedron can move along the framework structure, thus showing high or at least comparable electrical performance with current materials used in absorber layers.

This rationalization of the crystal structure allows tetrahedrite compounds to be described by a formula V

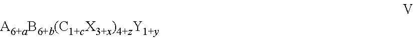

where a is from about −2.5 to about 2, b is from about −2 to about 2, c is from about −1 to about 1, x is from about −2 to about 2, z is from about −1 to about 1 and y is from about −1 to about 2, and A, B, and C independently can be selected from cations or combinations of cations from the periodic table of the elements, and X and Y independently can be selected from anions or combinations of anions from the periodic table of the elements.

Typically with reference to formula V, A and B independently are selected from a transition metal, a group 13 element, a group 14 element, a group 15 element or a combination thereof. C is selected from a transition metal, a group 15 element, a group 16 element or a combination thereof, and X and Y independently are selected from a group 15 element, a group 16 element or a combination thereof.

In some embodiments A and B independently are selected from Cu, Ag, Au, Mn, Zn, Mo, W, Ti, Zr, Hf, Cd, Al, Ga, In, Si, Ge, Sn, Zn, Mn, Fe, Co, Ni, V, Nb, Ta, Mo, W, or any combination thereof, C is selected from Ga, In, Si, Ge, Sn, Pb, P, As, Sb, Bi, Se, Te, or any combination thereof, and X and Y independently are selected from P, As, Sb, Bi, O, S, Se, Te, F, Cl, or a combination thereof.

In some embodiments A and B independently are cations with an oxidation state from greater than 0 to about 6+, preferable from greater than 0 to about 5+. The oxidation state maybe an integer value, or it may be a non-integer value. In some embodiments the oxidation state is selected from 1+, 2+, 3+, 4+, or 5+. In other embodiments the oxidation state is from about 0.5+ to about 1.5+. In particular embodiments A and/or B comprises Cu with an oxidation state from about 0.5+ to about 1.5+, more preferably from about 0.7+ to about 1.3+.

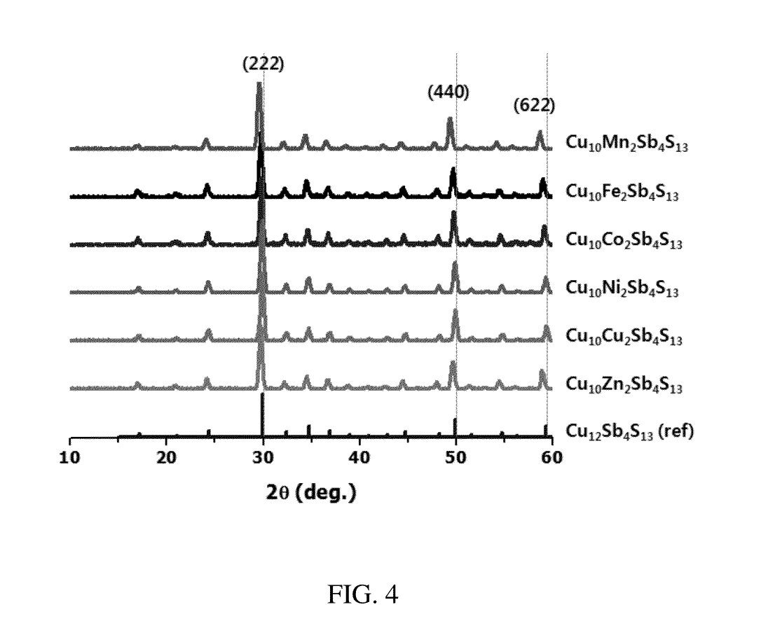

In particular working embodiments, tetrahedrite compounds were produced that had modifications at various sites of the crystal structure. Compounds having modifications at the A site had a formula Cu₄A₂Cu₆(SbS₃)₄S, where A was selected from Mn, Fe, Co, Ni and Zn. Exemplary working embodiments of such compounds include Cu₁₀Mn₂Sb₄S₁₃, Cu₁₀Fe₂Sb₄S₁₃, Cu₁₀Co₂Sb₄S₁₃, Cu₁₀Ni₂Sb₄S₁₃, and Cu₁₀Zn₂Sb₄S₁₃. FIG. 4 provides XRD patterns for synthetic compounds and for Cu₁₀Cu₂Sb₄S₁₃.

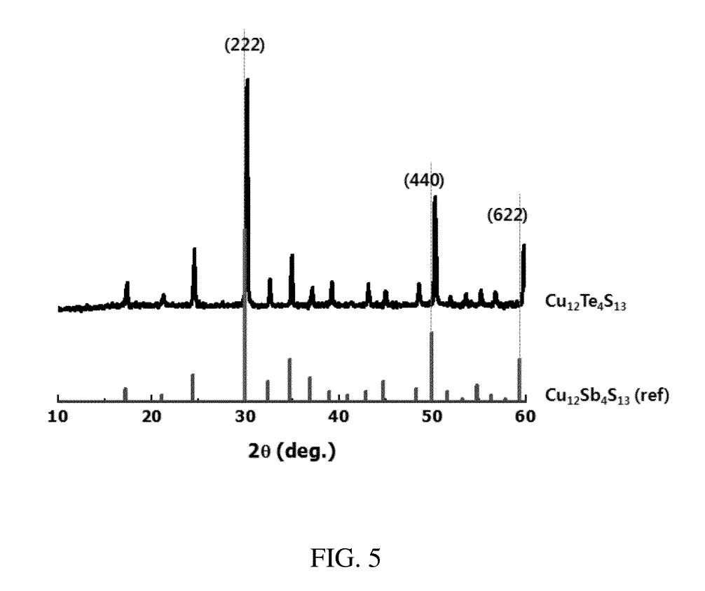

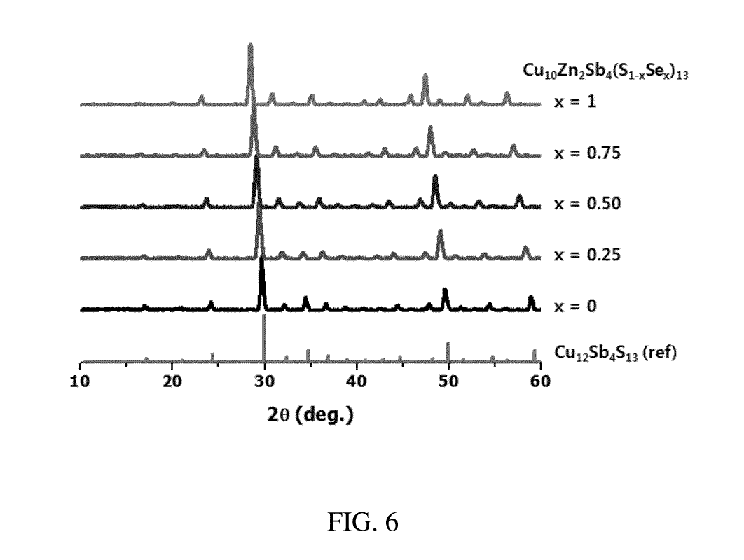

In another working embodiment, Cu₁₂Te₄S₁₃ with a Te substitution at the C site was produced. FIG. 5 provides XRD spectra of the synthetic compound. Also produced were compounds with a formula Cu₁₀Zn₂Sb₄(S₁₋ₓSeₓ)₁₃, where x was 0, 0.25, 0.50, 0.75 and 1. These compounds had Zn substitutions at the A and/or B sites and partial Se substitution at the X and Y sites (FIG. 6).

In particular working embodiments subscripts a, b, c, x, y and z of formula V are all zero, resulting in formula VI

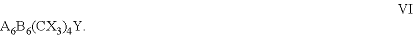

In some embodiments compounds having formula V are selected from Cu₁₂Sb₄S₁₃, Cu₁₀Mn₂Sb₄S₁₃, Cu₁₀Zn₂Sb₄S₁₃, Cu₁₀Fe₂Sb₄S₁₃, Cu₁₀Ni₂Sb₄S₁₃, Cu₁₀Sn₂Sb₄S₁₃, Cu₁₀Co₂Sb₄S₁₃, Cu₁₀Cr₂Sb₄S₁₃, Cu₁₀V₂Sb₄S₁₃, Cu₁₀Ti₂Sb₄S₁₃, Cu₁₀Nb₂Sb₄S₁₃, Cu₁₀Mo₂Sb₄S₁₃, Cu₁₀Ag₂Sb₄S₁₃, Cu₁₀Cd₂Sb₄S₁₃, Cu₁₀Ta₂Sb₄S₁₃, Cu₁₀W₂Sb₄S₁₃, Cu₁₁AuSb₄S₁₃, Cu₁₁WSb₄S₁₃, Cu₁₁TaSb₄S₁₃, Cu₁₁MoSb₄S₁₃, Cu₁₁NbSb₄S₁₃, Cu₁₁TiSb₄S₁₃, Cu₁₁HfSb₄S₁₃, Cu₁₁ZrSb₄S₁₃, Cu₁₁NiSb₄S₁₃, Cu₁₁CoSb₄S₁₃, Cu₁₁MnSb₄S₁₃, Cu₁₁FeSb₄S₁₃, Cu₁₁InSb₄S₁₃, Cu₁₁AlSb₄S₁₃, Cu₁₁GaSb₄S₁₃, Cu₁₀Mn₂Sb₄Se₁₃, Cu₁₀Zn₂Sb₄Se₁₃, Cu₁₀Fe₂Sb₄Se₁₃, Cu₁₀Ni₂Sb₄Se₁₃, Cu₁₀Co₂Sb₄Se₁₃, Cu₁₀V₂Sb₄Se₁₃, Cu₁₀Ti₂Sb₄Se₁₃, Cu₁₀Nb₂Sb₄Se₁₃, Cu₁₀Mo₂Sb₄Se₁₃, Cu₁₀Ag₂Sb₄Se₁₃, Cu₁₀Cd₂Sb₄Se₁₃, Cu₁₀Ta₂Sb₄Se₁₃, Cu₁₀W₂Sb₄Se₁₃, Cu₁₁AuSb₄Se₁₃, Cu₁₁WSb₄Se₁₃, Cu₁₁TaSb₄Se₁₃, Cu₁₁MoSb₄Se₁₃, Cu₁₁NbSb₄Se₁₃, Cu₁₁ZrSb₄Se₁₃, Cu₁₁NiSb₄Se₁₃, Cu₁₁CoSb₄Se₁₃, Cu₁₁MnSb₄Se₁₃Cu₁₁FeSb₄Se₁₃, Cu₁₁InSb₄Se₁₃, Cu₁₁AlSb₄Se₁₃, Cu₁₁GaSb₄Se₁₃, Cu₁₂P₄S₁₃, Cu₁₂Bi₄S₁₃, Cu₁₂Te₄S₁₃, Cu₁₂P₄Se₁₃, Cu₁₂As₄Se₁₃, Cu₁₂As₄S₁₃, Cu₁₂Sb₄Se₁₃, Cu₁₂Sb₄S₁₃, Cu₁₂Bi₄Se₁₃, Cu₁₂Te₄Se₁₃, Cu₁₀Sb₄S₁₃, Cu₁₀As₄S₁₃, Cu₁₀P₄S₁₃, Cu₁₀Bi₄S₁₃, Cu₁₀Te₄S₁₃, Cu₁₀Sb₄S₁₃, Cu₁₀As₄Se₁₃, Cu₁₀P₄Se₁₃, Cu₁₀Bi₄Se₁₃, Cu₁₀Te₄Se₁₃, Cu₁₀Sb₄Se₁₃, Cu₁₄Sb₄S₁₃, Cu₁₄P₄Se₁₃, Cu₁₄P₄S₁₃, Cu₁₄As₄Se₁₃, Cu₁₄As₄S₁₃, Cu₁₄Bi₄Se₁₃, Cu₁₄Bi₄S₁₃, Cu₁₀Zn₂Sb₄(S_{0.75} Se_{0.25})₁₃, Cu₁₀Zn₂Sb₄(S_{0.5} Se_{0.5})₁₃, Cu₁₀Zn₂Sb₄(S_{0.25} Se_{0.75})₁₃, Cu₁₀Zn₂Sb₄Se₁₃, Cu₁₀TiSb₄S₁₃, Cu₁₀HfSb₄S₁₃, Cu₁₀ZrSb₄S₁₃, Cu₁₀TiSb₄Se₁₃, Cu₁₀HfSb₄Se₁₃, Cu₁₀ZrSb₄Se₁₃, Cu_{11.5}Zn_{0.5}Sb₄S₁₃, Cu₁₁ZnSb₄S₁₃, Cu_{10.5}Zn_{1.5}Sb₄S₁₃, Cu₁₀Zn₂Sb₄S₁₃, Cu_{11.5}Mn_{0.5}Sb₄S₁₃, Cu₁₁MnSb₄S₁₃, Cu_{10.5}Mn_{1.5}Sb₄S₁₃, Cu₁₀Mn₂Sb₄S₁₃, Cu₁₁FeSb₄S₁₃, Cu₉AgZn₂Sb₄S₁₃, Cu₈Ag₂Zn₂Sb₄S₁₃, Cu₇Ag₃Zn₂Sb₄S₁₃, Cu₉AgMn₂Sb₄S₁₃, Cu₈Ag₂Mn₂Sb₄S₁₃, Cu₇Ag₃Mn₂Sb₄S₁₃, Cu_{9.75}Ag_{0.25}Te₄S₁₃, Cu_{9.5}Ag_{0.5}Te₄S₁₃, Cu_{9.25}Ag_{0.75}Te₄S₁₃ or Cu₉AgTe₄S₁₃.

Particular working embodiments are Cu₁₂Sb₄S₁₃, Cu₁₂₋ₓZnₓSb₄S₁₃ (x=0.5, 1, 1.5, 2), Cu₁₂₋ₓMnₓSb₄S₁₃ (x=0.5, 1, 1.5, 2), Cu₁₁FeSb₄S₁₃, Cu₁₀Fe₂Sb₄S₁₃, Cu₁₀CO₂Sb₄S₁₃, Cu₁₀Ni₂Sb₄S₁₃, Cu₁₀Zn₂Sb₄(S₁₋ₓSeₓ)₁₃ (x=0.25, 0.5, 0.75, 1), Cu₁₀₋ₓAgₓZn₂Sb₄S₁₃ (x=1, 2, 3), Cu₁₀₋ₓAgₓMn₂Sb₄S₁₃ (x=1, 2, 3), Cu₁₁InSb₄S₁₃, Cu₁₀Sn₂Sb₄S₁₃, Cu₁₀Te₄S₁₃, Cu₁₂Te₄S₁₃, Cu₁₀₋ₓAgₓTe₄S₁₃ (x=0, 0.25, 0.5, 0.75, 1).

In some embodiments one or more of the A and/or B sites are vacant, i.e. with reference to formula V, (6+a)+(6+b) is less than 12. In a particular working embodiment, two A sites were vacant, the remaining As and Bs were Cu, C was Te, and X and Y were S, leading to the compound Cu₁₀Te₄S₁₃.

Certain disclosed compound embodiments include one or more interstitial substitutions. For example, with reference to formula V, (6+a)+(6+b) may be greater than 12, such as in compound Cu₁₄Sb₄S₁₃, which has 2 interstitial Cu ions.

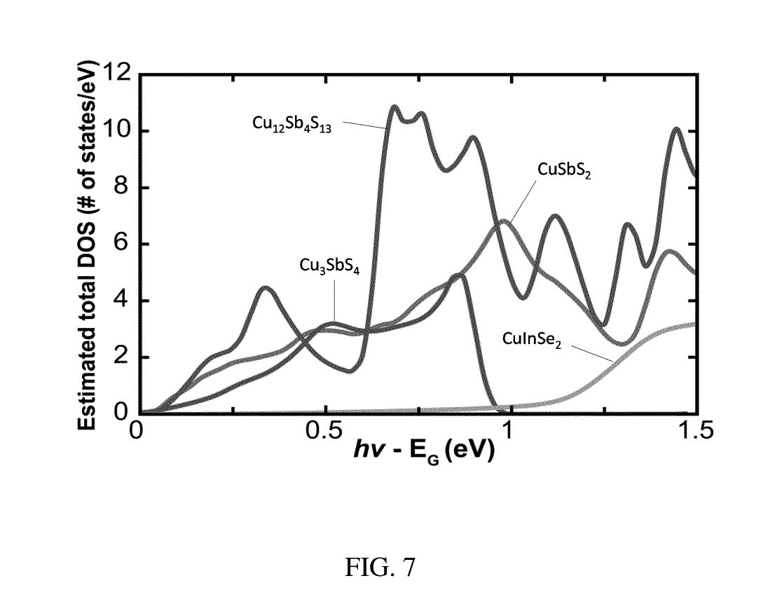

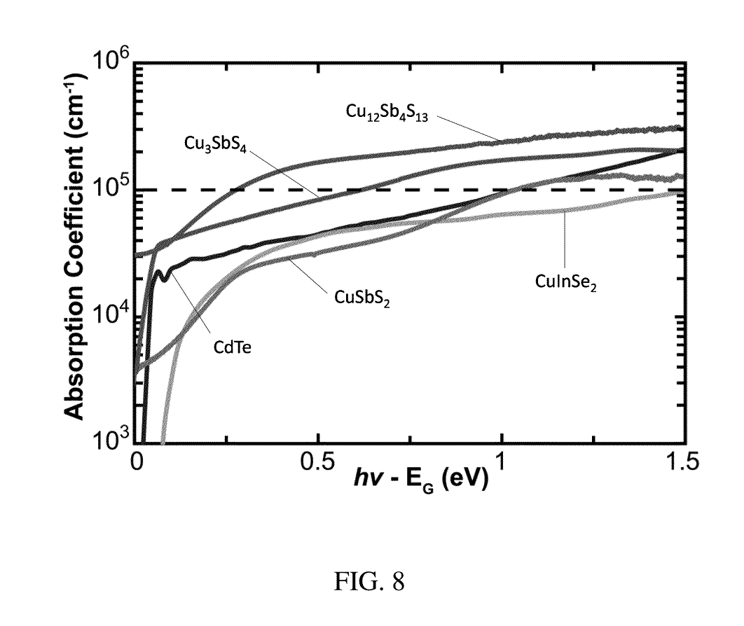

Famatinite (Cu₃SbS₄) has a tetragonal crystal structure (space group I-42m), containing high-valence Sb⁵⁺ atoms isolated within the structure. The isolated Sb⁵⁺ atoms lead to a small dispersion for the Sb-derived s bands, which translates to a high DOS near the conduction band minimum (CBM) (FIG. 7). In contrast, chalcostibite (CuSbS₂, space group Pnma) has low-valence Sb³⁺ atoms and has a distorted crystal structure due to the effect of lone-pair electrons. In this distorted environment, low-valence Sb³⁺ atoms also result in a low dispersion for Sb s-like bands and p-like bands, and present a higher DOS near the valence band maximum (VBM) and the CBM, respectively. In both Cu₃SbS₄ and CuSbS₂ compounds, these flat-band characters near the VBM and/or the CBM result in a high joint DOS, leading to strong absorption, coupled with Cu d-like orbitals concentrated near the VBM (FIG. 8).

The same considerations, flat-band characteristics and strong absorption, apply to Cu₁₂Sb₄S₁₃ with low-valence Sb³⁺ atoms forming a cavity polyhedron within the structure. Although CuSbS₂ and Cu₁₂Sb₄S₁₃ both have low-valence Sb₃₊ atoms, and the band character is similar near the VBM and CBM, Cu₁₂Sb₄S₁₃ exhibits considerably narrower Sb s- and p-like bands, while increasing the band gap as compared to CuSbS₂. Since these flat-band characters near both the VBM and the CBM contribute to a high joint DOS, electric-dipole-allowed Cu d→Sb p, S p and Sb s→Sb p transitions enhance the absorption strength of Cu₁₂Sb₄S₁₃The Cu₁₂Sb₄S₁₃ thin film shows exceptionally strong absorption with an abrupt onset near the band gap in comparison to conventional thin-film absorbers, such as CuInSe₂ and CdTe (FIG. 8). Without being bound to a particular theory, this result suggests that there is an additional effect from a cavity polyhedron isolated in Cu₁₂Sb₄S₁₃, due to the combined effects of both isolation and low valence.

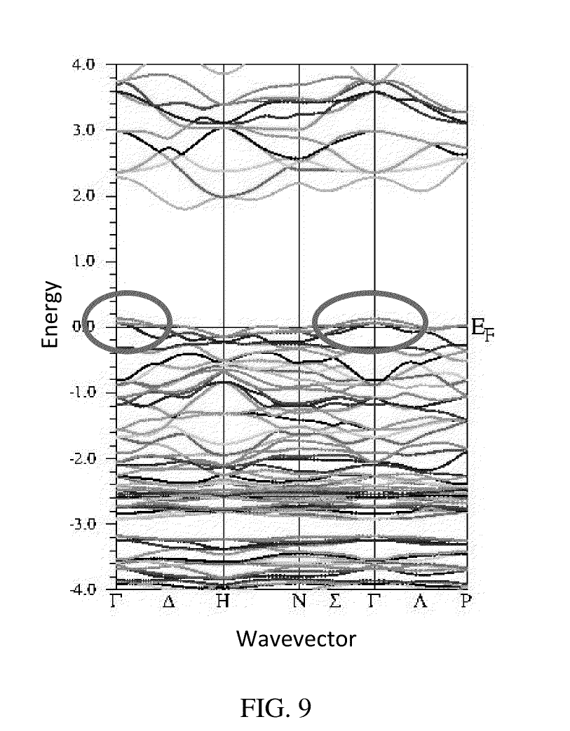

In various embodiments, the electrical and optical properties of tetrahedrite compounds can be tuned by varying the composition. The electronic band structure of a solid describes those ranges of energy that an electron within the solid may have, and ranges of energy that it may not have. FIG. 9 shows the band structure of Cu₁₂Sb₄S₁₃ from DFT calculations. The y-axis represents the energy (eV) and x-axis the wavevector, k. The wavevector takes on any value inside the Brillouin zone, which is a polyhedron in wavevector space that is related to the crystal's structure and lattice. Therefore, the x-axis is represented by the special symmetry points. Usually, the special high symmetry point (Γ) has the maximal-energy state in the valence band and sets the Fermi level, E_{F}, as 0 eV. The circled areas in FIG. 9 indicate that for Cu₁₂Sb₄S₁₃ the Fermi level is within the valence band. This suggests that Cu₁₂Sb₄S₁₃ exhibits degenerate semiconductor behavior. Without being bound to a particular theory, a possible explanation of this behavior could be found in the oxidation states of the Cu atoms. For charge balance, ten of the Cu atoms in Cu₁₂Sb₄S₁₃ should be monovalent and the remaining two Cu atoms should be divalent, indicating the formal oxidation state of Cu is +14/12, or +7/6. Charge transfer along the tetrahedral A site framework due to mixed valency could induce the relatively high conductivity of Cu₁₂Sb₄S₁₃, similar to mixed valence in Fe₃O₄. The mixed valency is one possible explanation for the relatively low resistivity of 0.001-0.004 Ωcm measured in Cu₁₂Sb₄S₁₃ thin-films and powders (listed in Table 1, below). This results in a degenerate semiconductor material, with a carrier concentration greater than 10²⁰ cm⁻³. A degenerate p-type semiconductor is not desirable as an absorber layers in TFSCs, which typically have carrier concentrations between 10¹⁴-10¹⁶ cm⁻³. However, such high carrier concentration coupled with a wide band gap makes Cu₁₂SbS₄ an outstanding candidate for a p+ layer in a PV cell, enabling efficient collection of photogenerated hole carriers in the adjacent p-absorber layer.

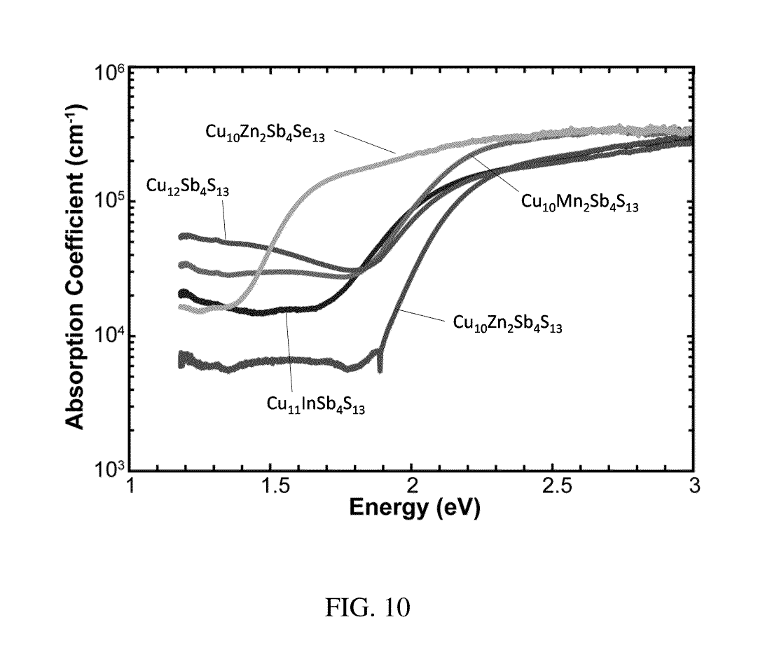

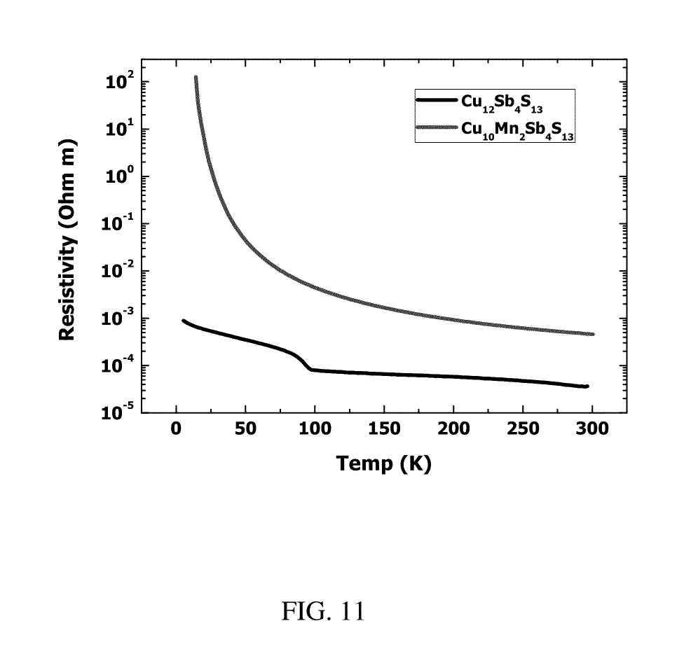

Substitution of A, B, C, X, and/or Y sites with different elements, as described below, can modify the formal oxidation state of cations A and B. By modifying the tetrahedrite compounds so that they have an exact charge balance, i.e., the formal oxidation state of the cations is an integer, such as Cu¹⁺, the valence bands will be completely filled and the compounds will exhibit non-degenerate semiconductor behavior. For example, substitution of the A sites in the CuS₄ tetrahedron with different elements having formal oxidation states of 2+ or 3+ can make the formal oxidation state of the Cu be 1+, e.g. in Cu¹⁺₁₀Zn²⁺₂Sb³⁺₄S²⁻₁₃, Cu¹⁺₁₀Mn²⁺₂Sb³⁺₄S²⁻₁₃, and Cu¹⁺₁₁In³⁺Sb³⁺₄S²⁻₁₃. Hence, the tetrahedrite compounds where Cu has a formal oxidation state of Cu¹⁺ show a strong reduction in sub-gap absorption (FIG. 10) and increased resistivity (FIG. 11), making them suitable materials for semiconductor devices, such as photovoltaics.

Additionally, a tetrahedrite compound with a Te substitution of all Sb sites can be a degenerate semiconductor, with a formal oxidation state of Cu^{5/6+}, i.e. Cu^{5/6+}₁₂Te⁴⁺₄S²⁻₁₃. However, in this case, a non-degenerate semiconductor material with two vacant sites, known as a goldfieldite mineral, can be formed having a formula M¹₁₀M²₄Ch₁₃ and a formal oxidation state of Cu¹⁺ for example, Cu¹⁺₁₀Te⁴⁺₄S²⁻₁₃. Using this particular compound as an example, the crystal structure can be rationalized as Cu₄Cu₆[TeS₃]₄S, where four of the Cu atoms occupy four-coordinate, distorted tetrahedral sites and the others occupy three-coordinate triangular sites. Comparing this structure to Sb-based tetrahedrite compounds with a formula M¹₁₂M²₄Ch₁₃, two M¹ locations in the tetrahedral sites are vacant and the Sb sites are all substituted with Te. Similar to tetrahedrite compounds with a formula M¹₁₂M²₄Ch₁₃, the CuS₄ units are condensed via vertex-sharing into a highly defective framework. In the goldfieldite compounds, however, the occupied tetrahedral CuS₄ sites only have d¹⁰ Cu¹⁺ atoms, to balance the formal oxidation charge resulting from the replacement of Sb³⁺ by Te⁴⁺, and the two vacant sites are randomly distributed. Conversely, the tetrahedral sites in Cu₁₂Sb₄S₁₃ are occupied by a mixture of Cu¹⁺ and Cu²⁺. Therefore, tetrahedrite compounds can be expressed at least as M¹₁₂₋ₓM²₄Ch₁₃ (0≦x≦2) based on the oxidation states of cations M¹ and M².

Additionally, all substituted tetrahedrite compounds containing only Cu¹⁺ in the A sites are non-degenerate, including Cu¹⁺₁₁Sb³⁺Te⁴⁺³S²⁻₁₃. Therefore, any tetrahedrite compound with a formal oxidation state of Cu¹⁺ can be used to make an absorber layer due to non-degeneracy. And any tetrahedrite compound with formal oxidation states of Cu^{7/6+} and/or Cu^{5/6+} can be used to make a contact layer due to degeneracy. Similarly, the above modification in composition was utilized to tune optical band gaps, as shown in FIG. 10.

Additionally, tetrahedrite compounds can have interstitial substitutions. An interstitial substitution happens when a crystal is formed with one or more additional atoms, in addition to its usual complement, and these atoms locate in voids within the crystal structure, such that the shape of the crystal structure is substantially unaffected. These interstitial substitutions provide the ability to modulate carrier concentrations by controlling the formal oxidation states of Cu, like the substitution of A, B, C, X, and/or Y described above. For example, Cu^{7/6+}₁₂Sb³⁺₄S²⁻₁₃ with two Cu interstitial substitutions can change a formal oxidation state of Cu from 7/6+ to 1+, by forming Cu¹⁺₁₄Sb³⁺₄S²⁻₁₃. Cu₁₄Sb₄S₁₃, with a formal oxidation state of Cu¹⁺ completely fills the valence bands and exhibit non-degenerate semiconductor behavior for a good absorber.

Additionally, tetrahedrite compounds with one or more substitutions provide the ability to modulate carrier concentrations and/or a carrier type via controlling the formal oxidation states of Cu as shown in FIG. 11 and Table 1.

TABLE 1
Optical And Electrical Properties from Experimental
Measurements of a Selection of Tetrahedrite Compounds
Made According to Disclosed Embodiments

| | | | | Seebeck |
|---|---|---|---|---|
| | | Band Gap | Resistivity | coefficient |
| Composition | | E_{G} [eV] | ρ [Ω cm] | S [μV/K] |
| Cu₁₂Sb₄S₁₃ | Powder | — | 0.004 | 75 |
| | Thin film | 1.83 | 0.001 | 60 |
| Cu₁₀Mn₂Sb₄S₁₃ | Powder | 1.81 | 0.46 | 250 |
| | Thin film | 1.83 | 9.5 | 180 |
| Cu₁₀Zn₂Sb₄S₁₃ | Powder | 1.80 | 5.5 | 312 |
| | Thin film | 1.82 | 10.0 | 180 |
| Cu₁₁In₁Sb₄S₁₃ | Powder | 1.65 | 8.5 | 330 |
| | Thin film | 1.70 | 4.0 | 120 |
| Cu₁₀Zn₂Sb₄Se₁₃ | Powder | 1.36 | 12.0 | 300 |
| | Thin film | 1.36 | 10.0 | 280 |

For example, in Cu¹⁺₁₂₋ₓMn²⁺ₓSb³⁺₄S²⁻₁₃, if x=2, the tetrahedrite compound with Mn substitution will have the lowest carrier concentration within this system, by having a formal oxidation state of Cu¹⁺. If 0≦x≦2, the tetrahedrite compound with Mn substitution will generate excess holes intrinsically. Compounds where x approaches 0 will be degenerate semiconductors by having a formal oxidation state of Cu^{7/6+}. Charge balance and compositions determine Fermi level. Hence, within the same system, the carrier concentration will be easily controlled by the formal oxidation state of Cu and the cation ratio, i.e., the Cu-to-Mn ratio in this case.

In some embodiments where M² selected from Zn, Mn, or Mg, and e is less than 2, or where M² is selected from In, Ga, or Al and e is less than 1, decreasing resistivity due to increasing hole carrier concentration is observed, due to the presence of mixed valent Cu cation. These compositions are also examples of p⁺ hole extraction layers.

B. Selenium-Containing Compounds

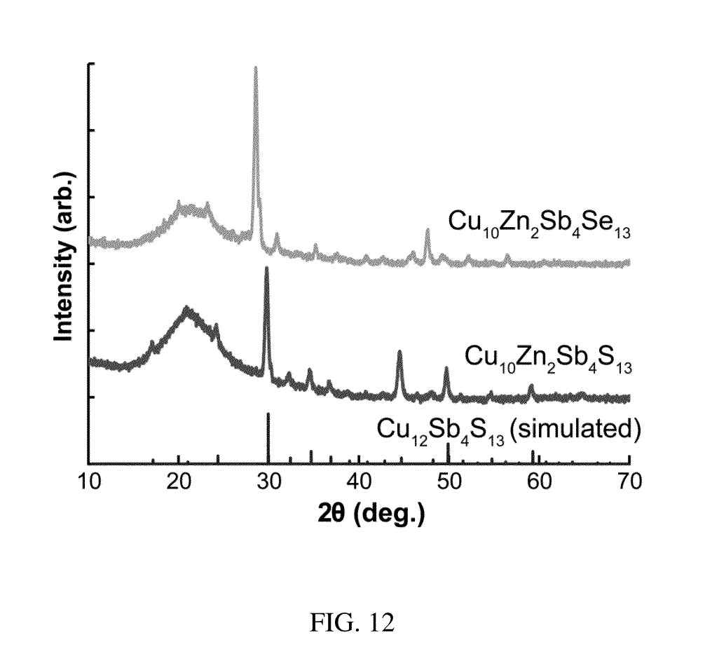

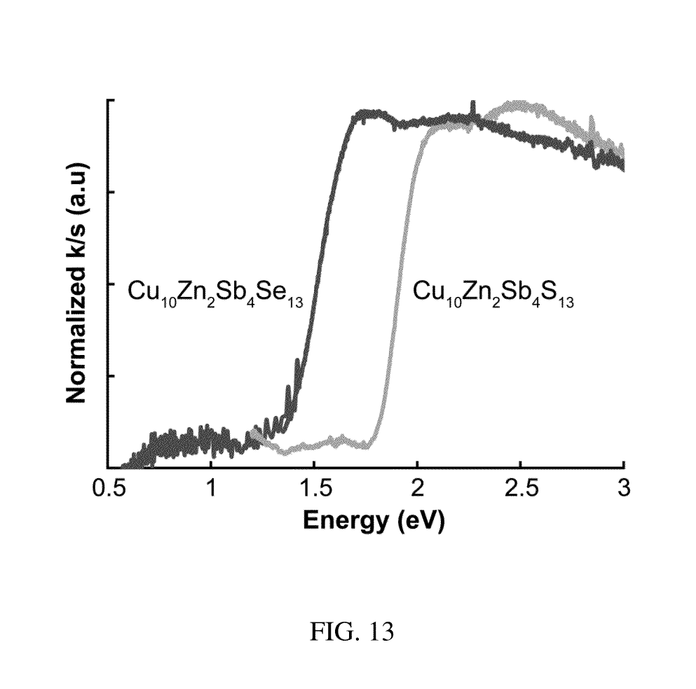

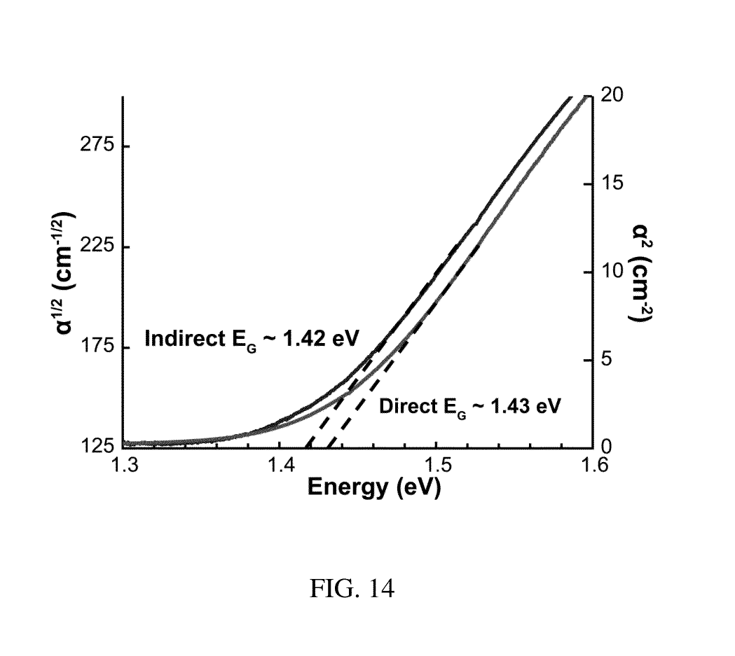

Tetrahedrite compounds were made according to disclosed embodiments of the method, with selenium substituted into the X and Y anion sites in formula V. One exemplary selenium-containing compound made by the disclosed embodiments was Cu₁₀Zn₂Sb₄Se₁₃. The structures of both the powder and thin-film form of this compound were confirmed via high-resolution XRD patterns (FIGS. 6 and 12). The absorption coefficient of a Cu₁₀Zn₂Sb₄Se₁₃ thin-film is shown in FIG. 10, and the compound exhibited a similar strong onset property to that of the corresponding sulfide-based compound, Cu₁₀Zn₂Sb₄S₁₃. However, the band gap was shifted to a lower energy of about 1.36 eV, which is within the desired range of a photovoltaic (1.1-1.8 eV). The band gaps for the bulk materials are shown in FIG. 13. The nature of the band gap for Cu₁₀Zn₂Sb₄Se₁₃ had to be considered, i.e., whether it was direct or indirect. A band gap is “direct” if the wavevector of electrons and holes is the same in both the conduction band and the valence band, and an electron can directly emit a photon. In an “indirect” band gap, a photon cannot be emitted because the electron has to pass through an intermediate state and transfer momentum to the crystal lattice. A plot of α^{1/2} versus E (direct) and α² versus E (indirect) for a Cu₁₀Zn₂Sb₄Se₁₃ thin-film (FIG. 14) showed that the energy difference between direct and indirect gaps was very small (<0.02 eV). This small difference shows that the absorption coefficient rises rapidly at an energy near the band gap, dominated by the direct gap, even though the optical band gap is indirect. The absorption coefficient for the Cu₁₀Zn₂Sb₄Se₁₃ thin-film shown in FIG. 10 exhibited a high sub-band gap absorption (a of about 2×10⁴ cm⁻¹) due to a non-optimized deposition process.

Tetrahedrite compounds, especially those with a band gap greater than about 1.5 eV and a formal oxidation state of Cu other than 1+ can be used as a transparent conducting layer.

### III. C—V—VI Compounds

Certain disclosed compounds, hereafter referred to as C—V—VI compounds, have a formula VII

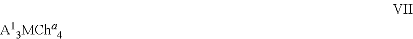

where A¹ is a transition metal or a combination thereof; M is selected from a transition metal, a group 14 element, a group 15 element or a combination thereof and Ch^{a} is a group 16 element, or a combination thereof. In some examples, A¹ is a cation or mixture of cations, M is a cation or mixture of cations and Ch^{a} is an anion or mixture of anions.

In some embodiments, A¹ comprises Cu and may comprise from about 50% to about 100% Cu. In certain embodiments, A¹ further comprises from 0 to about 50% Ag, from 0 to about 10% Zn, Mn, Mg, or any combination thereof.

In some examples, M is selected from P, As Sb, V, Nb, Ta, or combinations thereof. Certain disclosed compounds comprise about 90% to about 100% P, As, Sb, or combinations thereof. In particular examples, M comprises from about 95% to about 100% P, As, Sb, or combinations thereof, and from 0 to about 10% V, Nb, Ta, Si, Ge, Sn, or combinations thereof. In particular embodiments, A¹=Cu, M=P, As, Sb, V, Nb, Ta or a combination thereof, and Ch^{a}═S, Se or a combination thereof.

In some embodiments, suitable C—V—VI compounds are selected from Cu₃SbS₄, Cu₃SbSe₄, Cu₃AsS₄, Cu₃AsSe₄, Cu₃PS₄, Cu₃PSe₄, Cu₃As₁₋ₑSbₑS₄ (0≦e≦1), Cu₃PS₄₋ₓSeₓ (0≦x≦4), Cu₃AsS_{4-y}Se_{y}(0≦y≦4), Cu₃P_{1-z}As_{z}S₄ (0.1≦z≦1), Cu₃P₁₋ₐAsₐSe₄ (0≦a≦1), Cu₃SbS_{4-f}Se_{f} (0≦f≦1), Cu₃₋ₕAgₕSbS₄ (0≦h≦1.5), Cu₃₋ᵢ(Mn,Zn)ᵢSbS₄ (0≦i≦0.3), Cu₃Sb₁₋ⱼ(Te,Ge)ⱼS₄ (0≦j≦0.05), Cu₃(V,Nb,Ta)S₄.

In particular embodiments, the C—V—VI compound is selected from Cu₃PS₂Se₂, Cu₃PSSe₃, Cu₃PS_{2.5}Se_{1.5}, Cu₃PS_{1.89}Se_{2.11}, Cu₃PS_{0.71}Se_{3.29}, Cu₃AsS₃Se, Cu₃AsS₂Se₂, Cu₃AsS_{2.5}Se_{1.5}, Cu₃AsSSe₃, Cu₃P_{0.5}As_{0.5}Se₄, Cu₃P_{0.75}As_{0.25}Se₄, Cu₃P_{0.9}As_{0.1}Se₄, Cu₃P_{0.2}As_{0.8}S₄, Cu₃P_{0.4}As_{0.6}S₄, Cu₃P_{0.5}As_{0.5}S₄, Cu₃P_{0.6}As_{0.4}S₄, or Cu₃P_{0.8}As_{0.2}S₄. Alternatively, the compound can be selected from Cu₃(As,Sb)₁₋ₖ(V,Nb,Ta)ₖ(S,Se)₄ (0≦k≦1).

The A¹₃MCh^{a}₄ materials of formula VII described herein exhibit rapid onset to high absorption, supporting the premise of the current invention. FIG. 8 illustrates the rapid absorption onset to an absorption coefficient of 10⁵ cm⁻¹ within 0.8 eV from the band gap energy for Cu₃SbS₄, outperforming conventional TFSC absorbers, such as CdTe and CIS.

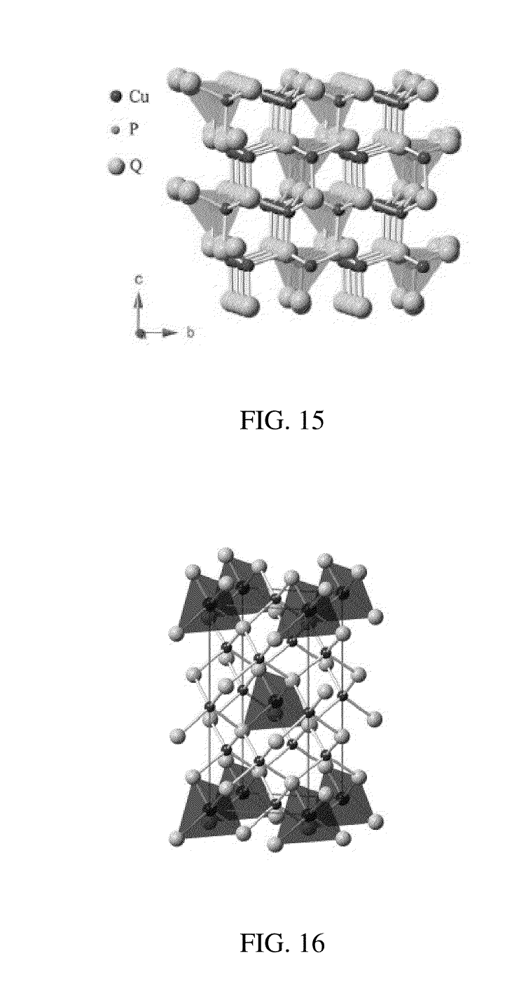

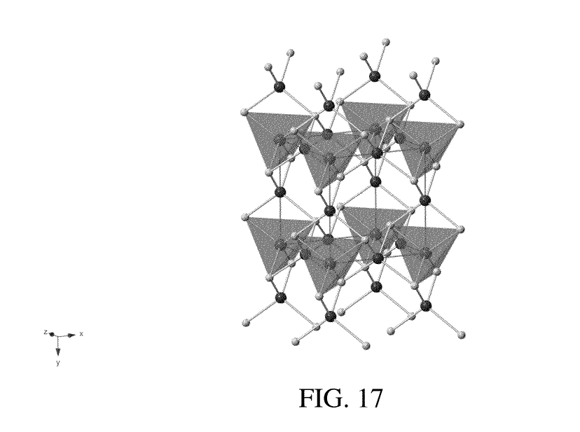

The materials of formula VII include M=group 5 or 15 cations that have 5+ formal oxidation state. This does not fit the high absorption semiconductor design principle based on low-valent group 15 or 16 elements described above for tetrahedrite-like compounds. Rapid onset to high absorption is enabled by the high A¹/M=3 ratio in the compounds that results in structural localization of the M element polyhedra (coordination unit by anions) in the Cu-chalcogenide matrix. The three main crystal structures assumed by A¹₃MCh^{a}₄ are orthorhombic (space group Pmn2₁) in FIG. 15, tetragonal (space group I-42m) in FIG. 16, and cubic (space group P4-3m) in FIG. 17, showing the absence of nearest neighbor M polyhedra.

Cu₃PSe₄, Cu₃PS₄ and Cu₃AsS₄ adopt the enargite structure, with the orthorhombic unit cell, and their crystal structures have been reported. The structure may be considered to be a derivative of wurtzite with Cu and P ordered across tetrahedral interstices within the distorted close packing of S(Se) atoms (FIG. 15). The structure is also adopted by the two compositions Cu₃PS_{1.89}Se_{2.11} and Cu₃PS_{0.71}Se_{3.29}.

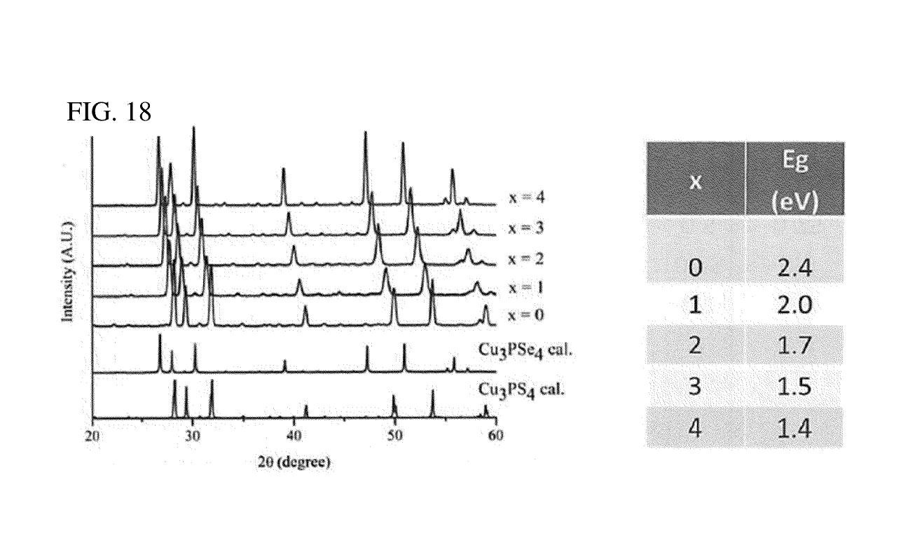

Powder X-ray diffraction patterns for Cu₃PS₄₋ₓSeₓ (x is from 0 to 4) are shown in FIG. 18. The experimental Cu₃PS₄ and Cu₃PSe₄ patterns are similar to those calculated from previously reported crystal structures. Intermediate compositions exhibit peak positions between those of Cu₃PS₄ and Cu₃PSe₄. They are shifted to smaller 20 angles as x increases, which is consistent with the substitution of Se for S and an expansion of the unit cell.

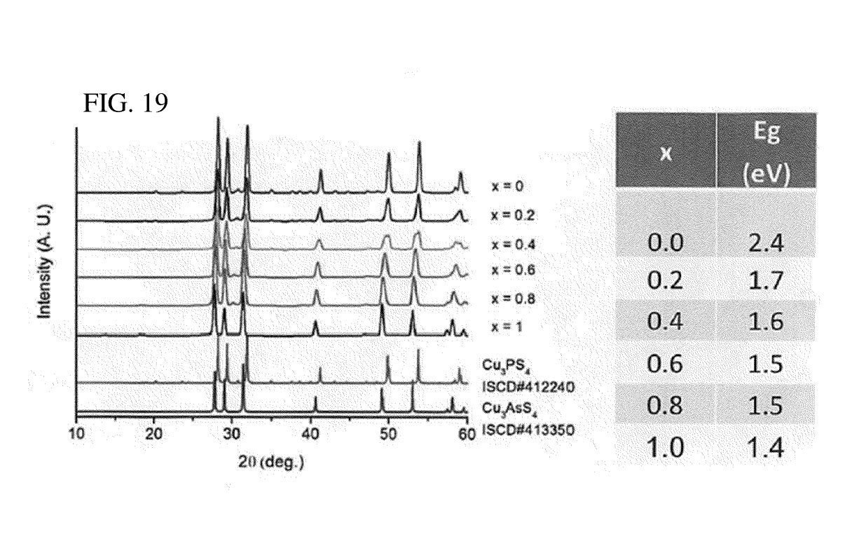

The powder X-ray diffraction for Cu₃PₓAs_{1-y}S_{y}Se_{4-y} (0<x<1, 0≦y≦4) compounds are shown in FIGS. 19-21. Based on the apparent similarity of the intermediate as well as the x=0 and 1 compositions in Cu₃PₓAs_{1-y}S₄ (FIG. 19), the wurtzite-related enargite-type structure is assumed by all members of this series. A monotonic unit cell expansion for 0<x<1, following Vegard's law, confirms the uniform incorporation of the larger crystal radius As cation on the smaller P cation site. This result is similar to that reported for Cu₃PS_{4-y}Se_{y} compounds.

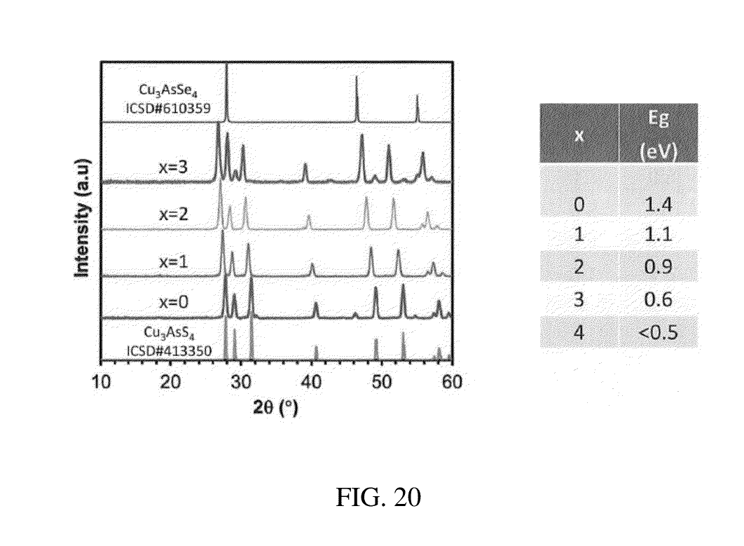

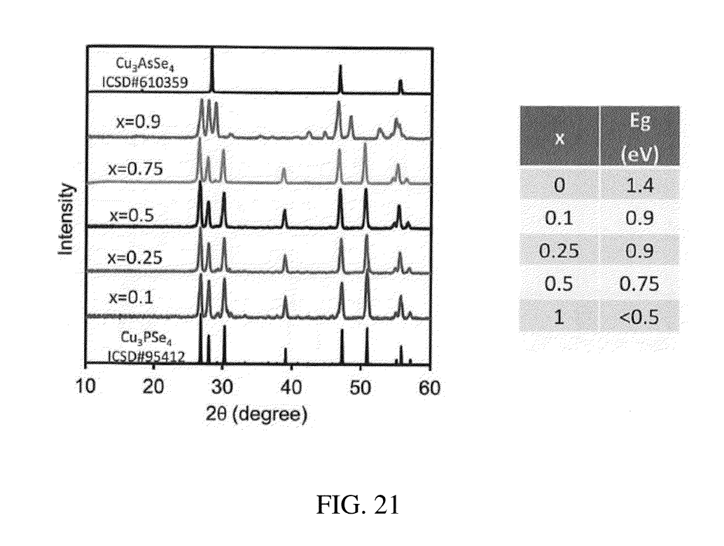

The Cu₃AsS_{y}Se_{4-y} (1≦y≦4) and Cu₃P₁₋ₓAsₓSe₄ (0≦x≦0.75) solid solutions also crystallize in the orthorhombic structure, as shown in FIG. 20 and FIG. 21, respectively. However, a structure transition is expected in these systems as the Cu₃AsSe₄ composition with the tetragonal unit cell is approached. In case of Cu₃AsS_{y}Se_{4-y} such transition is not observed for y≦1. A unique pattern is observed for Cu₃As_{0.9}P_{0.1}Se₄. Using a model enargite structure with random distribution of P and As on the respective a-site yields a similar pattern; however an exact match is not obtained. Long range ordering of P/As cations may be present to account for the differences.

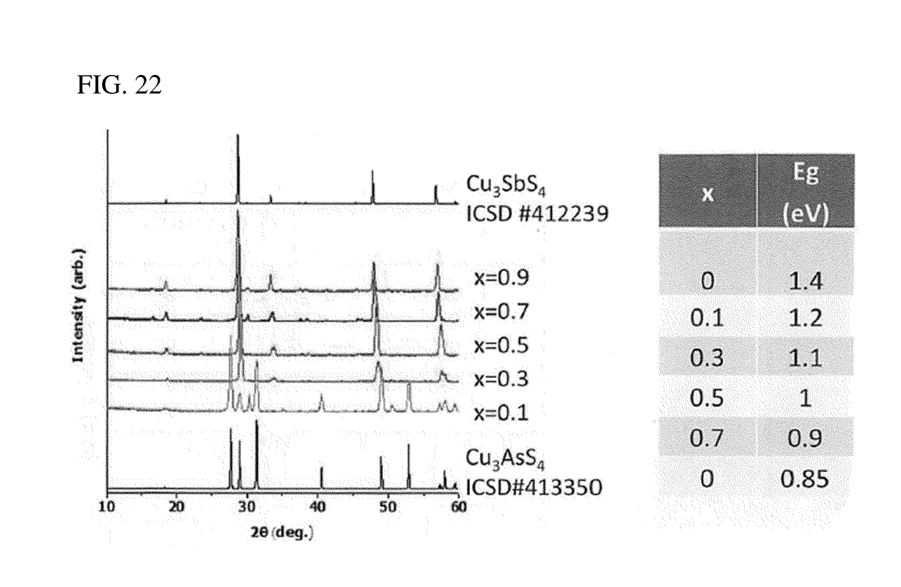

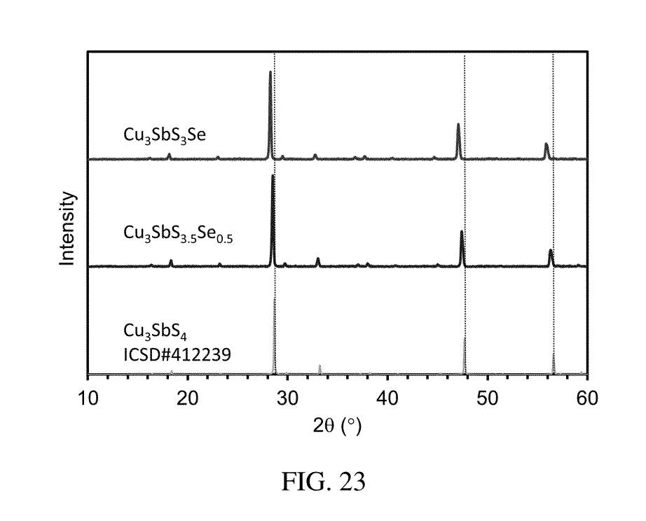

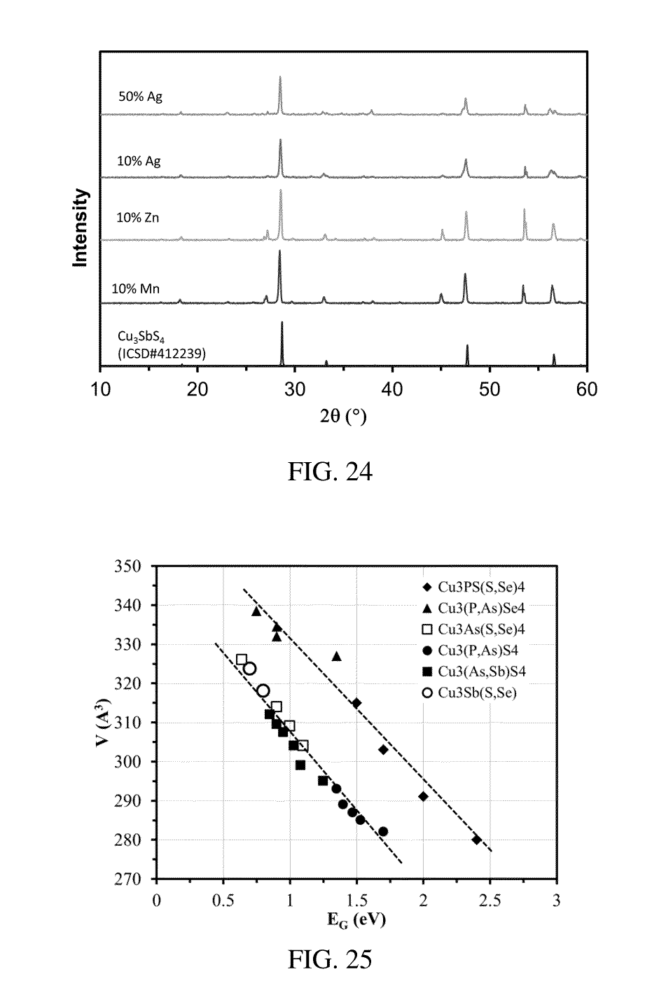

Other compounds in this family adopt a tetragonal crystal structure (FIG. 16). Exemplary compounds of this type include Cu₃SbS₄, Cu₃SbSe₄ and Cu₃AsSe₄. As for the Cu₃As₁₋ₓSbₓS₄ system where x>0.1 a clear structure transformation is observed from orthorhombic to tetragonal (FIG. 22), that also has been reported [M. Posfai, P. R. Buseck, American Mineralogist 83 (1998) 373-382]. The XRD patterns of Cu₃SbS₄ with Se substituted onto the S-anion site are shown in FIG. 23. A corresponding expansion of the unit cell is observed from peak shifts towards lower 20 values as referenced to Cu₃SbS₄ reference pattern (ICSD#412239). FIG. 24 provides unit cell volume of the compounds in comparison to other C—V—VI materials.

In all solid solutions examined so far with M=group 15 element the unit cell volume clearly increases with the incorporation of larger cations, e.g., P→As→Sb, or larger anion, e.g., S→Se (FIG. 24), enabling compositions with band gaps in the spectral range of 0.6-2.0 eV. The wide range of solid solutions available in this materials system enables the fine tuning of the optical and electronic properties over a wide range, relevant to application as absorbers in thin film solar cells.

Finally, compounds with M=group 5 element, have a cubic unit cell (FIG. 17). The arrangement of the Cu- and M-element polyhedra in the unit cell also exhibits localization, similarly to compositions described above, therefore supporting the concept of rapid onset to high absorption. The detailed structural, electrical and optical properties of these compounds are found in [P. Hersh, “Wide Band Gap Semiconductors and Insulators: Synthesis, Processing and Characterization”, PhD dissertation, Oregon State University, 2007]. In particular, the M=group 5 element compounds have optical band gaps in range from 2 to 3 eV, outside the range of interest for PV absorber application. Cu₃VS₄ is shown to have a band gap of 1.35 eV [S. Lv, Z. H. Deng, F. X. Miao, G. X. Gu, Y. L. Sun, Q. L. Zhang, S. M. Wan. Opt. Mat. 34 (2012) 1451]. The 5+ formal charge of group 5 and 15 elements in the compounds and their structural similarity make the Cu₃(As,Sb)₁₋ₖ(V,Nb,Ta)ₖ(S,Se)₄ (0≦k≦1) type solid solutions possible, making new A¹₃MCh^{a}₄ compositions suitable for PV absorber application.

A theoretical explanation attributes the rapid onset to high absorption in the described materials family of formula VII to the low dispersion of energy states near the CBM (FIG. 7) [Yu, L., Kokenyesi, R. S., Keszler, D. A., Zunger, A. Advanced Energy Materials 3 (2013) 43-48]. Primarily s-p orbital contribution derived from localized M-cation polyhedra make up the CBM of these compounds. Although the M-cation has a terminal 5+ oxidation state, similarly to In³⁺ in CuInSe₂, the advantage of the described localization and derived enhanced DOS near CBM (FIG. 7), results in the superior absorption property of A¹₃MCh^{a}₄, exemplified by Cu₃SbS₄ absorption spectrum in FIG. 8. The theoretical calculations confirm the direct band gap of example compounds from the materials family. Calculated high PV conversion efficiencies of example A¹₃MCh^{a}₄ surpass that of CuInSe₂ by over 3% within the SLME computational metric.

The absorption properties of the described C—V—VI compounds may be further enhanced by creating additional localized states in the materials. One avenue to achieve it is by isovalent cation substitution on the Cu site, thus creating new localized states. XRD patterns of up to 50 at. % Ag substituted on the Cu site in Cu_{1.5}Ag_{1.5}SbS₄ are presented in FIG. 24.

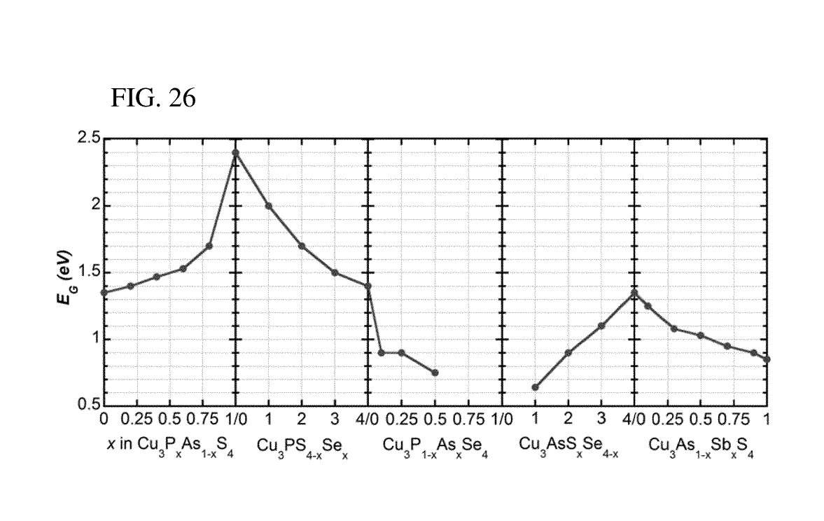

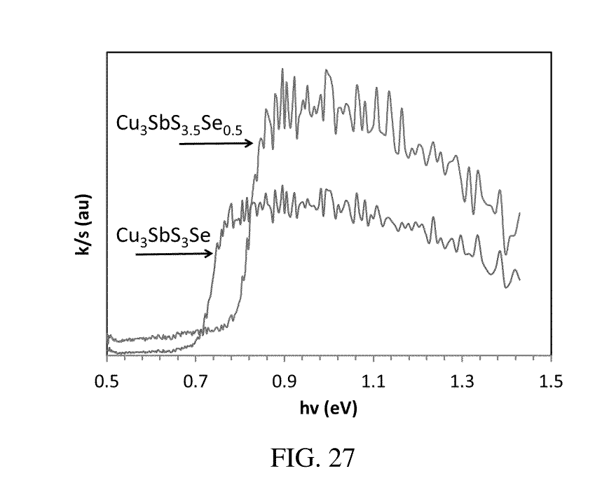

The band-gaps in the C—V—VI system monotonically decrease with the unit cell volume (FIG. 25) from 2.4 eV in Cu₃PS₄ to 0.6-0.7 eV in Cu₃AsSSe₃ or Cu₃SbS₃Se. Specific examples examined have band gaps as shown in FIG. 26 and FIG. 27, not limiting the described materials to these compositions. This band gap range of the described materials family covers the desirable range for multi-junction, or tandem, PV solar cell [for example A. De Vos J. Phys. D: Appl. Phys. 13 (1980) 839]. A notable advantage of tandem solar cells is higher conversion efficiency, and hence power output per unit area, due to relaxed thermodynamic efficiency limitations compared to single-junction PV cells. Example C—V—VI materials suitable for tandem solar cells are listed in Table 2.

TABLE 2
Example Cu₃MCh^{a}₄ Materials for Tandem Solar Cells

| | E_{G} | ρ | p | μ | S |
|---|---|---|---|---|---|
| | (eV) | (Ω cm) | (×10¹⁶ cm⁻³) | (cm²/Vs) | (μV/K) |
| Cu₃PS₂Se₂ | 1.7 | 494 | 1 | 1 | +585 |
| Cu₃P_{0.8}As_{0.2}S₄ | 1.7 | 120 | 0.9 | 4 | +850 |
| Cu₃PSe₄ | 1.4 | 0.62 | 60 | 13 | +360 |
| Cu₃AsS₄ | 1.4 | 55 | 1 | 10 | +540 |
| Cu₃AsS₂Se₂ | 0.9 | 15 | 10 | 4 | +510 |
| Cu₃SbS₄ | 0.9 | 50 | 1 | 12 | +700 |

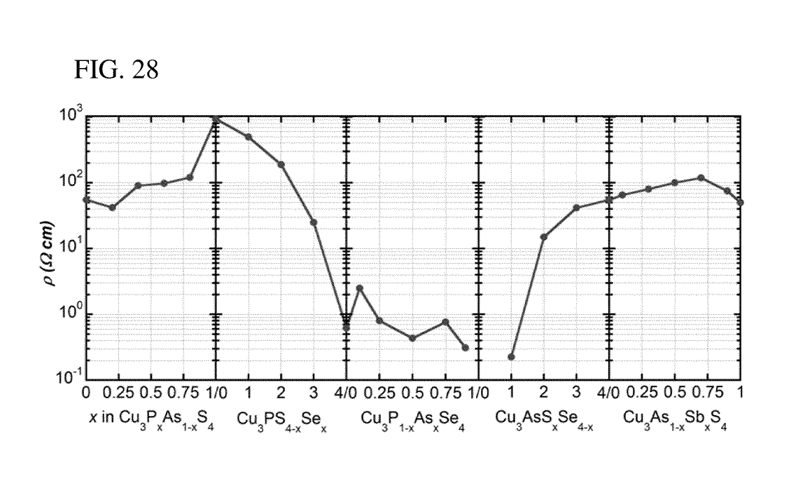

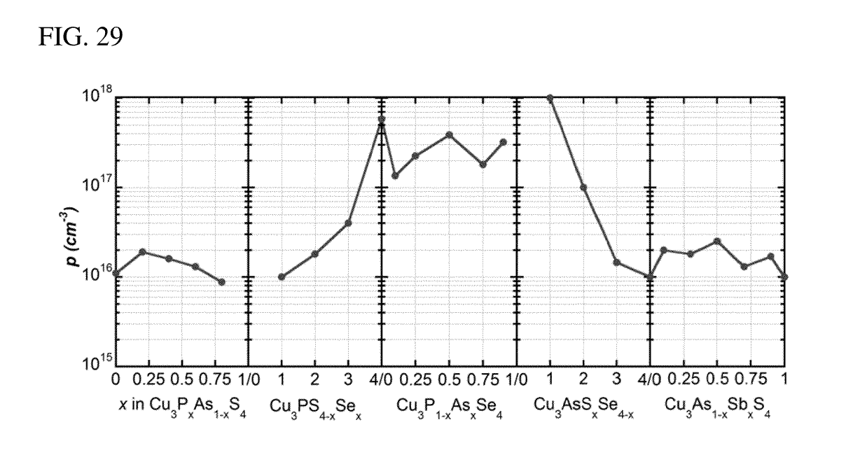

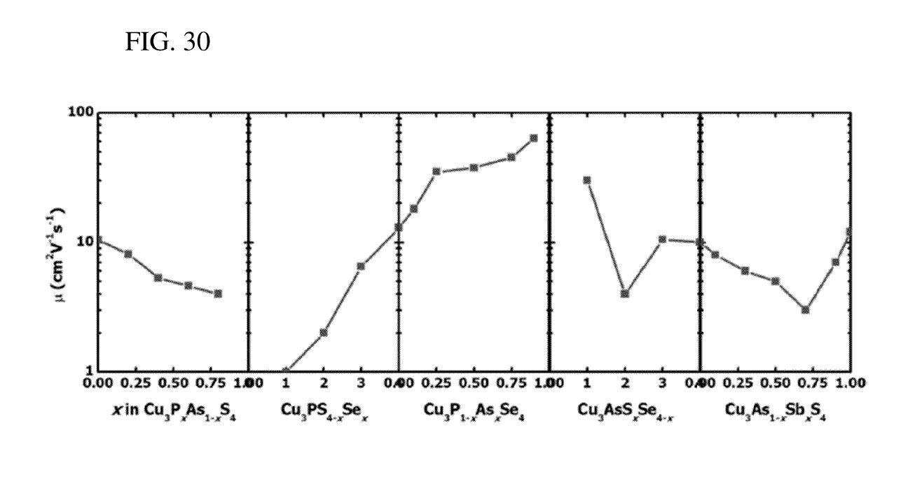

Resistivity (p), carrier concentration (p), and mobility (μ) from 4-point probe Hall measurements on pressed pellets are shown in FIGS. 28-30. Seebeck coefficients (S) in Table 2 for exemplary compounds are consistent with p-type semiconductor behavior (+300 to +500 μVK⁻¹). The low carrier concentration (p) and high mobility (μ) of FIG. 29 and FIG. 30 and Table 2 of the example Cu-V-VI are comparable to CIGS, making the described compounds prime candidates for solar absorber semiconductor application in PV cells.

A photoelectrochemical (PEC) test cell with a Cu₃PSe₄ single crystal was used to assess initial PV device parameters, including short-circuit current density (J_{sc}) and open-circuit voltage (V_{oc}) [V. Itthibenchapong, R. S. Kokenyesi, A. J. Ritenour, L. N. Zakharov, S. W. Boettcher, J. F. Wager, and D. A. Keszler. J. Mat. Chem. C 1 (2013) 657]. The differences between the light and dark response yielded V_{oc} of about 0.12 V and J_{sc} of about 0.25 mA cm⁻²; the p-type character was also confirmed on the basis of the sign of the photoresponse.

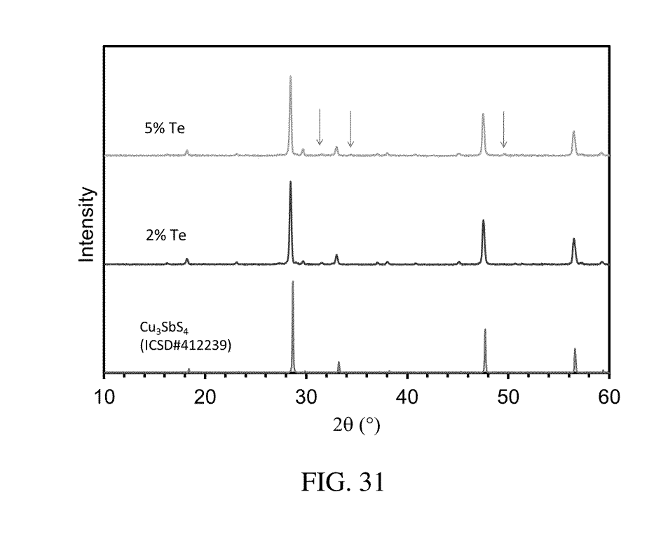

The carrier concentration the Cu-V-VI absorber material can be manipulated by substitution with other suitable elements. For example, halogen (group 17) substitution on Ch anion sites, in this example case Br in Cu₃PSe₄ observed by electron probe microanalysis [V. Itthibenchapong, R. S. Kokenyesi, A. J. Ritenour, L. N. Zakharov, S. W. Boettcher, J. F. Wager, and D. A. Keszler. J. Mat. Chem. C 1 (2013) 657], could act as compensating n-type dopants that would decrease the hole concentration. Similarly, substitution on the M cation site with elements that have 6+ oxidation formal state, such as Te or group 6 elements (Cr, Mo, or W); and Zn, Mn, or Mg with a 2+ oxidation state substituted on the A¹ site of 1+ formal oxidation state. Such substitutions result in a decrease of hole carrier concentration due to additional electrons added into the system. Such substitution typically occurs at the 10 atomic % level or less. Example XRD patterns of Zn and Mn substituted materials with highest example compositions Cu_{2.7}Zn_{0.3}SbS₄ and Cu_{2.7}Mn_{0.3}SbS₄, respectively, are illustrated in FIG. 24. Only compositions of Cu₃M_{1-c}Te_{c}Ch^{a}₄ with c<0.05 compounds are expected to be single phase, shown by XRD patterns in FIG. 31, due to secondary phase formation of tetrahedrite-type is observed when c=5.

Finally, the hole carrier concentration in the Cu-V-VI materials can be increased by removing electrons from the system and be used to create a p+ contact layer. Such removal of electrons can occur for example by substitution of M cations by group 4 or 14 cations. The substitution occurring at the less than 10 at. % level by Ti, Zr, Hf, Si, Ge, or Sn creates excess hole carriers in Cu-V-VI up to degenerate semiconductor state. In a particular example, Cu₃Sb₁₋ᵥGeᵥS₄ with 0<v<0.1 was synthesized and characterized to exhibit carrier concentrations in excess of 1×10²⁰ cm⁻³ [A. Suzumura, M. Watanabe, N. Nagasako, R. Asahi. J. Electr. Mater. (2014) DOI: 10.1007/s11664-014-3064-y]. Te substitution may result in increased hole concentration if its oxidation state is 4⁺. Another possible route for increasing hole carrier concentration in Cu-V-VI is by group 15 element substitution on the Ch^{a} anion site.

### IV. Method for Making Tetrahedrite Compounds

A general method for making the tetrahedrite compounds disclosed herein comprises providing a mixture of reactants selected to produce a desired tetrahedrite compound and heating the reactants.

The compounds can be made in different forms, such as polycrystalline powders, pellets and thin films. To make polycrystalline powders of the disclosed compounds, reactants were mixed in quantities selected to produce the desired compounds. For example, to produce Cu₁₀Mn₂Sb₄S₁₃, stoichiometric amounts of Cu, Mn, Sb and S, such as 10 molar equivalents of copper, 2 molar equivalents of manganese, 4 molar equivalents of antimony and 13 molar equivalents of sulfur, were selected and mixed together. The mixture of reactants was heated in an evacuated sealed tube at a temperature and pressure effective to produce the desired compounds, such as at a temperature from greater than ambient temperature to at least about 700° C., preferably from about 400° C. to about 550° C., more preferably at about 450° C. A person of ordinary skill in the art will appreciate that a pressure effective to produce the desired compounds could be about atmospheric pressure or less than atmospheric pressure, such as from less than 1 mm Hg to about 760 mmHg, preferably from about 10 mm Hg to about 700 mm Hg. Or the pressure could be greater than atmospheric pressure, such as from about 1 atmosphere pressure to greater than 10 atmospheres, preferably from about 1.1 atmospheres to about 5 atmospheres pressure. The mixture was heated for at least 1 hour to at least 7 weeks, preferably from about 1 week to about 5 weeks, and in working embodiments for a period of about 3 weeks. Additional grinding and reheating resulted in polycrystalline powders. It should be appreciated that much shorter heating times will be realized from studying and optimizing the process.

Powders can be formulated in different forms suitable for selected application. For example, in certain embodiments the powders were crushed and molded into pellets, then sintered at a temperature effective to produce the desired compound in a pellet form, such as at a temperature from greater than ambient to at least about 700° C., preferably from about 300° C. to about 600° C., more preferably at about 450° C. The pellets were sintered for more than about 1 hour to at least about 48 hours, preferably for about 12 hours to about 36 hours, and in working embodiments for about 24 hours.

The compounds disclosed herein can also be made as thin films. Thin films can be produced by any suitable method including, but not limited to, plating, chemical solution deposition, spin coating, chemical vapor deposition (CVD), physical vapor deposition (PVD), atomic layer deposition, thermal evaporation, electron beam evaporation, molecular beam epitaxy, sputtering (DC, rf, magnetron), pulsed laser deposition, cathode arc deposition, electrohydrodynamic deposition, or a combination thereof.

In a CVD process, the tetrahedrite thin films can be deposited via atmospheric pressure CVD (APCVD), low-pressure CVD (LPCVD), ultrahigh vacuum CVD (UHVCVD), microwave assisted CVD (MACVD), plasma-enhanced CVD (PECVD) or metal-organic CVD (MOCVD).

Vacuum-free processes can also be used to deposit the tetrahedrite thin films via closed space sublimation (CSS) or closed spaced vapor transport (CSVT).

A liquid (referred to as an ink-based method) method, such as ink-jet deposition, slot die coating, or capillary coating, can be used to deposit a tetrahedrite semiconductor thin film. The “ink” is based on a precursor comprising at least one dissolved component and at a least one solvent component. The solvent can be water or non-aqueous liquid, the second being either organic or inorganic liquid. Preferably, the solvent can be substantially eliminated by evaporation.

After layer deposition, a post-deposition anneal can be performed to adjust the elemental composition and to improve the crystallinity of the deposited layer or layers. Annealing can be conducted in an evacuated environment or under an atmosphere comprising a component of the desired compound. For example, in certain working embodiments annealing was conducted in an atmosphere of carbon disulfide, hydrogen sulfide, and/or sulfur. The annealing was performed at a temperature effective to produce the desired compound, such as at a temperature of greater than room temperature to at least 600° C. In certain embodiments, annealing was conducted at temperatures greater than ambient temperature to temperatures below about 500° C., and more preferably below about 300° C., for about 10 minutes to at least about 2 hours, preferably from about 20 minutes to about 1 hour, and in certain disclosed working embodiments for about 30 minutes.

For certain working embodiments thin films comprising a compound having formula V were fabricated using electron-beam evaporation of a mixture of reactants selected to produce the desired compound, for example, a C—X and/or C—Y compound, an A-X, A-Y, B—X and/or B—Y compound, and optionally an additional elemental compound or elements, A, B, C, X and/or Y. After fabrication, the film was heated to form a thin film comprising a compound having formula V. In some embodiments the mixture of reactants comprised Sb₂S₃, a metal sulfide and optionally an elemental metal. In other embodiments the mixture of reactants comprised Sb₂Se₃, a metal selenide and optionally elemental metal and/or elemental Se. In some working embodiments the mixture of reactants was ZnS, Cu, and Sb₂S₃; MnS, Cu and Sb₂S₃; In₂S₃, Cu and Sb₂S₃; or ZnSe, Cu, Se, Sb₂Se₃.

### V. Method for Making C—V—VI Compounds

A general method for making the C—V—VI compounds disclosed herein comprises providing a mixture of reactants selected to produce a desired C—V—VI compound and heating the reactants.

The compounds can be made in different forms, such as crystalline, polycrystalline, powders, pellets and thin films. To make polycrystalline powders of the disclosed compounds, reactants are mixed in quantities selected to produce the desired compounds. For example, to produce Cu₃PS₄, stoichiometric amounts of Cu, P and S, such as 3 molar equivalents of copper, 1 molar equivalent of phosphorus and 4 molar equivalents of sulfur, were selected and mixed together. Typically, the mixture of reactants is then ground under an inert atmosphere, such as argon gas.

The mixture of reactants is heated in an evacuated sealed tube at a temperature and pressure effective to produce the desired compounds, such as at a temperature from greater than ambient temperature to at least about 700° C., preferably from about 400° C. to about 600° C., more preferably from about 450° C. to about 500° C. In some embodiments, an excess, such as a 0.01 equivalent excess, of the volatile elements, such as P, As, S or Se, is added to prevent formation of secondary phases deficient in those elements. A person of ordinary skill in the art will appreciate that a pressure effective to produce the desired compounds could be about atmospheric pressure or less than atmospheric pressure, such as from less than 1 mm Hg to about 760 mmHg, preferably from about 10 mm Hg to about 700 mm Hg. Or the pressure could be greater than atmospheric pressure, such as from about 1 atmosphere pressure to greater than 10 atmospheres, preferably from about 1.1 atmospheres to about 5 atmospheres pressure. The mixture is heated for an effective period of at least 1 hour to at least 1 week, preferably from about 12 hours to about 2 days, and in certain embodiments for a period of about 24 hours. Additional grinding and reheating results in polycrystalline powders.

Powders can be formulated in different forms suitable for selected application. For example, in some embodiments the powders are crushed and molded into pellets. In certain embodiments, the powders are cold pressed into disks at a pressure of from about 3 ton to 8 tons, typically from about 2.5 tons to about 3 tons. The disks are then sintered at a temperature and pressure effective to produce the desired compound in a pellet form. Typically, suitable temperatures are from greater than ambient to at least about 700° C., preferably from about 400° C. to about 600° C., and even more preferably from about 450° C. to about 500° C. Suitable pressures are from atmospheric to greater than 50,000 psi, such as from about 5,000 psi to about 20,000 psi, and in certain embodiments, at about 10,000 psi. Typically, the sintering is performed in an inert atmosphere, such as an argon atmosphere. The pellets are sintered for more than about 1 hour to at least about 12 hours, preferably for about 2 hours to about 6 hours, and in certain embodiments for about 3 hours.

The compounds disclosed herein can also be made as thin films. These can be produced by any suitable method including, but not limited to, plating, chemical solution deposition, spin coating, chemical vapor deposition (CVD), physical vapor deposition (PVD), atomic layer deposition, thermal evaporation, electron beam evaporation, molecular beam epitaxy, sputtering (DC, rf, magnetron), pulsed laser deposition, cathode arc deposition and electrohydrodynamic deposition or a combination thereof.

In a CVD process, thin films can be deposited via atmospheric pressure CVD (APCVD), low-pressure CVD (LPCVD), ultrahigh vacuum CVD (UHVCVD), microwave assisted CVD (MACVD), plasma-enhanced CVD (PECVD) or metal-organic CVD (MOCVD).

Vacuum-free processes can also be used to deposit the thin films via closed space sublimation (CSS) or closed spaced vapor transport (CSVT).

A liquid (ink-based) method, such as ink-jet deposition, slot die coating, or capillary coating, can be used to deposit a C—V—VI semiconductor thin film. The ink is based on a precursor containing at least one dissolved component and at a least one solvent component. The solvent can be water or non-aqueous liquid, the second being either organic or inorganic liquid. Preferably, the solvent can be substantially eliminated by evaporation.

After layer deposition, a post-deposition anneal can be performed to adjust the elemental composition and to improve the crystallinity of the deposited layer or layers. The annealing can be conducted in an evacuated environment or under an atmosphere comprising a volatile component of the desired compound, such as S, P, Se, As, or combinations thereof. In certain embodiments, annealing is conducted at temperatures within the range of greater than ambient to below about 600° C., and more preferably from about 250° C. to about 500° C. Annealing is continued for an effective period of from less than 1 minute to at about 2 hours, preferably from about 2 minutes to about 30 minutes.

### VI. Converting a C—V—VI Compound to a Tetrahedrite Compound

C—V—VI absorbers offer a unique opportunity to create an integrated p+ contact comprising a composition having the same or substantially the same cation Cu/M ratio. This contact will provide higher carrier-collection efficiencies and simplified manufacturing processes. The contact may be prepared by a simple surface treatment of the absorber material, eliminating the need for deposition of additional material layers. The hole-extraction contact will be seamlessly integrated, providing the necessary transparency and conductivity for the bottom cell in a tandem device, i.e., a combination of properties absent in existing PV materials. Direct integration on the TCO contact is enabled by processing temperatures below 400° C., potentially eliminating the need for a buffer layer.

In light of the above, C—V—VI compounds, at least for certain embodiments, can be converted into a tetrahedrite compound. A general method of converting a C—V—VI compound to a tetrahedrite compound comprises heating the C—V—VI compound under Ch^{a}-poor conditions, such as vacuum or reducing conditions in the presence of H₂ gas. Such conversion is possible due to the same cation ratio of A¹/M=3 in compounds of formula VII and certain tetrahedrite-based compounds. In some embodiments, a thin film or layer comprising a compound having a formula A¹₃MCh^{a}₄ (formula VII) is heated under conditions poor in Ch^{a} to form a thin film or layer comprising a compound having a formula A₆₊ₐB_{6+b}(C_{1+c}X₃₊ₓ)_{4+z}Y_{1+y} (formula V), where A and B comprise A¹, C comprises M, and X and Y comprise Ch^{a}. Thus a p-p+ stack of layers is formed without additional deposition of material. For example, an alternative representation of Cu₃SbS₄ is Cu₁₂Sb₄S₁₆, and with the removal of three S anions from the compounds, provides Cu₁₂Sb₄S₁₃.

In some embodiments, discrete layers are formed within the thin film or layer, one layer comprising the compound with formula VII, and another layer comprising the compound with formula V. In other embodiments, a graded thin film or layer is formed, such that one surface of the thin film or layer comprises, consists essentially of, or consists of, the compound having formula VII, another surface comprises, consists essentially of, or consists of, the compound having formula V, and in between there is a gradual or graded change in composition from one compound to the other.

### VII. Methods of Using Disclosed Compounds

Disclosed herein are embodiments of a method for using compounds having formula V or formula VII. The exemplary embodiments of the present disclosure include a component of a semiconductor device, such as a photovoltaic device, that contains one or more disclosed compounds. In some of the exemplary embodiments, the disclosed compound is used in an amorphous form, a single-phase crystalline state, a mixed-phase crystalline state, or a combination thereof.

A. Overview of Photovoltaic Devices

The compounds disclosed herein can be used in devices useful for generating electricity. One such type of device is a photovoltaic device that converts light into electricity. Photovoltaic devices typically incorporate semiconductors that exhibit a photovoltaic effect. One example of a photovoltaic device is a solar cell.

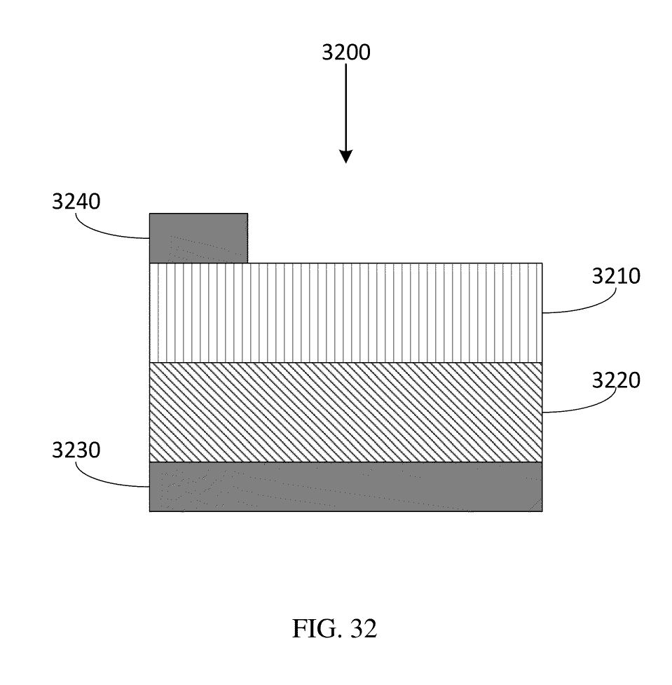

FIG. 32 provides a cross-sectional schematic of an exemplary photovoltaic cell 3200. A single-junction photovoltaic cell comprises at least two semiconductor layers, an n-type layer 3210, and a p-type layer 3220. The “p” and “n” types of semiconductors correspond to “positive” and “negative” because of their abundance of holes or electrons (the extra electrons make an “n” type because of the negative charge of the electrons). Although both materials are electrically neutral, n-type semiconductors typically have excess electrons and p-type semiconductors have excess holes. Positioning these two materials adjacent to each other creates a p/n junction at their interface, thereby creating an electric field. Each layer may comprise multiple sub-layers. When cell 3200 is exposed to light, some photons are reflected, some pass through the cell, and some are absorbed. When sufficient photons are absorbed by the absorber layer, electrons are freed from the semiconductor material and migrate to a contact. This creates a voltage differential between two contacts, similar to a household battery. When the two layers are connected to an external load, through contacts 3230 and 3240, the electrons flow through the circuit producing electricity.

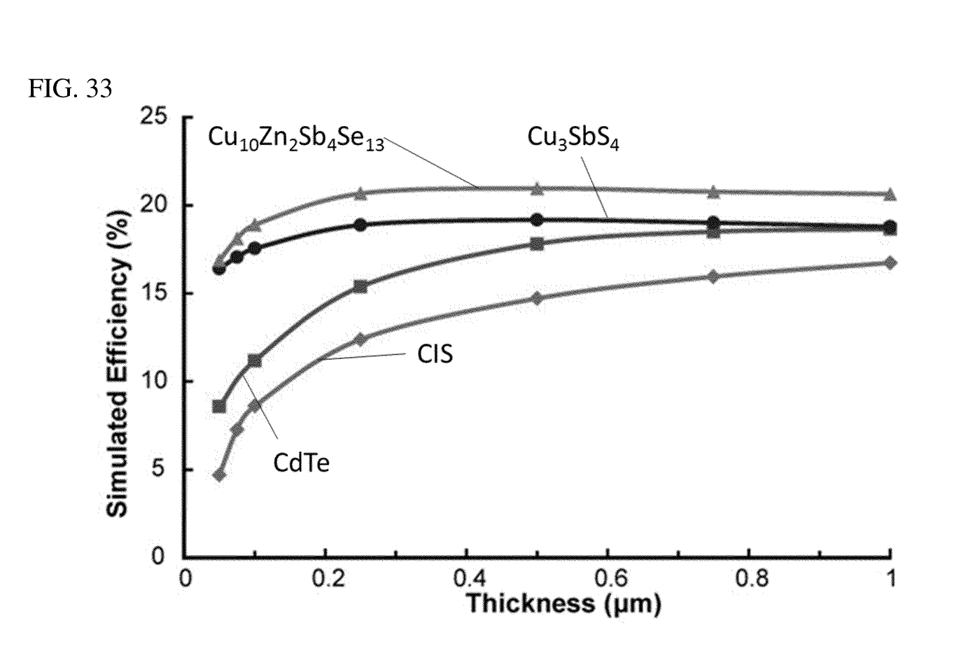

Disclosed herein are embodiments of a photovoltaic device comprising a semiconductor absorber layer selected from embodiments of the disclosed compounds. In some embodiments the composition of the semiconductor layer can be tuned by the independent selection of the cations and anions in the disclosed compounds, to produce an electronic band gap of from about 0.6 eV to about 1.8 eV for high level solar absorption. In some embodiments, the semiconductor layer has a thickness or depth of from about 20 nm to about 2000 nm, and the layer may comprise crystallites of sizes commensurate with thickness of the layer. Partial or full absorption of incident sunlight can be achieved within that depth by semiconductors that exhibits an abrupt onset of absorption with the absorption coefficient (a) rising above about 1×10⁵ cm⁻¹ within 0.8 eV in the materials of described above. The abrupt onset and high absorption coefficient in the suitable range of electromagnetic radiation (FIG. 8 and FIG. 10), enables superior light absorption relative to conventional polycrystalline thin-film PV materials such as CIS and CdTe. This efficient light absorption enables high-efficiency photovoltaic devices (FIG. 33) in a p⁺-p-n configuration, wherein the semiconductor absorber layer has a hole majority carrier concentration p≦1×10¹⁷ cm³. In certain embodiments, this carrier concentration requirement can be realized by replacing some of the cations in the absorber layer with Zn, Mn, Mg, or any combination thereof. In some embodiments, up to about 10 at % of the A¹ cation compounds having formula VII was replaced with Zn, Mn, as described above (FIG. 24). In alternative embodiments, the absorber layer may comprise or consist of variable (graded) cation compositions to achieve maximum device efficiency. In certain embodiments the absorber layer thickness is less than about 1000 nm, allowing electric field assisted extraction of photogenerated carriers via a charged carrier drift process leading to high efficiency solar cells (FIG. 33) in a p⁺-p-n configuration. In certain embodiments, the absorber layer is in direct contact with an n-type oxide semiconductor with an electron majority carrier type of concentration of 1×10¹⁵ cm⁻³ to 1×10²⁰ cm⁻³.

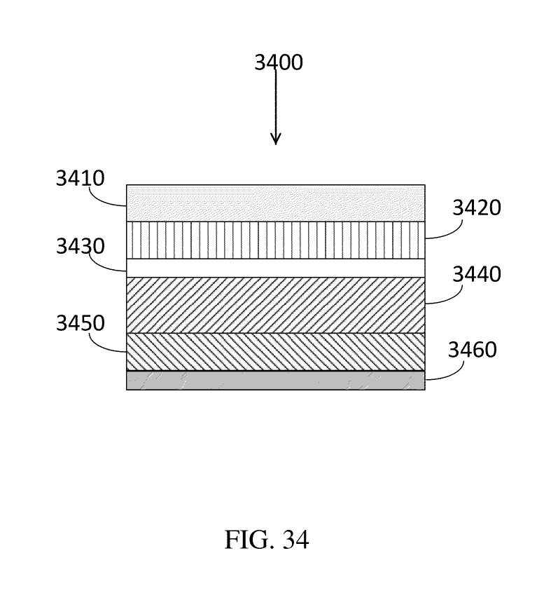

The contact layers may comprise conductive metals, semiconductors, or combinations thereof. A separate p⁺ semiconductor layer can be used with a hole concentration p≧1×10¹⁷ cm³ to aid effective hole carrier extraction in layers having a thickness of from about 5 nm to about 100 nm (see, for example, FIG. 34). In some embodiments, such a hole extraction semiconductor can be produced by doping the semiconductor, i.e. by replacing up to about 5% of the M cation of formula VII, with Si, Ge, Sn, or any combination thereof. In other embodiments, the hole extraction semiconductor may comprise a tetrahedrite compound having a formula A₆₊ₐB_{6+b}(C_{1+c}X₃₊ₓ)_{4+z}Y_{1+y} (formula V), where A₆₊ₐB_{6+b} comprises Cu_{12+a+b-h}M⁵ₕ where M⁵ is selected from Mg, Zn, Mn, Sn, or any combination thereof, and h is from 0 to less than 2. Alternatively, M⁵ may be selected from Al, Ga, In, or any combination thereof, and h is from 0 to less than 1. These contact materials may be specifically designed and made to have a band gap between about 0.6 and about 2.1 eV, making them useful as transparent contacts for improving device efficiency and simplifying device fabrication. The described p⁺ semiconductor contact layer comprising the described tetrahedrite compounds is also applicable to devices containing semiconductor absorber layers other than those described here (for example, CIGS, CZTS, CdTe, Si).

B. Photovoltaic Device Comprising a Tetrahedrite Thin Film

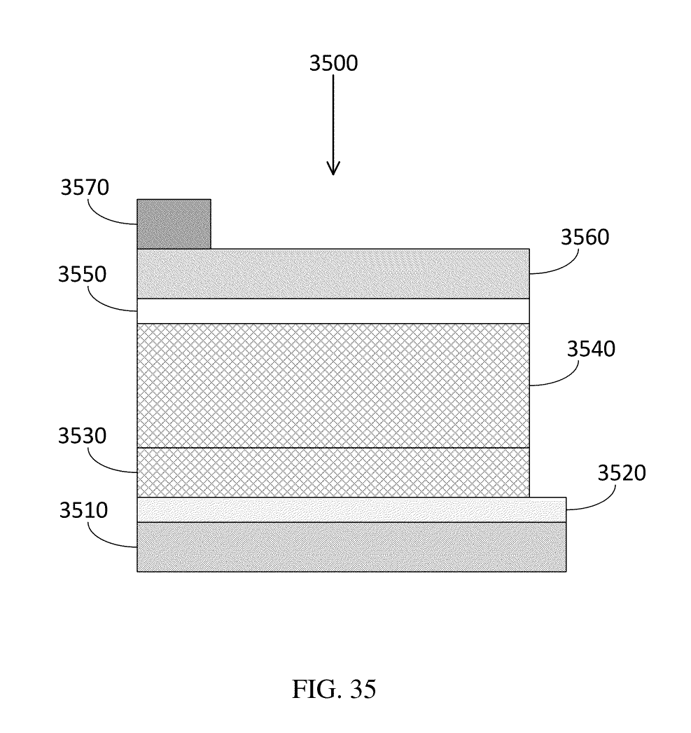

Tetrahedrite thin films made according to disclosed embodiments can be used in photovoltaic devices such as TFSCs. FIG. 35 provides a cross-sectional schematic of an exemplar TFSC device 3500 in a substrate configuration, comprising a tetrahedrite thin film. The device configuration is an n-p-p⁺ heterojunction TFSC. An n-p-p⁺ heterojunction with a thin p layer (<1 um) operates as a drift cell. This means that the n and p⁺ layers provide a strong built-in electric field across the absorber layer, sweeping photogenerated carriers towards their respective contacts, rather than relying on the diffusion of carriers due to their random thermal motion, as in a diffusion cell configuration.

With reference to FIG. 35, at the base of device 3500 is substrate 3510. Substrate 3510 can be made from any suitable material, such as glass, ceramic, plastic or bioplastic, polymers, including high temperature polymers, metals, metal foils, such as copper, aluminum or stainless steel, and metal alloys and combinations thereof. The substrate can be flexible or rigid and can be transparent or opaque. The substrate material will be sufficiently heat resistant to withstand fabrication processes, such as an annealing process. On top of the substrate 3510 is a bottom contact layer 3520. Bottom contact layer 3520 can be made using any suitable material that can conduct electricity, such as a metal, alloy, heavily doped p-type material, or a degenerate semiconductor, such as a degenerate tetrahedrite semiconductor disclosed herein. In some embodiments, bottom contact layer 3520 comprises a metal. On top of bottom contact layer 3520 is a tetrahedrite semiconductor layer made according to the disclosed embodiments, forming a p⁺-layer 3530. Suitable materials for the p⁺-layer include materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃. On top of the p⁺-layer is p-layer 3540, comprising a tetrahedrite compound according to the disclosed embodiments. Suitable materials for the p-layer include materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃. In some embodiments the properties of the p-layer are assumed to be identical to those of the p⁺-layer. Buffer layer 3550 and the window 3560 together form an n-type layer. Buffer layer 3550 can be formed from any material suitable for an n-type layer. Preferably, buffer layer 3550 comprises an n-type material with a band gap E_{g} from greater than the band gap of the p-type layer, to less than the band gap of the window layer, preferably from about 1.5 to about 3.5 eV, more preferably about 2.5 eV. Exemplary materials for the buffer layer 3550 include, but are not limited to, CdS, ZnS, ZnSe, Zn(O,S), (Zn,Mg)O, In₂S₃, In₂Se₃ and silicon, which may or may not be doped, such as with phosphorous or arsenic.

Window layer 3560 is formed from any material suitable for an n-type layer that allows photons to pass to the layers below. Preferably window layer 3560 comprises an n-type material with a band gap E_{g} of greater than about 3 eV. Exemplary suitable materials for the window layer include, but are not limited to, ITO (indium tin oxide), SnO₂, FTO (fluorine doped tin oxide), ZnO, ZnO:Al (Al doped ZnO) and ZnO:B (boron doped ZnO). Top contact electrode 3570 is placed above window layer 3560. Top contact electrode 3570 can be formed from any suitable material that can conduct electricity, such as a metal, alloy, heavily doped p-type material or a degenerate semiconductor, such as a degenerate tetrahedrite semiconductor disclosed herein.

FIG. 34 provides a cross-sectional schematic of a superstrate configuration for an exemplar TFSC device 3400. Device 3400 has a substrate 3410. Substrate 3410 typically is transparent, such as, for example, a glass substrate. Light shines through transparent substrate 3410 and through the n-type layer comprising a window layer 3420 and a buffer layer 3430. Window layer 3420 and buffer layer 3430 can comprise any suitable materials, such as those listed above with respect to device 3400. In particular embodiments, window layer 3420 comprises SnO₂ and buffer layer 3430 comprises CdS. Below buffer layer 3430 is the p-type absorber layer 3440 comprising a tetrahedrite compound according to the disclosed embodiments. Suitable materials for p-layer 3440 include materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃. Below p-layer 3440 is p⁺-layer 3450, also comprising a tetrahedrite compound according to the disclosed embodiments, such as those listed as suitable for p-layer 3440. In some embodiments p-layer 3440 and p⁺-layer 3450 have the same properties. In some particular embodiments, p⁺-layer 3450 comprises Cu₁₂Sb₄S₁₃. Below p⁺-layer 3450 is the bottom contact 3460. Contact 3460 can be formed from any suitable material that can conduct electricity, such as a metal, alloy, heavily doped p-type material or a degenerate semiconductor such as a degenerate tetrahedrite semiconductor disclosed herein.

C. Photovoltaic Devices Comprising a C—V—VI Thin Film

The disclosed C—V—VI compounds have a wide range of optical band gaps enabling incorporation into single- and multi-junction solar cells. In some embodiments, the optical band gaps are from about 0.6 eV to about 2.0 eV. C—V—VI thin films made according to disclosed embodiments can be used in photovoltaic devices such as TFSCs.

The constituent elements (Cu, As, Sb, S and Se) of the C—V—VI family are earth-abundant in contrast to indium and tellurium. As a result, materials availability and costs do not limit the potential for TW scalability. Unlike established technologies, A¹₃MCh^{a} has two available positions (M and Ch^{a} substitutions) for tuning band gap (such as between about 0.5 and about 2.4 eV) and maximizing absorption over the entire solar spectrum. In addition, the charge carrier transport properties remain largely unchanged over broad composition ranges. Lastly, treatment of the materials under Ch^{a}-poor conditions forms a conductive, wider band-gap tetrahedrite layer, which can serve as an integrated hole-extraction contact. At the same time, the need for a buffer layer may be eliminated.

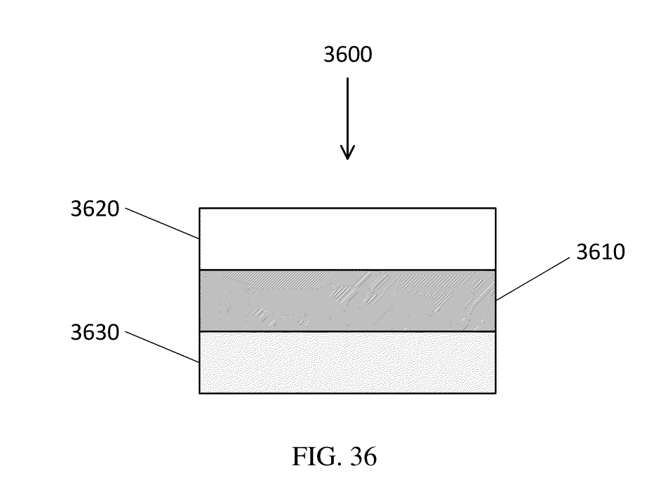

FIG. 36 is a schematic representation of a typical single-junction solar cell 3600 that comprises or consists of an absorber layer 3610 and electrically conductive contact layers 3620 and 3630. Typically, the absorber layer 3610 comprises a C—V—VI compound having a band gap of from about 0.9 eV to about 1.5 eV. With reference to FIG. 36, conductive contact layer 3620 is located vertically above and layer 3630 is located vertically below the absorber layer 3610. The contact layers may contain multiple layers/materials for efficient photogenerated charge carrier extraction. Typically at least one of the contact layers will have an optical band gap greater than that of the absorber layer 3610, and will act as a transparent window contact, to allow incident light to penetrate to the absorber layer. The absorber layer 3610 may comprise a single compound having formula VI or variable (graded) composition of compounds having formula VI. The absorber layer 3610 has a thickness H. In some embodiments, the thickness H is from about 2×10⁻⁷ m to about 20×10⁻⁷ m.

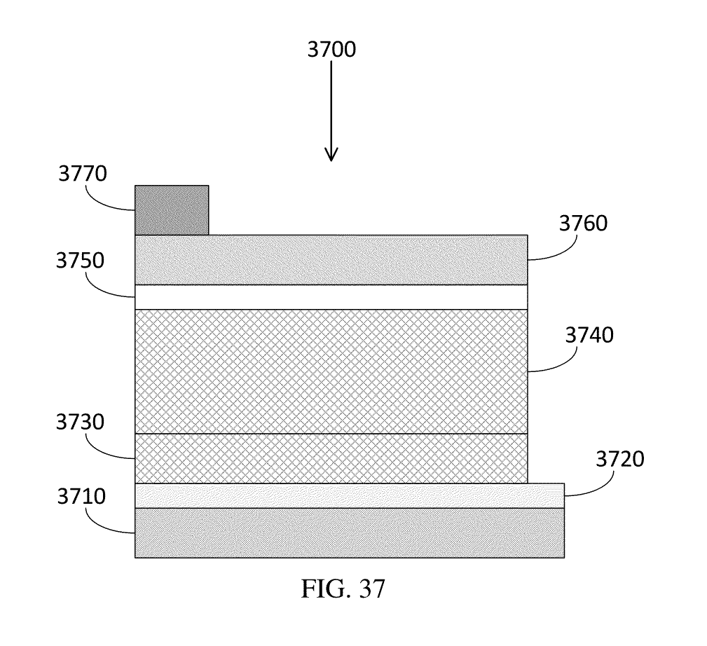

FIG. 37 provides a cross-sectional schematic of an exemplar TFSC device 3700 in a substrate configuration, comprising a C—V—VI thin film. The device configuration is an n-p-p⁺ heterojunction TFSC. An n-p-p⁺ heterojunction with a thin p layer (<1 um) is a drift cell configuration. This means that the n and p⁺ layers provide a strong built-in electric field across the absorber layer, sweeping photogenerated carriers towards their respective contacts, rather than relying on the diffusion of carriers due to their random thermal motion, as in a diffusion cell configuration.

With reference to FIG. 37, at the base of device 3700 is substrate 3710. Substrate 3710 can be made from any suitable material, such as glass, ceramic, plastic or bioplastic, polymers, including high temperature polymers, metals, metal foils, such as copper, aluminum or stainless steel, and metal alloys and combinations thereof. The substrate can be flexible or rigid and can be transparent or opaque. The substrate material will be sufficiently heat resistant to withstand fabrication processes, such as an annealing process. On top of the substrate is a bottom contact layer 3720. Bottom contact layer 3720 can be made using any suitable material that can conduct electricity, such as a metal, alloy, heavily doped p-type material, or a degenerate semiconductor such as a degenerate tetrahedrite semiconductor disclosed herein. In some embodiments bottom contact layer 3720 comprises a metal. On top of bottom contact layer 3720 is a C—V—VI semiconductor layer made according to the disclosed embodiments, forming a p⁺-layer 3730. Suitable materials for the p⁺-layer include materials having formula VII, such as Cu₃AsS₄, Cu₃SbS₄, Cu₃As_{0.2}P_{0.8}S₄, Cu₃AsS_{2.5}Se_{1.5}, and combinations thereof. On top of the p⁺-layer is p-layer 3740, comprising a C—V—VI compound according to the disclosed embodiments. Suitable materials for the p-layer include materials having formula VII, such as Cu₃AsS₄, Cu₃SbS₄, Cu₃As_{0.2}P_{0.8}S₄, Cu₃AsS_{2.5}Se_{1.5}, and any combination thereof. In some embodiments the properties of the p-layer are assumed to be identical to those of the p⁺-layer. Buffer layer 3750 and the window 3760 together form an n-type layer. Buffer layer 3750 can be formed from any material suitable for an n-type layer. Preferably, buffer layer 3750 comprises an n-type material with a band gap E_{g} from greater than the band gap of the p-type layer to less than the band gap of the window layer, preferably from about 1.5 to about 3.5 eV, more preferably about 2.5 eV. Exemplary materials for the buffer layer 3750 include, but are not limited to, ZnO, SnO₂, IGZO (indium gallium zinc oxide), CdS, ZnS, ZnSe, Zn(O,S), (Zn,Mg)O, In₂S₃, In₂Se₃ and silicon, which may or may not be doped, such as with phosphorous or arsenic. In some embodiments, the buffer layer material has an electron majority carrier concentration of from about 1×10¹⁵ to about 1×10¹⁸ cm⁻³. The window layer 3760 is formed from any material suitable for an n-type layer that allows photons of light to pass to the layers below. Preferably window layer 3760 comprises an n-type material with a band gap E_{g} of greater than about 3 eV. Exemplary suitable materials for the window layer include, but are not limited to, ITO (indium tin oxide), SnO₂, FTO (fluorine doped tin oxide), ZnO, ZnO:Al (Al doped ZnO) and ZnO:B (boron doped ZnO). Top contact electrode 3770 is placed above window layer 3760. Top contact electrode 3770 can be formed from any suitable material that can conduct electricity, such as a metal, alloy, heavily doped p-type material or a degenerate semiconductor, such as a degenerate tetrahedrite semiconductor disclosed herein.

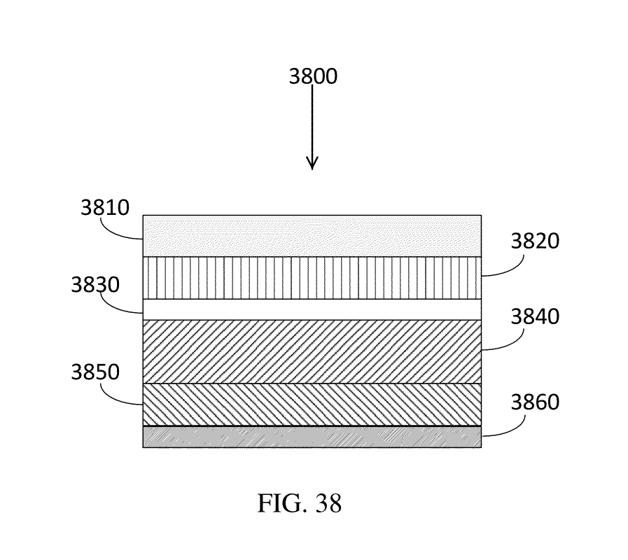

FIG. 38 provides a cross-sectional schematic of a superstrate configuration for an exemplar TFSC device 3800 comprising a C—V—VI compound. Device 3800 has a substrate 3810. Substrate 3810 typically is transparent, such as, for example, a glass substrate. Light shines through transparent substrate 3810 and through the n-type layer comprising a window layer 3820 and a buffer layer 3830. Window layer 3820 and buffer layer 3830 can comprise any suitable materials, such as those listed above with respect to device 3700. In particular embodiments, window layer 3820 comprises SnO₂ and buffer layer 3830 comprises CdS. Below buffer layer 3830 is the p-type absorber layer 3840. Layer 3840 comprises a C—V—VI compound according to the disclosed embodiments. Suitable materials for p-layer 3840 include materials having formula VII, such as Cu₃AsS₄, Cu₃SbS₄, Cu₃As_{0.2}P_{0.8}S₄, Cu₃AsS_{2.5}Se_{1.5}, and combinations thereof. Below p-layer 3840 is p⁺-layer 3850, also comprising a C—V—VI compound according to the disclosed embodiments, such as those listed as suitable for p-layer 3840. In some embodiments p-layer 3840 and p⁺-layer 3850 have the same properties. Below p⁺-layer 3850 is the bottom contact 3860. Contact 3860 can be formed from any suitable material that can conduct electricity, such as a metal, alloy, heavily doped p-type material or a degenerate semiconductor such as a degenerate tetrahedrite semiconductor disclosed herein.

D. Photovoltaic Devices Comprising Both a Tetrahedrite Thin Film and a C—V—VI Thin Film

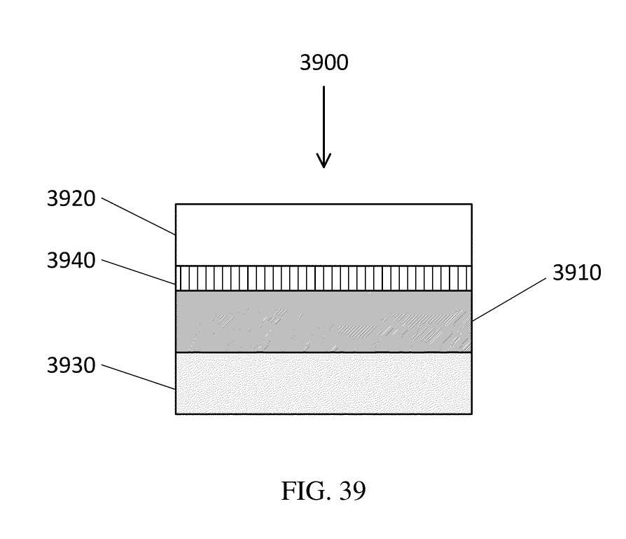

Tetrahedrite compounds and C—V—VI compounds can also be used in combination in a device, such as a photovoltaic device. FIG. 39 provides a schematic representation of one exemplary solar cell 3900 comprising both a tetrahedrite compound and a C—V—VI compound. With reference to FIG. 39, a single-junction solar cell 3900 may comprise an absorber layer 3910, electrically conductive contact layers 3920 and 3930, and a p⁺ layer 3940 for efficient photogenerated charge carrier extraction. In some embodiments, the absorber layer 3910 has an optical band gap of from about 0.9 eV to about 1.5 eV. The p⁺-layer 3940 typically has an optical band gap greater than that of the absorber layer 3910 to allow incident light to penetrate to the absorber layer. In some embodiments, the absorber layer 3910 comprises a compound having formula VII, and the p⁺-layer 3940 comprises a tetrahedrite compound having formula V. In other embodiments, the absorber layer 3910 comprises a compound having formula V, and the p⁺-layer 3940 comprises a compound having formula VII. In still further embodiments, the absorber layer and/or the p⁺-layer comprise both a compound having formula VII and a compound having formula V. The two compounds may be in discrete sub-layers, or they may be in a single layer that is concentration graded from a material substantially comprising the compound having formula V at one point or layer face to a material substantially comprising the compound having formula VII. In some embodiments, the p⁺ layer has a thickness of from about 0.1×10⁻⁷ to about 1.5×10⁻⁷ m.

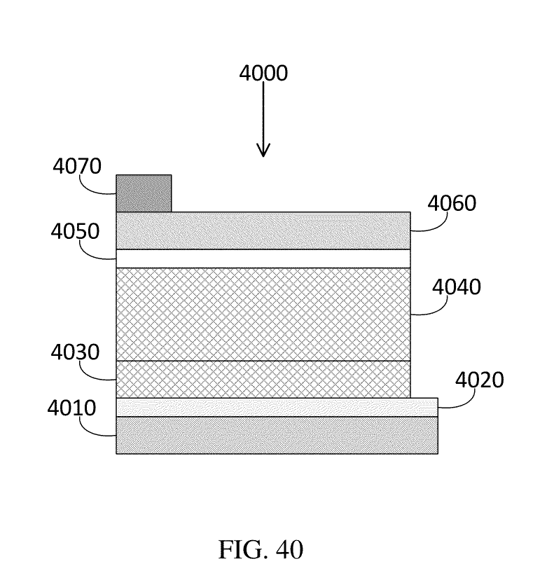

FIG. 40 provides a cross-sectional schematic of an exemplar TFSC device 4000 in a substrate configuration, comprising both a tetrahedrite thin film and a C—V—VI thin film. The device configuration is an n-p-p⁺ heterojunction TFSC. An n-p-p⁺ heterojunction with a thin p layer (<1 um) is a drift cell configuration. This means that the n and p⁺ layers provide a strong built-in electric field across the absorber layer, sweeping photogenerated carriers towards their respective contacts, rather than relying on the diffusion of carriers due to their random thermal motion, as in a diffusion cell configuration.

With reference to FIG. 40, at the base of device 4000 is substrate 4010. Substrate 4010 can be made from any suitable material, such as glass, ceramic, plastic or bioplastic, polymers, including high temperature polymers, metals, metal foils, such as copper, aluminum or stainless steel, and metal alloys and combinations thereof. The substrate can be flexible or rigid and can be transparent or opaque. The substrate material will be sufficiently heat resistant to withstand fabrication processes, such as an annealing process. On top of the substrate is a bottom contact layer 4020. Bottom contact layer 4020 can be made using any suitable material that can conduct electricity, such as a metal, alloy, heavily doped p-type material, or a degenerate semiconductor such as a degenerate tetrahedrite semiconductor disclosed herein. In some embodiments bottom contact layer 1420 comprises a metal. On top of bottom contact layer 4020 is semiconductor layer made according to the disclosed embodiments, forming a p⁺-layer 4030. Suitable materials for the p⁺-layer include materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃; compounds having formula VII, such as Cu₃AsS₄, Cu₃SbS₄, Cu₃As_{0.2}P_{0.8}S₄ and Cu₃AsS_{2.5}Se_{1.5}, that are doped with Si, Ge or Sn and any combination thereof, for example Cu₃Sb_{0.98}Ge_{0.02}S₄. In some particular embodiments, the p⁺-layer comprises Cu₁₂Sb₄Se₁₃. On top of the p⁺-layer is p-layer 4040, comprising a compound according to the disclosed embodiments. Suitable materials for the p-layer include materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃, compounds having formula VII, such as Cu₃AsS₄, Cu₃SbS₄, Cu₃As_{0.2}P_{0.8}S₄ and Cu₃AsS_{2.5}Se_{1.5}, and any combination thereof. In some embodiments the properties of the p-layer are assumed to be identical to those of the p⁺-layer. Buffer layer 4050 and the window 4060 together form an n-type layer. Buffer layer 4050 can be formed from any material suitable for an n-type layer. Preferably, buffer layer 4050 comprises an n-type material with a band gap E_{g} from greater than the band gap of the p-type layer, to less than the band gap of the window layer, preferably from about 1.5 to about 3.5 eV, more preferably about 2.5 eV. Exemplary materials for the buffer layer 4050 include, but are not limited to, ZnO, SnO₂, IGZO, CdS, ZnS, ZnSe, Zn(O,S), (Zn,Mg)O, In₂S₃, In₂Se₃ and silicon, which may or may not be doped, such as with phosphorous or arsenic. The window layer 4060 is formed from any material suitable for an n-type layer that allows photons of light to pass to the layers below. Preferably window layer 4060 comprises an n-type material with a band gap E_{g} of greater than about 3 eV. Exemplary suitable materials for the window layer include, but are not limited to, ITO (indium tin oxide), SnO₂, FTO (fluorine doped tin oxide), ZnO, ZnO:Al (Al doped ZnO) and ZnO:B (boron doped ZnO). Top contact electrode 4070 is placed above window layer 4060. Top contact electrode 4070 can be formed from any suitable material that can conduct electricity, such as a metal, alloy, heavily doped p-type material or a degenerate semiconductor, such as a degenerate tetrahedrite semiconductor disclosed herein.

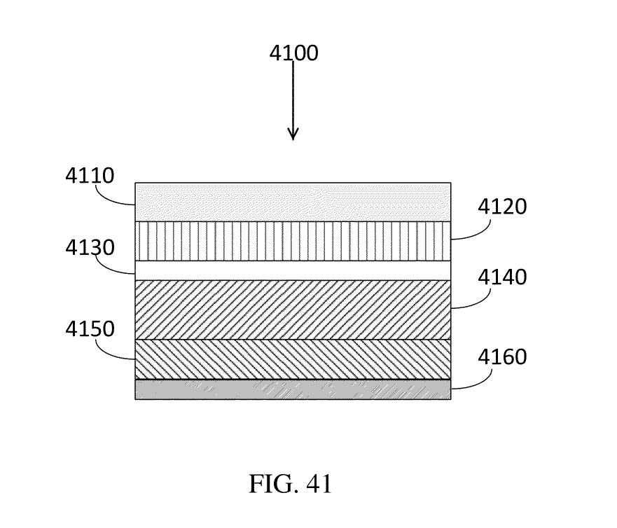

FIG. 41 provides a cross-sectional schematic of a superstrate configuration for an exemplar TFSC device 4100. Device 4100 has a substrate 4110. Substrate 4110 typically is transparent, such as, for example, a glass substrate. Light passes through transparent substrate 4110 and through the n-type layer comprising a window layer 4120 and a buffer layer 4130. Window layer 4120 and buffer layer 4130 can comprise any suitable materials, such as those listed above with respect to device 5600. In particular embodiments, window layer 4120 comprises SnO₂ and buffer layer 4130 comprises CdS. Below buffer layer 4130 is the p-type absorber layer 4140. Layer 4140 comprises a compound according to the disclosed embodiments. Suitable materials for p-layer 4140 include materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃, compounds having formula VII, such as Cu₃AsS₄, Cu₃SbS₄, Cu₃As_{0.2}P_{0.8}S₄ and Cu₃AsS_{2.5}Se_{1.5}, and any combination thereof. Below p-layer 4140 is p⁺-layer 4150, also comprising a compound according to the disclosed embodiments. Suitable materials for the p⁺-layer include materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃, compounds having formula VII, such as Cu₃AsS₄, Cu₃SbS₄, Cu₃As_{0.2}P_{0.8}S₄ and Cu₃AsS_{2.5}Se_{1.5}, that are doped with Si, Ge or Sn, and any combination thereof, for example Cu₃Sb_{0.98}Ge_{0.02}S₄. In some embodiments p-layer 4140 and p⁺-layer 4150 have the same properties. In some particular embodiments, p⁺-layer 4150 comprises Cu₁₂Sb₄S₁₃. Below p⁺-layer 4150 is the bottom contact 4160. Contact 4160 can be formed from any suitable material that can conduct electricity, such as a metal, alloy, heavily doped p-type material or a degenerate semiconductor, such as a degenerate tetrahedrite semiconductor disclosed herein.

In some embodiments, the advantages of the C—V—VI materials enable the use of a thin absorber layer (<1 μm). With such a thin film, carrier transport is enhanced by the presence of an internal electric field across the absorber layer, which sweeps photogenerated carriers towards their respective contacts. Efficiency is improved by drift-based cell operation. In this mode, the absorber is also expected to be much more tolerant of defects, potentially relaxing tolerances and easing manufacturing. The efficiency of a drift cell is modeled to exceed diffusion-based, single-junction TFSCs by up to 2 percentage points.

E. Multi-Junction Solar Cells

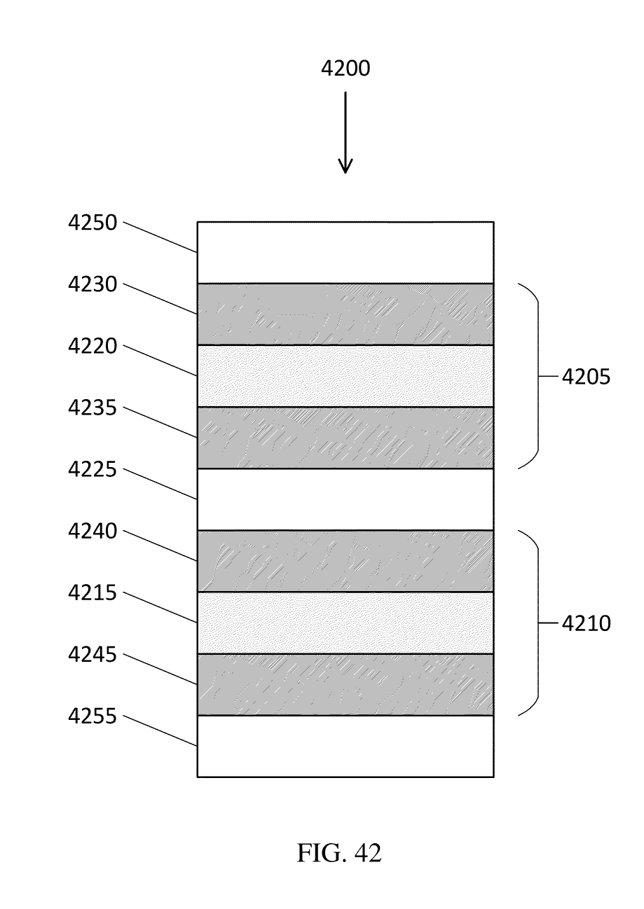

Also disclosed herein are multi-junction devices that comprise two or more cells. The cells can be configured in any suitable configuration, such as a mechanically stacked configuration. FIG. 42 provides a schematic of an exemplary multi-junction device 4200 comprising two stacked cells 4205 and 4210. With reference to FIG. 42, cell 4205 has an absorber layer 4215 with a band gap E_{G}1 greater than the band gap E_{G}2 of the absorber layer 4220 of cell 4210. The cells are electrically separated by an insulating layer 4225. The insulating layer 4225 can comprise any suitable insulating material, such as glass. Conductive contact layer 4230 has a band gap greater than that of the absorber layer 4220, and conductive contact layers 4235 and 4240 have optical band gaps greater than that of absorber layer 4215. Contact layer 4245 provides the second contact layer for cell 4210, and the multi-junction cell also comprises at least one substrate 4250, and optionally a second substrate 4255.

In some embodiments, the insulating layer 4225 is absent. This allows direct electrical contact between cells 4205 and 4210, through the electrically conductive contact layers 4235 and 4240.

A person of ordinary skill in the art will appreciate that multi-junction cells can be extended to three (3) or more cells with absorber layer band gaps following the sequence E_{G}1>E_{G}2>E_{G}3> etc. Table 3 provides exemplary ranges for absorber layer band gaps for up to a three cell multi-junction device.

TABLE 3
Exemplary absorber band gap energies for
a multi-junction device with three cells

| Number of cells | E_{G}1 (eV) | E_{G}2 (eV) | E_{G}3 (eV) |
|---|---|---|---|
| 1 | 0.9-1.5 | | |
| 2 | 1.4-1.7 | 0.8-1.1 | |
| 3 | 1.6-1.8 | 1.1-1.4 | 0.6-0.9 |

In some embodiments, at least one solar cell has at least one contact layer made of a transparent conductive oxide adjacent to the hole extraction layer. The transparent conductive oxide may have an electron carrier concentration of at least 1×10¹⁸ cm⁻³ to effectively extract carriers by tunneling—a tunnel-junction. A person of ordinary skill in the art will appreciate that the bottom and top contacts are interchangeable and depend on substrate or superstrate configuration of the solar cell.

The thin film solar cell stack is typically deposited onto a rigid (e.g. glass, metal plate) or flexible substrate (e.g. metal foil, polymer, glass) via vacuum or wet deposition methods that can be produced by one of ordinary skill in the art.

F. Other Devices

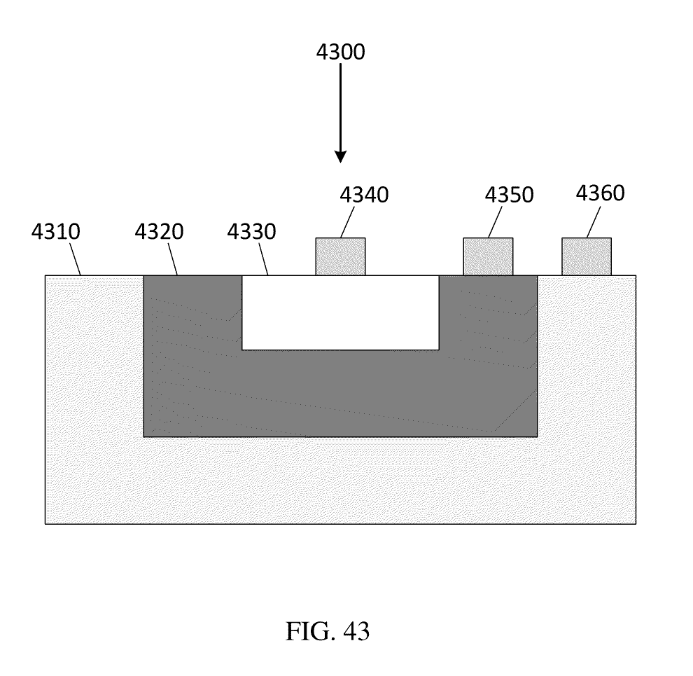

The compounds disclosed herein are also useful for making other electrical devices. FIG. 43 is a schematic of an exemplar bipolar junction transistor 4300 that comprises one or more of the disclosed compounds. Bipolar junction transistor 4300 typically has three semiconductor regions: a collector region 4310; a base region 4320; and an emitter region 4330. Regions 4310, 4320 and 4330 are, respectively, p-type, n-type and p-type in a PNP transistor, and n-type, p-type and n-type in an NPN transistor. Suitable materials for the p-type regions include materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃, compounds having formula VII, such as Cu₃AsS₄, Cu₃SbS₄, Cu₃As_{0.2}P_{0.8}S₄ and Cu₃AsS_{2.5}Se_{1.5}, and any combination thereof. The n-type regions can comprise any suitable semiconductor material, such as CdS, ZnS, ZnSe, Zn(O,S), (Zn,Mg)O, In₂S₃, In₂Se₃ and silicon, which may or may not be doped, such as with phosphorous or arsenic. Each semiconductor region 4310, 4320 and 4330 is connected to an electrode 4340. With reference to FIG. 43, the emitter region 4330 is connected to the emitter electrode 4340, the base electrode 4350 is connected to the base region 4320, and the collector electrode 4360 is connected to the collector region 4310. These electrodes can be formed from any suitable material that can conduct electricity, such as a metal, alloy, heavily doped p-type material, or a degenerate semiconductor such as a degenerate tetrahedrite semiconductor, disclosed herein.

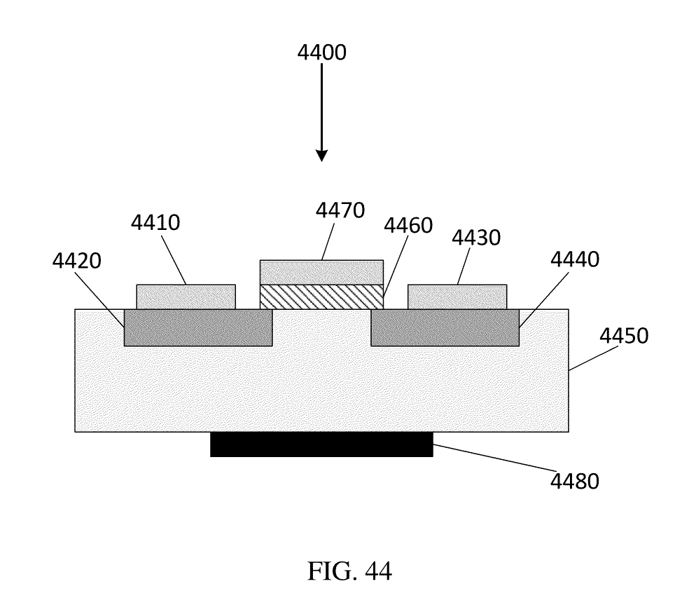

FIG. 44 is a schematic of an exemplar field effect transistor 4400. With reference to FIG. 44, the transistor 4400 has a source electrode 4410 connected to the source 4420 and a drain electrode 4430 connected to the drain 4440. The electrodes can be formed from any suitable material that can conduct electricity, such as a metal, alloy, heavily doped p-type material, or a degenerate semiconductor, such as a degenerate tetrahedrite semiconductor disclosed herein. Both the source 4420 and drain 4440 comprise n-type semiconductors. Suitable materials for the source 4420 and drain 4440 are any materials that are n-type semiconductors, such as CdS, ZnS, ZnSe, Zn(O,S), (Zn,Mg)O, In₂S₃, In₂Se₃ and silicon, which may or may not be doped, such as with phosphorous or arsenic. The source 4420 and the drain 4440 are in contact with a p-type substrate 4450. Suitable materials for p-type substrate 4450 include materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃, compounds having formula VII, such as Cu₃AsS₄, Cu₃SbS₄, Cu₃As_{0.2}P_{0.8}S₄ and Cu₃AsS_{2.5}Se_{1.5}, and any combination thereof. An insulating layer 4460, formed from a suitable electrical insulator, such as SiO₂, separates the gate electrode 4470 from the substrate 4450, and an electrode 4480 is attached to the p-type substrate 4450. These electrodes 4470, 4480 can also be formed from any suitable material that can conduct electricity, such as a metal, alloy, heavily doped p-type material, or a degenerate semiconductor, such as a degenerate tetrahedrite semiconductor disclosed herein. In some embodiments at least one of the electrodes comprises a metal.

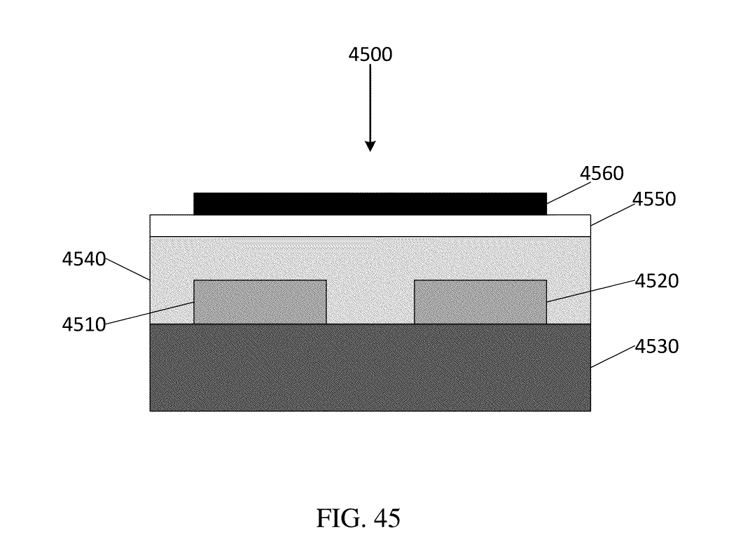

FIG. 45 is a schematic of a configuration of an exemplar thin film transistor 4500. With reference to FIG. 45, the source electrode 4510 and drain electrode 4520 are in contact with the substrate 4530. Electrodes 4510, 4520 can also be formed from any suitable material that can conduct electricity, such as a metal, alloy, heavily doped p-type material or a degenerate semiconductor, such as a degenerate tetrahedrite semiconductor disclosed herein. Substrate 4530 can be made from any suitable material, such as glass, ceramic, plastic or bioplastic, polymers, including high temperature polymers, and metal foils, such as copper, aluminum or stainless steel. Substrate 4530 can be flexible or rigid and can be transparent or opaque. The substrate material will be sufficiently heat resistant to withstand the annealing process. Channel layer 4540 is on top of the substrate 4530 and electrodes 4510, 4520. Suitable materials for the channel layer 4540 include materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃, compounds having formula VII, such as Cu₃AsS₄, Cu₃SbS₄, Cu₃As_{0.2}P_{0.8}S₄ and Cu₃AsS_{2.5}Se_{1.5}, and any combination thereof. The channel layer material may be in an amorphous form, a single phase crystalline form, a multiphase crystalline form, or a combination thereof. On top of the channel layer 4540 is the gate dielectric layer 4550. Gate dielectric layer 4550 is made from any suitable electrical indulator material, such as SiO₂. The gate electrode 4560 is on top of the gate dielectric layer 4550. Gate electrode 4560 can be made from any suitable material, such as indium tin oxide (ITO), SnO₂, FTO (fluorine doped tin oxide), ZnO, ZnO:Al (Al doped ZnO) and ZnO:B (boron doped ZnO).

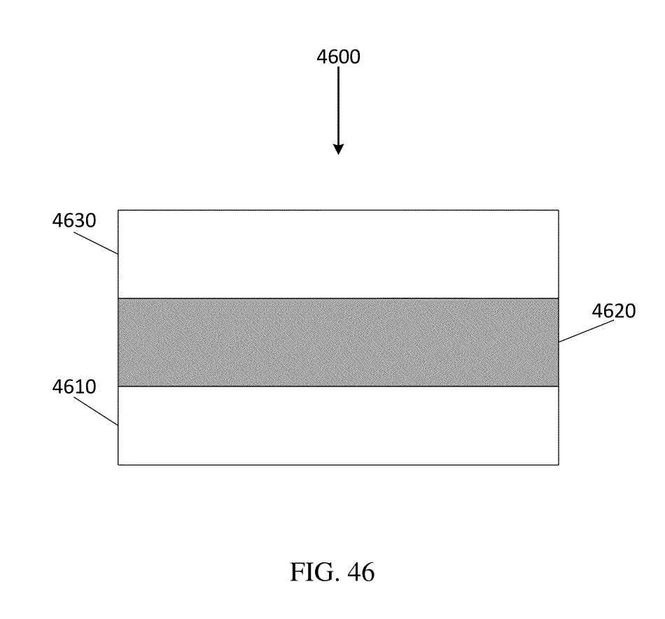

FIG. 46 schematically shows the components and configuration of one embodiment of a Schottky barrier diode 4600. Diode 4600 comprises a first contact layer 4610, comprising any suitable material, such as molybdenum, platinum, chromium or tungsten, and certain silicides, for example, palladium silicide and platinum silicide. First contact layer 4610 is in contact with a semiconductor layer 4620. Suitable materials for the channel layer include materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃, compounds having formula VII, such as Cu₃AsS₄, Cu₃SbS₄, Cu₃As_{0.2}P_{0.8}S₄, Cu₃AsS_{2.5}Se_{1.5}, and any combination thereof. A second contact layer 4630 is in contact with the semiconductor layer 4620, but not in contact with the first contact layer 4610. Second contact layer 4630 is made from any suitable material that can conduct electricity, such as a metal, alloy, heavily doped p-type material or a degenerate semiconductor, such as a degenerate tetrahedrite semiconductor disclosed herein.

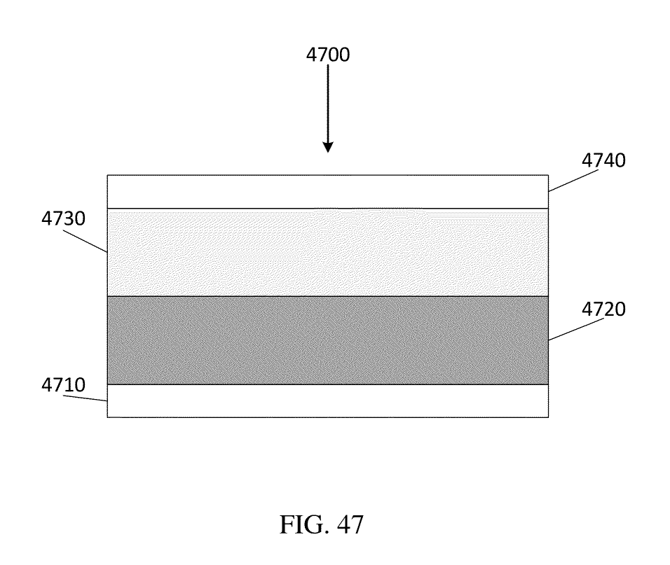

FIG. 47 schematically shows the components and configuration of one embodiment of a light emitting diode 4700. A first contact electrode 4710 is in contact with a p-type semiconductor layer 4720. The p-type semiconductor layer 4720 comprises any suitable material including materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃, compounds having formula VII, such as Cu₃AsS₄, Cu₃SbS₄, Cu₃As_{0.2}P_{0.8}S₄ and Cu₃AsS_{2.5}Se_{1.5}, and any combination thereof. The p-type semiconductor layer 4720 is in contact with an n-type semiconductor layer 4730, which in turn is in contact with a second contact electrode 4740. Contact electrodes 4710, 4740 are made from any suitable materials that can conduct electricity, such as a metal, alloy, heavily doped p-type material or a degenerate semiconductor, such as a degenerate tetrahedrite semiconductor disclosed herein. The n-type layer 4730 comprises any suitable material, such that the combination of the p-type layer 4720 and n-type layer 4730 result in light of a required color being emitted when the diode is connected to an electrical source.

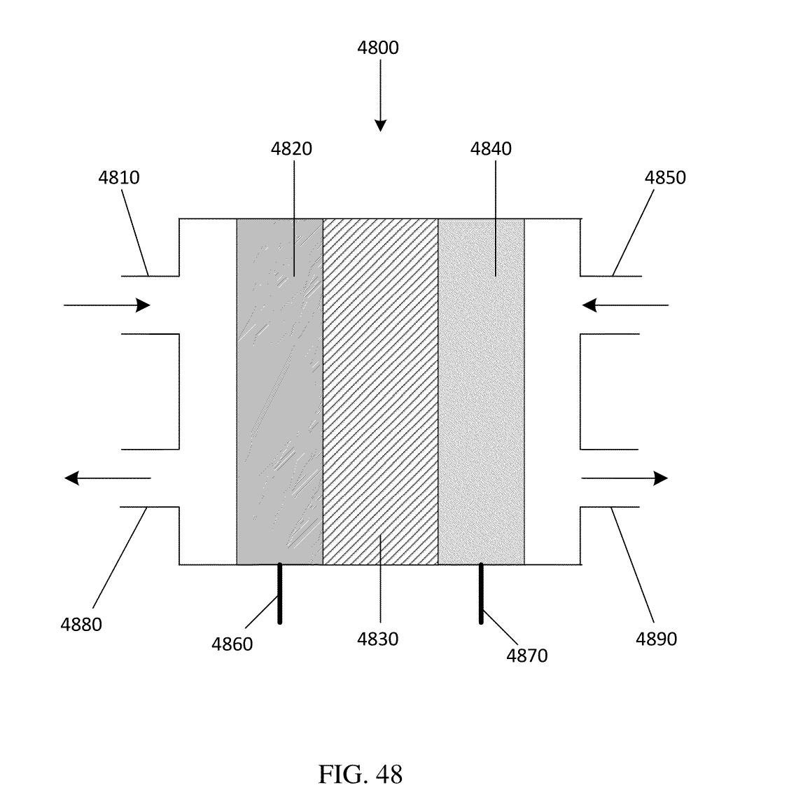

FIG. 48 schematically shows the components and configuration of one embodiment of a fuel cell 4800. The fuel, typically hydrogen gas, enters through inlet 4810 and contacts the anode electrode 4820. Anode electrode 4820 comprises any suitable material, such as platinum powder. The fuel is converted into a positively charged ion, which passes through electrolyte 4830 to the cathode electrode 4840. Electrolyte 4830 comprises any suitable material, such as concentrated potassium hydroxide or concentrated sodium hydroxide solutions. Suitable materials for the cathode electrode 4840 include materials having formula V, such as Cu₁₂Sb₄S₁₃, Cu₁₂Sb₄Se₁₃, Cu₁₀Zn₂Sb₄Se₁₃, Cu₁₀Mn₂Sb₄S₁₃, Cu₁₁InSb₄S₁₃ and Cu₁₀Zn₂Sb₄S₁₃, compounds having formula VII, such as Cu₃AsS₄, Cu₃SbS₄, Cu₃As_{0.2}P_{0.8}S₄, and Cu₃AsS_{2.5}Se_{1.5}, and any combination thereof. A second gas, typically oxygen, enters inlet 4850 and reacts with the positively charged ions, forming a third chemical, typically water. Electrical contacts 4860 and 4870 provide electrical energy to an external device to be powered by the fuel cell 4800. Unused fuel leaves the cell 4800 through an outlet 4880 and a mixture of unreacted second gas and the third chemical leaves the cell through outlet 4890.

One of the advantages of the disclosed compounds is the ability to produce an ultra-thin absorber layer. To demonstrate that tetrahedrite compounds are suitable for making a high-efficiency TFSC, device simulations were carried out using a solar cell capacitance simulator (SCAPS) software tool using the configuration shown in FIG. 35 with Cu₁₀Zn₂Sb₄Se₁₃ as the p-type absorber. Measured properties of Cu₁₀Zn₂Sb₄Se₁₃ from Table 1 and FIG. 5 were used as inputs to the model.

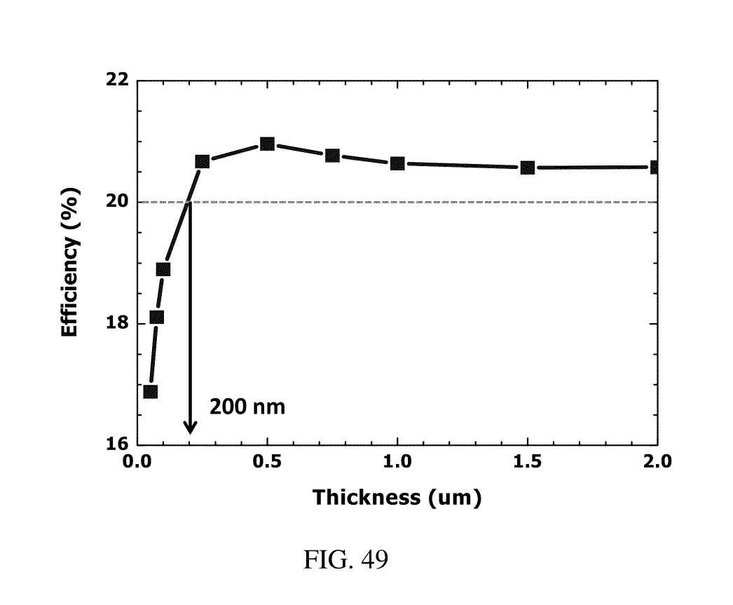

For example, the strong onset of absorption for Cu₁₀Zn₂Sb₄Se₁₃ combined with the ability to reach a maximum value of 3×10⁵ cm⁻¹ at band gap (E_{G}) plus 0.6 eV suggests that the thickness of absorber layer can be reduced to <1 μm without significant loss in performance. FIG. 49 shows that the efficiency of a Cu₁₀Zn₂Sb₄Se₁₃ thin film absorber layer depends on the thickness of that layer. FIG. 49 establishes that efficiencies of greater than 20% can be achieved even when the absorber layer thickness is above about 200 nm, confirming that absorber layers comprising compounds according to formula V that exhibit a strong onset coupled with high absorption can be utilized for high efficiency, thin film solar cells.

When the thickness is greater than 500 nm, the efficiency reduces slightly before saturating. Without being bound to a particular theory, this may be due to the thickness of the absorber layer being greater than an absorption length. As a result, the charge carriers have to diffuse to the edge of the space charge region before getting swept by the drift field, increasing the number of recombination events and resulting in a decreased device efficiency. The thickness requirement for optimal efficiency of a Cu₁₀Zn₂Sb₄Se₁₃ layer is considerably lower than that for a monocrystalline silicon-(c-Si) (from about 20 to 260 mu), CIGS- (from about 1 to 2 μm) or a CdTe- (from about 2 to 5 μm) based solar cell, and is similar to an amorphous silicon-based TFSC. However, Cu₁₀Zn₂Sb₄Se₁₃ has improved electrical and optical properties compared with amorphous silicon. Due to the amorphous nature of amorphous silicon, it has considerably lower transport properties compared to crystalline silicon, or other TFSC absorber materials. In addition, amorphous silicon suffers from light induced degradation (the Stabler-Wronski effect). As a result, the efficiency of a cell (or module) can decrease considerably (by up to about 30%) within 6 months of initial operation. Tetrahedrite-based TFSCs have a similar minimum thickness as amorphous silicon (300-500 nm), but the tetrahedrite compounds are more stable and do not degrade under illumination.

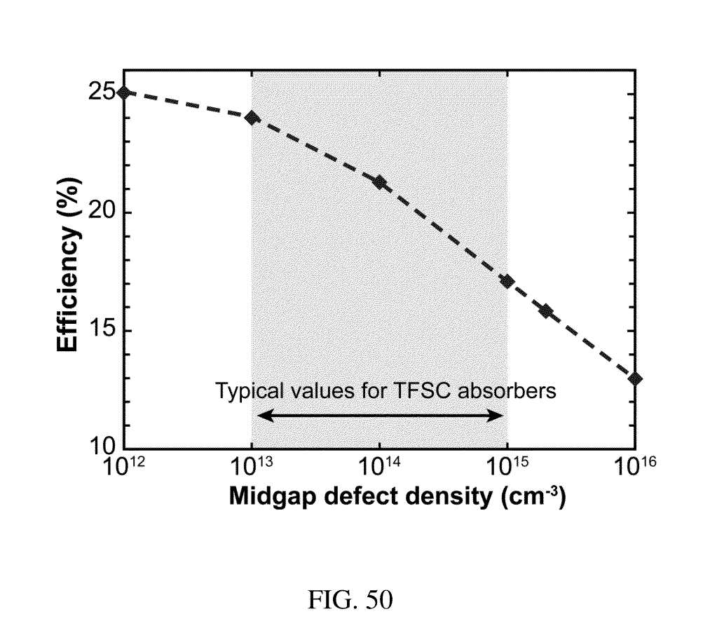

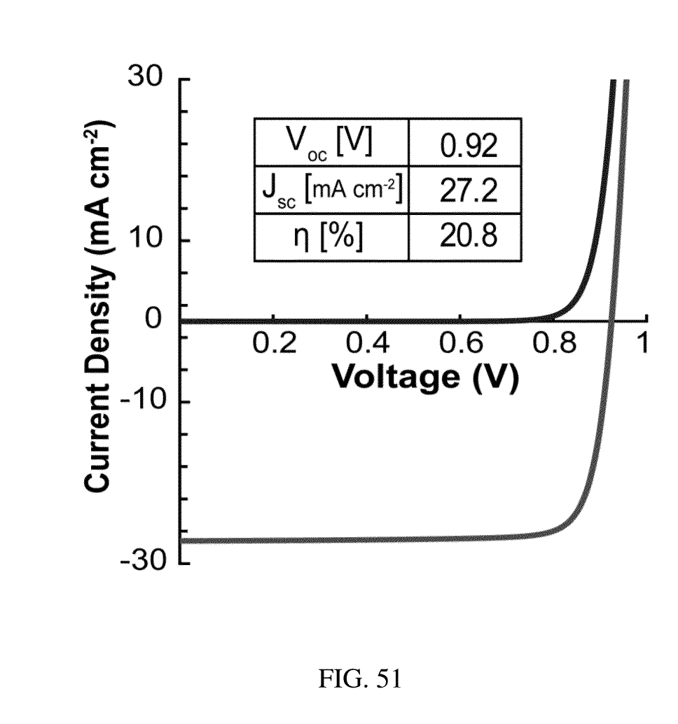

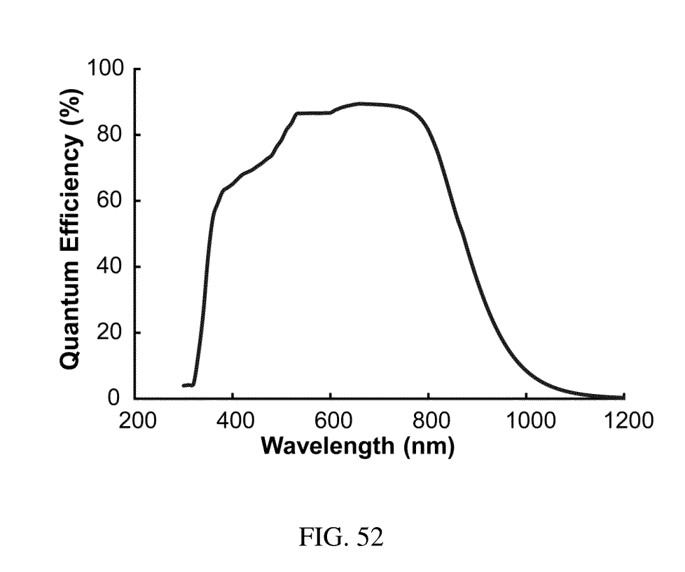

The concentration of midgap defect states in a material can affect the photoconversion efficiency in a TFSC. FIG. 50 shows the variation in device efficiency as a function of midgap defect density for a 300-nm thick Cu₁₀Zn₂Sb₄Se₁₃ absorber layer in a TFSC. Efficiencies greater than 20% were achieved with a trap density of 10¹⁴ cm⁻³, while a large trap density of 10¹⁶ cm⁻³ still provided a 13% efficient TFSC. This indicates that the Cu₁₀Zn₂Sb₄Se₁₃ absorber layer need not require the intensive process optimization that other materials required to provide a high quality, defect-free material. A Cu₁₀Zn₂Sb₄Se₁₃ absorber layer is relatively defect tolerant, due perhaps to the higher absorption coefficient and the drift cell configuration. The simulated current-voltage characteristics of a 300 nm Cu₁₀Zn₂Sb₄Se₁₃-based TFSC shown in FIG. 51, and the plot of the simulated quantum efficiency, which approaches 90% in wavelength range of 530-780 nm, shown in FIG. 52, validate Cu₁₀Zn₂Sb₄Se₁₃ as a high-performance TFSC absorber material.

### VIII. Working Examples

### Example 1

### A. Powder Synthesis of Tetrahedrite Compounds

Cu₁₀Zn₂Sb₄S₁₃:

Polycrystalline tetrahedrite Cu₁₀Zn₂Sb₄S₁₃ was synthesized by a standard solid-state reaction. The starting materials were commercial reagent grade Cu, Zn, Sb, and S having purity >99.95%, obtained from Alfa Aesar. Stoichiometric quantities of reactants, i.e. 10 molar equivalents of Cu, 2 molar equivalents of Zn, 4 molar equivalents of Sb and 13 molar equivalents of S, were mixed and heated at 450° C. for 3 weeks in evacuated sealed fused-silica tubes, and subsequently cooled to ambient temperature after switching off the furnace. Additional regrinding and reheating produced a single-phase sample. The resulting polycrystalline powder was crushed and molded into pellets having a diameter of about 0.5 inches. These were sintered at 450° C. for 24 hours to maximize the density of pellets (about 85%), for analysis of physical properties.

Cu_{11.5}Zn_{0.5}Sb₄S₁₃:

Polycrystalline tetrahedrite Cu_{11.5}Zn_{0.5}Sb₄S₁₃ was prepared following the method described above, starting with 11.5 molar equivalents of Cu, 0.5 molar equivalents of Zn, 4 molar equivalents of Sb and 13 molar equivalents of S.

Cu₁₁ZnSb₄S₁₃:

Polycrystalline tetrahedrite Cu₁₁ZnSb₄S₁₃ was prepared following the method described above, starting with 11 molar equivalents of Cu, 1 molar equivalent of Zn, 4 molar equivalents of Sb and 13 molar equivalents of S.

Cu_{10.5}Zn_{1.5}Sb₄S₁₃:

Polycrystalline tetrahedrite Cu_{10.5}Zn_{1.5}Sb₄S₁₃ was prepared following the method described above, starting with 10.5 molar equivalents of Cu, 1.5 molar equivalents of Zn, 4 molar equivalents of Sb and 13 molar equivalents of S.

Cu₁₀Mn₂Sb₄S₁₃:

Polycrystalline tetrahedrite Cu₁₀Mn₂Sb₄S₁₃ was prepared following the method described above, starting with 10 molar equivalents of Cu, 2 molar equivalents of Mn, 4 molar equivalents of Sb and 13 molar equivalents of S.

Cu_{10.5}Mn_{1.5}Sb₄S₁₃:

Polycrystalline tetrahedrite Cu_{10.5}Mn_{1.5}Sb₄S₁₃ was prepared following the method described above, starting with 10.5 molar equivalents of Cu, 1.5 molar equivalents of Mn, 4 molar equivalents of Sb and 13 molar equivalents of S.

Cu₁₁MnSb₄S₁₃:

Polycrystalline tetrahedrite Cu₁₁MnSb₄S₁₃ was prepared following the method described above, starting with 11 molar equivalents of Cu, 1 molar equivalent of Mn, 4 molar equivalents of Sb and 13 molar equivalents of S.

Cu_{11.5}Mn_{0.5}Sb₄S₁₃:

Polycrystalline tetrahedrite Cu_{11.5}Mn_{0.5}Sb₄S₁₃ was prepared following the method described above, starting with 11.5 molar equivalents of Cu, 0.5 molar equivalents of Mn, 4 molar equivalents of Sb and 13 molar equivalents of S.

Cu₁₀Fe₂Sb₄S₁₃:

Polycrystalline tetrahedrite Cu₁₀Fe₂Sb₄S₁₃ was prepared following the method described above, starting with 10 molar equivalents of Cu, 2 molar equivalents of Fe, 4 molar equivalents of Sb and 13 molar equivalents of S.

Cu₁₁FeSb₄S₁₃:

Polycrystalline tetrahedrite Cu₁₁FeSb₄S₁₃ was prepared following the method described above, starting with 11 molar equivalents of Cu, 1 molar equivalent of Fe, 4 molar equivalents of Sb and 13 molar equivalents of S.

Cu₁₀Co₂Sb₄S₁₃:

Polycrystalline tetrahedrite Cu₁₀Co₂Sb₄S₁₃ was prepared following the method described above, starting with 10 molar equivalents of Cu, 2 molar equivalents of Co, 4 molar equivalents of Sb and 13 molar equivalents of S.

Cu₁₀Ni₂Sb₄S₁₃:

Polycrystalline tetrahedrite Cu₁₀Ni₂Sb₄S₁₃ was prepared following the method described above, starting with 10 molar equivalents of Cu, 2 molar equivalents of Ni, 4 molar equivalents of Sb and 13 molar equivalents of S.

Cu₁₂Sb₄S₁₃:

Polycrystalline tetrahedrite Cu₁₂Sb₄S₁₃ was prepared following the method described above, starting with 12 molar equivalents of Cu, 4 molar equivalents of Sb and 13 molar equivalents of S.

Cu₁₁InSb₄S₁₃:

Polycrystalline tetrahedrite Cu₁₁InSb₄S₁₃ was prepared following the method described above, starting with 11 molar equivalents of Cu, 1 molar equivalent of In, 4 molar equivalents of Sb and 13 molar equivalents of S.

Cu₉AgZn₂Sb₄S₁₃:

Polycrystalline tetrahedrite Cu₉AgZn₂Sb₄S₁₃ was prepared following the method described above, starting with 9 molar equivalents of Cu, 1 molar equivalent of Ag, 2 molar equivalents of Zn, 4 molar equivalents of Sb and 13 molar equivalents of S.

Cu₈Ag₂Zn₂Sb₄S₁₃:

Polycrystalline tetrahedrite Cu₈Ag₂Zn₂Sb₄S₁₃ was prepared following the method described above, starting with 8 molar equivalents of Cu, 2 molar equivalents of Ag, 2 molar equivalents of Zn, 4 molar equivalents of Sb and 13 molar equivalents of S.

Cu₇Ag₃Zn₂Sb₄S₁₃:

Polycrystalline tetrahedrite Cu₇Ag₃Zn₂Sb₄S₁₃ was prepared following the method described above, starting with 7 molar equivalents of Cu, 3 molar equivalents of Ag, 2 molar equivalents of Zn, 4 molar equivalents of Sb and 13 molar equivalents of S.

Cu₉AgMn₂Sb₄S₁₃:

Polycrystalline tetrahedrite Cu₉AgMn₂Sb₄S₁₃ was prepared following the method described above, starting with 9 molar equivalents of Cu, 1 molar equivalent of Ag, 2 molar equivalents of Mn, 4 molar equivalents of Sb and 13 molar equivalents of S.

Cu₈Ag₂Mn₂Sb₄S₁₃:

Polycrystalline tetrahedrite Cu₈Ag₂Mn₂Sb₄S₁₃ was prepared following the method described above, starting with 8 molar equivalents of Cu, 2 molar equivalents of Ag, 2 molar equivalents of Mn, 4 molar equivalents of Sb and 13 molar equivalents of S.

Cu₇Ag₃Mn₂Sb₄S₁₃:

Polycrystalline tetrahedrite Cu₇Ag₃Mn₂Sb₄S₁₃ was prepared following the method described above, starting with 7 molar equivalents of Cu, 3 molar equivalents of Ag, 2 molar equivalents of Mn, 4 molar equivalents of Sb and 13 molar equivalents of S.

Cu₁₀Sn₂Sb₄S₁₃:

Polycrystalline tetrahedrite Cu₁₀Sn₂Sb₄S₁₃ was prepared following the method described above, starting with 10 molar equivalents of Cu, 2 molar equivalents of Sn, 4 molar equivalents of Sb and 13 molar equivalents of S.

Cu_{9.75}Ag_{0.25}Te₄S₁₃:

Polycrystalline tetrahedrite Cu_{9.75}Ag_{0.25}Te₄S₁₃ was prepared following the method described above, starting with 9.75 molar equivalents of Cu, 0.25 molar equivalents of Ag, 4 molar equivalents of Te and 13 molar equivalents of S.

Cu_{90.5}Ag_{0.5}Te₄S₁₃:

Polycrystalline tetrahedrite Cu_{90.5}Ag_{0.5}Te₄S₁₃ was prepared following the method described above, starting with 9.5 molar equivalents of Cu, 0.5 molar equivalents of Ag, 4 molar equivalents of Te and 13 molar equivalents of S.

Cu_{9.25}Ag_{0.75}Te₄S₁₃: Polycrystalline tetrahedrite Cu_{9.25}Ag_{0.75}Te₄S₁₃ was prepared following the method described above, starting with 9.25 molar equivalents of Cu, 0.75 molar equivalents of Ag, 4 molar equivalents of Te and 13 molar equivalents of S.

Cu₉AgTe₄S₁₃:

Polycrystalline tetrahedrite Cu₉AgTe₄S₁₃ was prepared following the method described above, starting with 9 molar equivalents of Cu, 1 molar equivalent of Ag, 4 molar equivalents of Te and 13 molar equivalents of S.

Cu₁₀Zn₂Sb₄Se₁₃:

Polycrystalline tetrahedrite Cu₁₀Zn₂Sb₄Se₁₃ was prepared following the method described above, starting with 10 molar equivalents of Cu, 2 molar equivalents of Zn, 4 molar equivalents of Sb and 13 molar equivalents of Se.

Cu₁₀Zn₂Sb₄(S_{0.75}Se_{0.25})₁₃:

Polycrystalline tetrahedrite Cu₁₀Zn₂Sb₄(S_{0.75} Se_{0.25})₁₃ was prepared following the method described above, starting with 10 molar equivalents of Cu, 2 molar equivalents of Zn, 4 molar equivalents of Sb, 9.75 molar equivalents of S and 3.25 molar equivalents of Se.

Cu₁₀Zn₂Sb₄(S_{0.5}Se_{0.5})₁₃:

Polycrystalline tetrahedrite Cu₁₀Zn₂Sb₄(S_{0.5} Se_{0.5})₁₃ was prepared following the method described above, starting with 10 molar equivalents of Cu, 2 molar equivalents of Zn, 4 molar equivalents of Sb, 6.5 molar equivalents of S and 6.5 molar equivalents of Se.

Cu₁₀Zn₂Sb₄(S_{0.25} Se_{0.75})₁₃:

Polycrystalline tetrahedrite Cu₁₀Zn₂Sb₄(S_{0.25} Se_{0.75})₁₃ was prepared following the method described above, starting with 10 molar equivalents of Cu, 2 molar equivalents of Zn, 4 molar equivalents of Sb, 3.25 molar equivalents of S and 9.75 molar equivalents of Se.

Cu₁₂Te₄S₁₃:

Polycrystalline tetrahedrite Cu₁₂Te₄S₁₃ was prepared following the method described above, starting with 12 molar equivalents of Cu, 4 molar equivalents of Te and 13 molar equivalents of S.

Cu₁₀Te₄S₁₃:

Polycrystalline tetrahedrite Cu₁₀Te₄S₁₃ was prepared following the method described above, starting with 10 molar equivalents of Cu, 4 molar equivalents of Te and 13 molar equivalents of S.

### B. Thin-Film Deposition of Sulfide-Based Tetrahedrite Compounds

Cu₁₀Zn₂Sb₄S₁₃:

A thin-film of the tetrahedrite Cu₁₀Zn₂Sb₄S₁₃ was fabricated using electron-beam (EB) evaporation of the constituent layers (20 equivalents ZnS/100 equivalents Cu/20 equivalents Sb₂S₃) at room temperature onto a fused silica substrate and were subsequently annealed in a CS₂ environment in a tube furnace at 295° C. for 30 minutes.

Cu₁₀Mn₂Sb₄S₁₃:

A thin-film of the tetrahedrite Cu₁₀Mn₂Sb₄S₁₃ was fabricated following the method described above and using 20 equivalents MnS, 100 equivalents Cu, and 20 equivalents Sb₂S₃.

Cu₁₁InSb₄S₁₃:

A thin-film of the tetrahedrite Cu₁₁InSb₄S₁₃ was fabricated following the method described above and using 5 equivalents In₂S₃, 110 equivalents Cu, and 20 equivalents Sb₂S₃.

Cu₁₂Sb₄S₁₃:

A thin-film of the tetrahedrite Cu₁₂Sb₄S₁₃ was fabricated following the method described above and using 60 equivalents CuS, 90 equivalents Cu, and 180 equivalents Sb₂S₃.

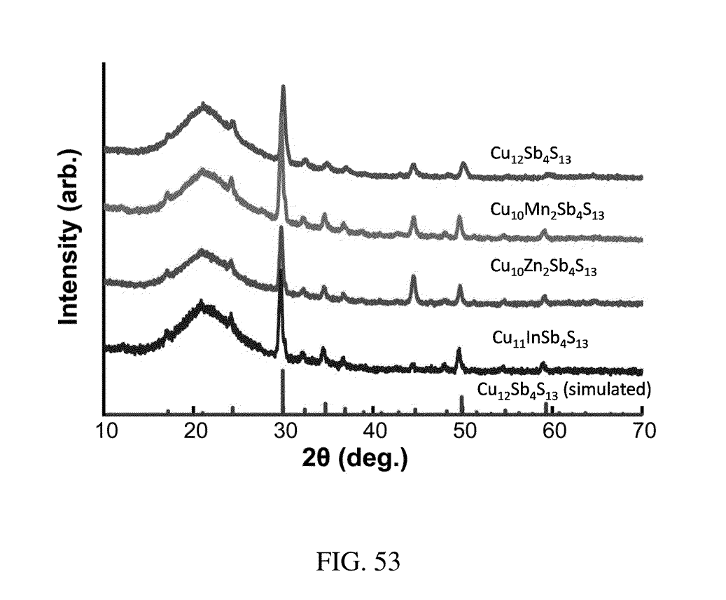

The thicknesses of final films were from about 180 to 400 nm after annealing. FIG. 53 provides XRD patterns of these thin films.

### C. Thin-Film Deposition of a Selenide-Based Tetrahedrite

Cu₁₀Zn₂Sb₄Se₁₃:

A thin-film of the tetrahedrite Cu₁₀Zn₂Sb₄Se₁₃ was fabricated onto a fused silica substrate at ambient temperature using EB of the constituent layers of 60 equivalents ZnSe/77 equivalents Cu/175 equivalents Se/90 equivalents Sb₂Se₃. The sample was subsequently annealed in an evacuated sealed fused-silica tube at 295° C. for 30 minutes resulting in a 180 nm-thick film. The XRD pattern of this thin film is shown in FIG. 14.

### D. X-Ray Characterization of Tetrahedrite Compounds

The crystal phase of tetrahedrite samples in the annealed powders and deposited thin films was characterized with a Rigaku Ultima IV diffractometer with a 0.02 rad slit and Cu Kα radiation (λ=1.5418 Å). Data were collected between 10 and 100 degrees at a step size of 0.02 degrees and a dwell time of 1 second at each step. X-ray diffraction patterns were compared with ICSD and ICDD-PDF files by using PDXL software suite.

### F. Powder Synthesis of C—V—VI Compounds

Bulk synthesis was carried out using elemental powders of Cu, P, As, Sb, S and Se supplied by Alfa Aesar of 99.95% purity or higher. The stoichiometric mixtures of appropriate compositions, i.e. 3 molar equivalents of Cu, 1 molar equivalent of Sb, As or P and 4 molar equivalents of S or Se, were mixed and annealed in evacuated fused silica sealed tubes in the 400-500° C. temperature range. Slight excess of volatile elements, such as P, As, S, Se, was added to prevent formation of M-element poor secondary phases. The resulting polycrystalline powder was crushed and molded into pellets of diameter of about 0.5 inches. These were sintered in the 400-500° C. temperature range for 12 hours to achieve dense pellets (about 85%) that were used to analyze the physical properties.

Powder samples of Cu₃PS₄₋ₓSeₓ (0≦x≦4) were prepared by mixing and grinding stoichiometric amounts of the elemental powders of Cu (99.999% Alfa Aesar), P (99.999%, Materion Advanced Chemicals), S (99.999%, Cerac) and Se (99.999%, Alfa Aesar) under an Argon atmosphere. The samples were then sealed in evacuated fused silica tubes and heated at 480-600° C. for 24 hours, followed by an additional grinding and heating for 24 hours at the same temperature. Pressed pellets were made by cold pressing 12.5 mm diameter disks at 2.5 to 3 tons, and then sintering at the synthesis temperature for 3 hours under 10,000 psi of Ar gas in a hot isostatic press (American Isostatic Presses, Inc. AIP6-30H). Final pellet densities were approximately 70% of theoretical values.

### G. Single Crystal Synthesis of C—V—VI Compounds

Single crystals were grown by chemical vapor transport (CVT) with NH₄Br (99.999%, Alfa Aesar) as the transport agent. The sample tubes, containing mixed elemental powders and the transport agent (1.5 mg cm⁻³ for Cu₃PSe₄ and 5 mg cm⁻³ for Cu₃PS₄₋ₓSeₓ) were uniformly heated in a three-zone ATS series 3210 split-tube furnace at 500° C. for 12 hours. Then, a temperature gradient was applied by setting temperatures to 550° C. (zone 1), 600° C. (zone 2), and 700° C. (zone 3) for 3 days before cooling at a rate of 5° C./hour to 400° C. (zone 1), 450° C. (zone 2) and 500° C. (zone 3). The furnace power was then turned off and the furnace was allowed to cool to room temperature. Black needle-shaped crystals were found at the cold zone of each tube.

### H. Thin Layer Deposition of C—V—VI

Thin-film deposition of Cu₃SbS₄, was carried out using electron-beam (EB) evaporation of the constituent layers, Cu and Sb₂S₃, or rf sputtering from a target of the same composition, at room temperature onto a fused silica substrate. These products were subsequently annealed in a sulfur/argon environment in a tube furnace at 300° C. for 30 minutes.

Thin films of Cu₃AsS₄ were prepared by pulsed electron deposition from a target of the same composition at ambient temperature onto a fused silica substrate. Resulting products were subsequently annealed in an argon/sulfur containing tube furnace at 350° C. for 30 minutes.

Alternatively, the films can be annealed in an evacuated sealed quartz tube in the presence of sulfur at 350-500° C. for 2 minutes.

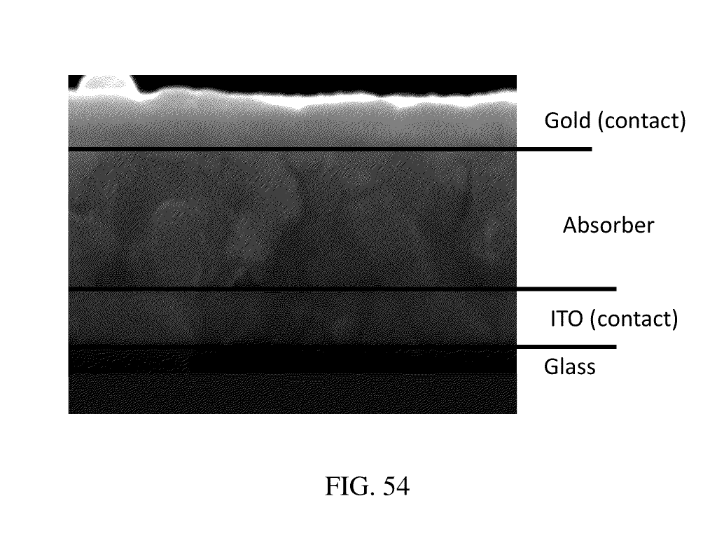

FIG. 54 is a photomicrograph of a simple photovoltaic device that was made using a Cu₃SbS₄ semiconductor absorber layer prepared by the disclosed method directly on a transparent conductive oxide layer, and completed with an Au contact top contact.

### I. Chemical Analysis

Data for compositional analyses of the single crystals were acquired on an electron microprobe (Cameca SX-50) equipped with four tunable wavelength dispersive spectrometers. Operating conditions comprised a 40° takeoff angle and 18 keV beam energy at a current of 20 nA and a spot size of 10 μm diameter.

### J. X-Ray Characterization

Powder X-ray diffraction data were collected with a Ripku Uldma IV diffractometer using Cu Ka radiation. Lattice parameters of powder samples were refined using PDXL software. X-ray diffraction data for single crystals were collected on a Bruker SMART APEX CCD diffractometer at 293 K using Mo Ka radiation. The structures were solved using direct methods and completed by subsequent difference Fourier syntheses and refinement by full matrix least-squares procedures on F². Absorption corrections were applied by using the computer program SADABS. All atoms were refined with anisotropic thermal parameters. The software for solution and refinement and sources of scattering factors are contained in the SHELXTL 6.10 package.

### K. Optical and Electrical Characterization

Optical transmission and reflection measurements were performed using a spectrometer equipped with an Ocean Optics HR4000 UV-Vis detector and a balanced deuterium/tungsten halogen source (DH-2000-BAL). For diffuse reflectance measurements, MgO power (99.95%, Cerac) was used as a white reference. Room temperature resistivity and Hall mobility were collected in the van der Pauw geometry with a LakeShore 7504 measurement system. Majority carrier type was determined from Seebeck measurements on a custom-built system by applying a 3 Kelvin temperature gradient to the sample.

### L. Theoretical Calculations

The first principles calculation of Cu₁₂Sb₄S₁₃ presented here was carried using VASP code and PAW potentials. The electronic degrees of freedom were described within DFT by the generalized gradient approximation (GGA) with the value of the Hubbard U parameters (for Cu, U=6 eV; for others, U=0 eV). The atomic positions were fully relaxed by HSE06, while lattice parameters were fixed to the experimental data. For the exchange-correlation functional, the PW91 parameterization for accurate total energy calculations was used with a F-centered 4×4×4 k-point grid.

### M. Device Simulation

1. Tetrahedrite Compounds

The device configuration used in SCAPS is shown in FIG. 35 and was similar to a CdTe-based TFSC. It was an n-p-p⁺ heterojunction TFSC configuration, comprising the following layers: back contact/p+-Cu₁₀Zn₂Sb₄Se₁₃/p-Cu₁₀Zn₂Sb₄Se₁₃/n-CdS/n-SnO₂/front contact. The p-type Cu₁₀Zn₂Sb₄Se₁₃ absorber layer was assumed to have a carrier concentration of 2×10¹⁶ cm⁻³. The 100 nm p⁺-type layer had a carrier concentration of 2×10¹⁸ cm⁻³ and otherwise the same properties as the absorber layer. The p⁺-type layer was included beneath the absorber to create an electron reflector via a small (0.2 eV) conduction band offset at the p-p⁺ interface, providing a bather and preventing electrons and holes from recombining at the back surface. The n-type layer comprised a 25 nm CdS layer below a 500 nm SnO₂ layer, similar to a CdTe-based TFSC configuration. The work function values of the front and back contact were 4.1 and 5.0 eV, respectively. The electron/hole mobility value of the Cu₁₀Zn₂Sb₄Se₁₃ layers was assumed to be 50/14 cm²V⁻¹s⁻¹ and trap mediated (Shockley-Read-Hall) recombination was assumed to be the dominant recombination mechanism. The current-voltage characteristics were simulated between 0 and 1 V and the quantum efficiency was simulated between 300 and 1200 nm.

2. Combination of Tetrahedrite and C—V—VI Compounds

The device configuration used in SCAPS is shown in FIG. 41. CdTe is modeled as a pin junction solar cell, CIS is modeled as a pn junction, Cu₃MS₄₋ₓSeₓ and M¹_{d}M²ₑM³_{f}Ch_{g} are modeled as a p⁺pn heterojunction, where the p⁺-layer is the hole extraction contact. The p⁺-type layer was included beneath the absorber to create an electron reflector via a small (0.2 eV) conduction band offset at the p-p⁺ interface, providing a barrier and preventing electrons from recombining at the back surface. The n-type layer comprised a 25 nm CdS layer below a 500 nm SnO₂ layer, similar to a CdTe-based TFSC configuration. The work function values of the front and back contact were 4.1 and 5.0 eV, respectively. The electron/hole mobility value of the described semiconductor absorber layers was assumed to be 50/14 cm²V⁻¹s⁻¹. Trap mediated (Shockley-Read-Hall) recombination was assumed to be the dominant recombination mechanism in all modeled semiconductor absorbers with a mid-gap defect density of 10¹⁴ cm⁻³ that corresponds to minority carrier lifetime of 1 ns.

Table 4 provides a comparison of simulated C—V—VI-based device efficiency with CIGS. Tandem device bottom cell efficiency is q=10% evaluated using truncated solar spectrum with a 1.4 eV low-pass filter. Key assumptions include: absorber hole carrier concentration N_{A}=2×1016 cm⁻³; electron/hole mobility μₙ/μₚ=50/14 cm²/V-s; and minority (electron) carrier lifetime τ=10 ns. Simulations performed using SCAPS.

TABLE 4
Comparison of simulated C-V-VI-based
device efficiency with CIGS

| | Single-Junction | Tandem |
|---|---|---|
| Material | Efficiency (%) | Efficiency (%) |
| CIGS (single-junction) | 19.5 | — |
| Cu₃AsS₄ (tandem top cell) | 21.0 | 31 |
| Cu₃SbS₄ (tandem bottom cell) | 21.3 | |

### Example 2

A working example of a C—V—VI absorber using formula VII was made by integrating the material into the solar cell of a superstrate structure according to FIG. 38. The stack comprised an ITO/IGZO/CdS/Cu₃SbS₄/Au sequence of layers.

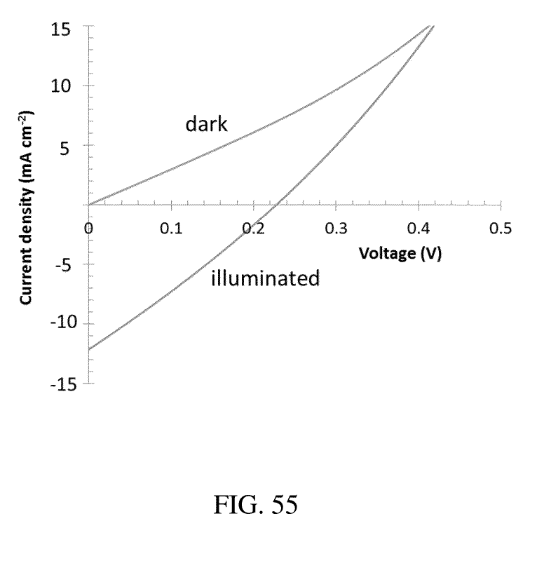

FIG. 55 provides a current-voltage measurement for this exemplary absorber. A person of ordinary skill in the art will understand that these results demonstrated a photovoltaic effect in the device. This exemplary working example of a C—V—VI absorber exhibited an open circuit voltage of 0.23 V, a shirt circuit current of 12 mA cm⁻² and a fill factor of 0.26, and demonstrated an 0.8% conversion efficiency under approximately 1 sun illumination.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

We claim:

1. A device, comprising:
a first semiconductor compound having a formula
A¹₃MCh^{a}₄
wherein A¹ is a transition metal or a combination thereof, M is selected from a transition metal, a group 14 element, a group 15 element or a combination thereof, and Ch^{a} is a group 16 element or a combination thereof; and
a second semiconductor compound having a formula
A₆₊ₐB_{6+b}(C_{1+c}X₃₊ₓ)_{4+z}Y_{1+y}
wherein A and B independently are selected from a transition metal, a group 13 element, a group 14 element, a group 15 element, or any combination thereof; C is a cation with ns² electronic configuration, which is selected from a group 13 element, a group 14 element, a group 15 element or a combination thereof; X and Y independently are a group 15 anion, a group 16 anion, a group 17 anion, or any combination thereof; a is from −2.5 to 2; b is from −2 to 2; c is from −1 to 1; x is from −2 to 2; z is from −1 to 1; and y is from −1 to 2.

2. The device of claim 1, wherein:
A and B independently are selected from Cu, Ag, Al, Ga, In, Si, Ge, Sn, Zn, Mn, Fe, Co, Ni, V, Nb, Ta, Mo, W, Ti, Hf, Zr, or a combination thereof;
C is selected from Ga, In, Si, Ge, Sn, Pb, P, As, Sb, Bi, Se, Te, or a combination thereof; and
X and Y independently are selected from P, As, Sb, Bi, O, S, Se, Te, F, Cl, or a combination thereof.

3. The device of claim 1, wherein:
C is selected from P, As, Sb, Te, or combinations thereof; and
X and Y each independently is selected from S, Se.

4. The device of claim 1, wherein:
A₆₊ₐB_{6+b} comprises Cu_{12+a+b-h}M⁵ₕ; and
M⁵ is selected from Mg, Zn, Mn, Sn, or any combination thereof, and h is from 0 to less than 2; or M⁵ is selected from Al, Ga, In, or any combination thereof, and h is from 0 to less than 1.

5. The device of claim 1, wherein:
A¹ is selected from Cu, Ag, Mg, Zn, Mn, or any combination thereof;
M is selected from P, As, Sb, V, Nb, Te, Ta, Si, Ge, Sn, Ti, Zr, Hf, Al, Ga, In, or any combination thereof; and
Ch^{a} is selected from S, Se or a combination thereof.

6. The device of claim 1, wherein the first semiconductor compound is selected from Cu₃SbS₄, Cu₃SbSe₄, Cu₃AsS₄, Cu₃AsSe₄, Cu₃PS₄, Cu₃PSe₄ or combinations thereof.

7. The device of claim 1, wherein the first semiconductor compound is selected from Cu₃As₁₋ₑSbₑS₄ (0<e<1), Cu₃PS₄₋ₓSeₓ (1≦x<4), Cu₃AsS_{4-y}Se_{y}(0<y<4), Cu₃P_{1-z}As_{z}S₄ (0.1≦z<1), Cu₃P₁₋ₐAsₐSe₄ (0<a≦1), or Cu₃SbS_{4-f}Se_{f} (0<f≦2).

8. The device of claim 1, wherein the first semiconductor is selected from A¹₃₋ᵢ(A^{1′})ᵢMS₄ (0<i≦0.3) or A¹₃M₁₋ⱼM′ⱼS₄ (0<j≦0.1), where A^{1′} is Mg, Mn, Zn, or any combination thereof, M is a group 5 element, a group 15 element, or any combination thereof, and M′ is a group 3 element, group 4 element, group 6 element, group 13 element, group 14 element, group 16 element, or any combination thereof.

9. The device of claim 1, wherein the first semiconductor compound is selected from Cu₃₋ₕAgₕMS₄ (0<h≦1.5), or A¹₃M₁₋ₖM″ₖS₄ (0<k<1), where M and M″ are selected from group 5 elements, group 15 elements, or any combination thereof.

10. The device of claim 1, wherein the first semiconductor compound is selected from A¹₃MCh^{a}₄₋ₘCh^{a′}ₘ (0≦m≦0.12) where Ch^{a′} are selected from group 15 elements, group 17 elements, O, or any combination thereof.

11. The device of claim 1, wherein the second semiconductor compound is selected from Cu₁₂Sb₄S₁₃, Cu₁₀Mn₂Sb₄S₁₃, Cu₁₀Zn₂Sb₄S₁₃, Cu₁₀Fe₂Sb₄S₁₃, Cu₁₀Ni₂Sb₄S₁₃, Cu₁₀Sn₂Sb₄S₁₃, Cu₁₀Co₂Sb₄S₁₃, Cu₁₀Cr₂Sb₄S₁₃, Cu₁₀V₂Sb₄S₁₃, Cu₁₀Ti₂Sb₄S₁₃, Cu₁₀Nb₂Sb₄S₁₃, Cu₁₀Mo₂Sb₄S₁₃, Cu₁₀Ag₂Sb₄S₁₃, Cu₁₀Cd₂Sb₄S₁₃, Cu₁₀Ta₂Sb₄S₁₃, Cu₁₀W₂Sb₄S₁₃, Cu₁₁AuSb₄S₁₃, Cu₁₁WSb₄S₁₃, Cu₁₁TaSb₄S₁₃, Cu₁₁MoSb₄S₁₃, Cu₁₁NbSb₄S₁₃, Cu₁₁TiSb₄S₁₃, Cu₁₁HfSb₄S₁₃, Cu₁₁ZrSb₄S₁₃, Cu₁₁NiSb₄S₁₃, Cu₁₁CoSb₄S₁₃, Cu₁₁MnSb₄S₁₃, Cu₁₁FeSb₄S₁₃, Cu₁₁InSb₄S₁₃, Cu₁₁AlSb₄S₁₃, Cu₁₁GaSb₄S₁₃, Cu₁₀Mn₂Sb₄Se₁₃, Cu₁₀Zn₂Sb₄Se₁₃, Cu₁₀Fe₂Sb₄Se₁₃, Cu₁₀Ni₂Sb₄Se₁₃, Cu₁₀Co₂Sb₄Se₁₃, Cu₁₀V₂Sb₄Se₁₃, Cu₁₀Ti₂Sb₄Se₁₃, Cu₁₀Nb₂Sb₄Se₁₃, Cu₁₀Mo₂Sb₄Se₁₃, Cu₁₀Ag₂Sb₄Se₁₃, Cu₁₀Cd₂Sb₄Se₁₃, Cu₁₀Ta₂Sb₄Se₁₃, Cu₁₀W₂Sb₄Se₁₃, Cu₁₁AuSb₄Se₁₃, Cu₁₁WSb₄Se₁₃, Cu₁₁TaSb₄Se₁₃, Cu₁₁MoSb₄Se₁₃, Cu₁₁NbSb₄Se₁₃, Cu₁₁ZrSb₄Se₁₃, Cu₁₁NiSb₄Se₁₃, Cu₁₁CoSb₄Se₁₃, Cu₁₁MnSb₄Se₁₃Cu₁₁FeSb₄Se₁₃, Cu₁₁InSb₄Se₁₃, Cu₁₁AlSb₄Se₁₃, Cu₁₁GaSb₄Se₁₃, Cu₁₂P₄S₁₃, Cu₁₂Bi₄S₁₃, Cu₁₂Te₄S₁₃, Cu₁₂P₄Se₁₃, Cu₁₂As₄Se₁₃, Cu₁₂As₄S₁₃, Cu₁₂Sb₄Se₁₃, Cu₁₂Sb₄S₁₃, Cu₁₂Bi₄Se₁₃, Cu₁₂Te₄Se₁₃, Cu₁₀Sb₄S₁₃, Cu₁₀As₄S₁₃, Cu₁₀P₄S₁₃, Cu₁₀Bi₄S₁₃, Cu₁₀Te₄S₁₃, Cu₁₀Sb₄S₁₃, Cu₁₀As₄Se₁₃, Cu₁₀P₄Se₁₃, Cu₁₀Bi₄Se₁₃, Cu₁₀Te₄Se₁₃, Cu₁₄Sb₄Se₁₃, Cu₁₄Sb₄S₁₃, Cu₁₄P₄Se₁₃, Cu₁₄P₄S₁₃, Cu₁₄As₄Se₁₃, Cu₁₄As₄S₁₃, Cu₁₄Bi₄Se₁₃, Cu₁₄Bi₄S₁₃, Cu₁₀Zn₂Sb₄(S_{0.75} Se_{0.25})₁₃, Cu₁₀Zn₂Sb₄(S_{0.5} Se_{0.5})₁₃, Cu₁₀Zn₂Sb₄(S_{0.25} Se_{0.75})₁₃, Cu₁₀Zn₂Sb₄Se₁₃, Cu₁₀TiSb₄S₁₃, Cu₁₀HfSb₄S₁₃, Cu₁₀ZrSb₄S₁₃, Cu₁₀TiSb₄Se₁₃, Cu₁₀HfSb₄Se₁₃, Cu₁₀ZrSb₄Se₁₃, Cu_{11.5}Zn_{0.5}Sb₄S₁₃, Cu₁₁ZnSb₄S₁₃, Cu_{10.5}Zn_{1.5}Sb₄S₁₃, Cu₁₀Zn₂Sb₄S₁₃, Cu_{11.5}Mn_{0.5}Sb₄S₁₃, Cu₁₁MnSb₄S₁₃, Cu_{10.5}Mn_{1.5}Sb₄S₁₃, Cu₁₀Mn₂Sb₄S₁₃, Cu₁₁FeSb₄S₁₃, Cu₉AgZn₂Sb₄S₁₃, Cu₈Ag₂Zn₂Sb₄S₁₃, Cu₇Ag₃Zn₂Sb₄S₁₃, Cu₉AgMn₂Sb₄S₁₃, Cu₈Ag₂Mn₂Sb₄S₁₃, Cu₇Ag₃Mn₂Sb₄S₁₃, Cu_{9.75}Ag_{0.25}Te₄S₁₃, Cu_{9.5}Ag_{0.5}Te₄S₁₃, Cu_{9.25}Ag_{0.75}Te₄S₁₃ or Cu₉AgTe₄S₁₃.

12. The device according to claim 1, comprising a plurality of semiconductor layers with the first semiconductor compound in a first semiconductor layer and the second semiconductor compound in a second semiconductor layer.

13. The device according to claim 1, comprising a semiconductor layer comprising the first semiconductor compound and the second semiconductor compound.

14. The device of claim 13, wherein the semiconductor layer is a graded semiconductor layer.

15. The device of claim 1, wherein the device is a photovoltaic device.

16. The device of claim 15, further comprising a p-layer and a p⁺-layer, wherein at least one of the p-layer and the p⁺-layer comprises the first semiconductor compound and at least one of the p-layer and the p⁺-layer comprises the second semiconductor compound.

17. The device of claim 16, wherein the p-layer comprises the first semiconductor compound and the p⁺-layer comprises the second semiconductor compound.

18. The device of claim 1, comprising:
a substrate;
a bottom contact layer;
a p⁺-type layer comprising the second semiconductor compound;
a p-type layer comprising the first semiconductor compound;
a buffer layer;
a window layer; and
a top contact electrode.

19. The device of claim 1, comprising:
a transparent substrate;
a window layer;
a buffer layer;
a p-type layer comprising the first semiconductor compound;
a p⁺-type layer comprising the second semiconductor compound; and
a bottom contact electrode.

20. The device according to claim 1, comprising:
at least one contact electrode; and
at least one semiconductor layer in electrical contact with the at least one contact electrode, at least one of the semiconductor layer and the contact electrode comprising a compound having a tetrahedrite crystal structure and a formula V 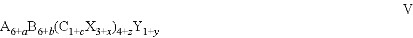
wherein
A is a transition metal, a group 13 element, a group 14 element, a group 15 element, or any combination thereof;
B is a transition metal, a group 13 element, a group 14 element, a group 15 element, or any combination thereof;
C is a cation with ns² electronic configuration, which is selected from a group 13 element, a group 14 element, a group 15 element or a combination thereof;
X is selected from a group 15 anion, a group 16 anion, a group 17 anion, or any combination thereof;
Y is selected from a group 15 anion, a group 16 anion, a group 17 anion, or any combination thereof
a is from −2.5 to 2;
b is from −2 to 2;
c is from −1 to 1;
x is from −2 to 2;
z is from −1 to 1;
and y is from −1 to 2.

21. The device of claim 20, wherein A is selected from Cu, Zn, Ag, Al, Ga or any combination thereof.

22. The device of claim 21, wherein B is Cu.

23. The device of claim 20, wherein the compound is selected from Cu₁₂Sb₄S₁₃, Cu₁₀Mn₂Sb₄S₁₃, Cu₁₀Zn₂Sb₄S₁₃, Cu₁₀Fe₂Sb₄S₁₃, Cu₁₀Ni₂Sb₄S₁₃, Cu₁₀Sn₂Sb₄S₁₃, Cu₁₀Co₂Sb₄S₁₃, Cu₁₀Cr₂Sb₄S₁₃, Cu₁₀V₂Sb₄S₁₃, Cu₁₀Ti₂Sb₄S₁₃, Cu₁₀Nb₂Sb₄S₁₃, Cu₁₀Mo₂Sb₄S₁₃, Cu₁₀Ag₂Sb₄S₁₃, Cu₁₀Cd₂Sb₄S₁₃, Cu₁₀Ta₂Sb₄S₁₃, Cu₁₀W₂Sb₄S₁₃, Cu₁₁AuSb₄S₁₃, Cu₁₁WSb₄S₁₃, Cu₁₁TaSb₄S₁₃, Cu₁₁MoSb₄S₁₃, Cu₁₁NbSb₄S₁₃, Cu₁₁TiSb₄S₁₃, Cu₁₁HfSb₄S₁₃, Cu₁₁ZrSb₄S₁₃, Cu₁₁NiSb₄S₁₃, Cu₁₁CoSb₄S₁₃, Cu₁₁MnSb₄S₁₃, Cu₁₁FeSb₄S₁₃, Cu₁₁InSb₄S₁₃, Cu₁₁AlSb₄S₁₃, Cu₁₁GaSb₄S₁₃, Cu₁₀Mn₂Sb₄Se₁₃, Cu₁₀Zn₂Sb₄Se₁₃, Cu₁₀Fe₂Sb₄Se₁₃, Cu₁₀Ni₂Sb₄Se₁₃, Cu₁₀Co₂Sb₄Se₁₃, Cu₁₀V₂Sb₄Se₁₃, Cu₁₀Ti₂Sb₄Se₁₃, Cu₁₀Nb₂Sb₄Se₁₃, Cu₁₀Mo₂Sb₄Se₁₃, Cu₁₀Ag₂Sb₄Se₁₃, Cu₁₀Cd₂Sb₄Se₁₃, Cu₁₀Ta₂Sb₄Se₁₃, Cu₁₀W₂Sb₄Se₁₃, Cu₁₁AuSb₄Se₁₃, Cu₁₁WSb₄Se₁₃, Cu₁₁TaSb₄Se₁₃, Cu₁₁MoSb₄Se₁₃, Cu₁₁NbSb₄Se₁₃, Cu₁₁ZrSb₄Se₁₃, Cu₁₁NiSb₄Se₁₃, Cu₁₁CoSb₄Se₁₃, Cu₁₁MnSb₄Se₁₃Cu₁₁FeSb₄Se₁₃, Cu₁₁InSb₄Se₁₃, Cu₁₁AlSb₄Se₁₃, Cu₁₁GaSb₄Se₁₃, Cu₁₂P₄S₁₃, Cu₁₂Bi₄S₁₃, Cu₁₂Te₄S₁₃, Cu₁₂P₄Se₁₃, Cu₁₂As₄Se₁₃, Cu₁₂As₄S₁₃, Cu₁₂Sb₄Se₁₃, Cu₁₂Sb₄S₁₃, Cu₁₂Bi₄Se₁₃, Cu₁₂Te₄Se₁₃, Cu₁₀Sb₄S₁₃, Cu₁₀As₄S₁₃, Cu₁₀P₄S₁₃, Cu₁₀Bi₄S₁₃, Cu₁₀Te₄S₁₃, Cu₁₀Sb₄S₁₃, Cu₁₀As₄Se₁₃, Cu₁₀P₄Se₁₃, Cu₁₀Bi₄Se₁₃, Cu₁₀Te₄Se₁₃, Cu₁₄Sb₄Se₁₃, Cu₁₄Sb₄S₁₃, Cu₁₄P₄Se₁₃, Cu₁₄P₄S₁₃, Cu₁₄As₄Se₁₃, Cu₁₄As₄S₁₃, Cu₁₄Bi₄Se₁₃, Cu₁₄Bi₄S₁₃, Cu₁₀Zn₂Sb₄(S_{0.75} Se_{0.25})₁₃, Cu₁₀Zn₂Sb₄(S_{0.5} Se_{0.5})₁₃, Cu₁₀Zn₂Sb₄(S_{0.25} Se_{0.75})₁₃, Cu₁₀Zn₂Sb₄Se₁₃, Cu₁₀TiSb₄S₁₃, Cu₁₀HfSb₄S₁₃, Cu₁₀ZrSb₄S₁₃, Cu₁₀TiSb₄Se₁₃, Cu₁₀HfSb₄Se₁₃, Cu₁₀ZrSb₄Se₁₃, Cu_{11.5}Zn_{0.5}Sb₄S₁₃, Cu₁₁ZnSb₄S₁₃, Cu_{10.5}Zn_{1.5}Sb₄S₁₃, Cu₁₀Zn₂Sb₄S₁₃, Cu_{11.5}Mn_{0.5}Sb₄S₁₃, Cu₁₁MnSb₄S₁₃, Cu_{10.5}Mn_{1.5}Sb₄S₁₃, Cu₁₀Mn₂Sb₄S₁₃, Cu₁₁FeSb₄S₁₃, Cu₉AgZn₂Sb₄S₁₃, Cu₈Ag₂Zn₂Sb₄S₁₃, Cu₇Ag₃Zn₂Sb₄S₁₃, Cu₉AgMn₂Sb₄S₁₃, Cu₈Ag₂Mn₂Sb₄S₁₃, Cu₇Ag₃Mn₂Sb₄S₁₃, Cu_{9.75}Ag_{0.25}Te₄S₁₃, Cu_{9.5}Ag_{0.5}Te₄S₁₃, Cu_{9.25}Ag_{0.75}Te₄S₁₃ or Cu₉AgTe₄S₁₃.

24. The device according to claim 20 selected from Schottky barrier diode, a field effect transistor, a thin bipolar junction transistor, a solar cell, a light emitting diode, a fuel cell, a metal-semiconductor-metal diode, or a metal-insulator-metal diode.

25. The device according to claim 1, comprising:
a contact layer;
an absorber layer comprising a first semiconductor compound having a formula VII 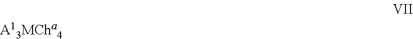
a second contact layer; and
a top contact electrode.
wherein
A¹ is a transition metal or any combination thereof;
M is selected from a transition metal, a group 14 element, a group 15 element or any combination thereof; and
Ch^{a} is a group 16 element, or any combination thereof.

26. The device of claim 25, wherein the second contact layer is a compound having formula VII.

27. The device of claim 25, wherein the first semiconductor is selected from Cu₃SbS₄, Cu₃SbSe₄, Cu₃AsS₄, Cu₃AsSe₄, Cu₃PS₄, Cu₃PSe₄, or any combination thereof.

28. The device of claim 25, wherein the first semiconductor is selected from Cu₃As₁₋ₑSbₑS₄ (0<e<1), Cu₃PS₄₋ₓSeₓ (1≦x<4), Cu₃AsS_{4-y}Se_{y}(0<y<4), Cu₃P_{1-z}As_{z}S₄ (0.1≦z<1), Cu₃P₁₋ₐAsₐSe₄ (0≦a≦1), or Cu₃SbS_{4-f}Se_{f} (0<f≦2).

29. The device of claim 25, wherein the second semiconductor is selected from A¹₃₋ᵢ(A^{1′})ᵢMS₄ (0<i≦0.3) or A¹₃M₁₋ⱼM′ⱼS₄ (0<j≦0.1), where A^{1′} is Mg, Mn, Zn, or any combination thereof, M is a group 5 element, a group 15 element, or any combination thereof, and M′ is a group 3 element, group 4 element, group 6 element, group 13 element, group 14 element, group 16 element, or any combination thereof.

30. The device of claim 25, wherein the first semiconductor is selected from Cu₃₋ₕAgₕMCh^{a}₄ (0<h≦11.5) or A¹₃M₁₋ₖM″ₖCh^{a}₄ (0<k<1), where M and M″ are group 5 elements, group 15 elements, or any combination thereof.

31. The device of claim 25, wherein the first semiconductor is selected from A¹₃MCh^{a}₄₋ₘCh^{a′}ₘ (0≦m≦0.12) where Ch^{a′} is selected from group 15 elements, group 17 elements, 0, or any combination thereof.

32. A compound having a formula I
M¹_{d}M²ₑM³_{f}Ch_{g}
wherein:
M¹ is selected from a transition metal, a group 13 element, a group 14 element, a group 15 element, or any combination thereof;
M² is selected from a group 13 element, a group 14 element, a group 15 element, or any combination thereof;
M³ is selected from a group 15 element, a group 16 element, a group 17, or any combination thereof;
Ch is selected from a group 15 element, a group 16 element, or any combination thereof;
d is from 10 to 14;
e is from 0 to 14-d;
f is from 2 to 6;
g is from 10 to 16; and
wherein when M¹ is a transition metal and d+e is 12, then e is greater than 0; and
when d+e is not 12, and M¹ is Cu, then e is greater than 0.

33. The compound according to claim 32, wherein:
M¹ is selected from Cu, Ag, Al, Ga, In, Si, Ge, Sn, Zn, Mn, Fe, Co, Ni, V, Nb, Ta, Mo, W, Ti, Hf, Zr, or any combination thereof;
M² is selected from Ga, In, Si, Ge, Sn, Pb, P, As, Sb, Bi, Se, Te, or any combination thereof;
M³ is selected from P, As, Sb, Bi, O, S, Se, Te, F, Cl, or any combination thereof; and
Ch is selected from P, As, Sb, Bi, O, S, Se, Te, F, Cl, or a combination thereof.

34. The compound according to claim 32, wherein d is 10, e is 2, f is 4 and g is 13.

35. The compound according to claim 32, wherein M¹ is Cu, M² is In, M³ is Sb and Ch is S, Se, or any combination thereof.

36. The compound according to claim 32, wherein M¹ is Cu and the compound has a formula Cu_{d}M²ₑM³_{f}Ch_{g}.

37. The compound according to claim 32, wherein M³ is Sb and the compound has a formula M¹_{d}M²ₑSb_{f}Ch_{g}.

38. The compound according to claim 32, wherein M¹ is Cu, M³ is Sb and the compound has a formula Cu_{d}M²ₑSb_{f}Ch_{g}.

39. The compound according to claim 32, wherein Ch comprises Ch¹₁₋ₕCh²ₕ, where h is from 0 to 1 and Ch¹ and Ch^{e} independently are selected from P, As, Sb, Bi, O, S, Se, Te, F, or Cl.

40. A method for making a photovoltaic device, comprising:
providing a compound according to claim 1, or a composition comprising the compound; and
making the device comprising the compound.

41. A semiconductor selected from Cu₃PS₃Se, Cu₃PS₂Se₂, Cu₃PSSe₃, Cu₃PS_{2.5}Se_{1.5}, Cu₃PS_{1.89}Se_{2.11}, Cu₃PS_{0.71}Se_{3.29}, Cu₃AsS₃Se, Cu₃AsS₂Se₂, Cu₃AsS_{2.5}Se_{1.5}, Cu₃AsSSe₃, Cu₃P_{0.5}As_{0.5}Se₄, Cu₃P_{0.75}As_{0.25}Se₄, Cu₃P_{0.9}As_{0.1}Se₄, Cu₃P_{0.2}As_{0.8}S₄, Cu₃P_{0.4}As_{0.6}S₄, Cu₃P_{0.5}As_{0.5}S₄, Cu₃P_{0.6}As_{0.4}S₄, or Cu₃P_{0.8}As_{0.2}S₄.
